(19) United States
(12) Patent Application Publication
(10) Pub. No.: US 2023/0245912 A1
(43) Pub. Date: Aug. 3, 2023

(54) TRANSFER FILM, MANUFACTURING METHOD FOR LAMINATE, MANUFACTURING METHOD FOR CIRCUIT WIRE, AND MANUFACTURING METHOD FOR ELECTRONIC DEVICE

(71) Applicant: FUJIFILM Corporation, Tokyo (JP)

(72) Inventors: Satoru YAMADA, Fujinomiya-shi (JP); Kazumasa Morozumi, Fujinomiya-shi (JP); Kentaro Toyooka, Fujinomiya-shi (JP)

(73) Assignee: FUJIFILM Corporation, Tokyo (JP)

(21) Appl. No.: 18/171,060

(22) Filed: Feb. 17, 2023

Related U.S. Application Data
(63) Continuation of application No. PCT/JP2021/030597, filed on Aug. 20, 2021.

(30) Foreign Application Priority Data
Aug. 26, 2020 (JP) 2020-142918

(51) Int. Cl. H01L 21/683; G03F 7/16; G03F 7/09; G03F 7/20; G03F 7/34; G03F 1/80

(52) U.S. Cl. CPC H01L 21/6835; G03F 1/80; G03F 7/09; G03F 7/34; G03F 7/168; G03F 7/2004; H01L 2221/68345

(57) ABSTRACT

A first object of the present invention is to provide a transfer film that is capable of forming a resist pattern having excellent resolution. In addition, a second object of the present invention is to provide a transfer film that is capable of forming a resin pattern having excellent planarity. Further, a third object of the present invention is to provide a manufacturing method for a laminate, a manufacturing method for a circuit wire, and a manufacturing method for an electronic device, using the above-described transfer film.

The transfer film of the present invention is a transfer film having a temporary support and a composition layer disposed on the temporary support, in which the composition layer includes a photosensitive resin layer and a water-soluble resin layer, where the transfer film is obtained by laminating the temporary support, the water-soluble resin layer, and the photosensitive resin layer in this order or obtained by laminating the temporary support, the photosensitive resin layer, and the water-soluble resin layer in this order.

The water-soluble resin layer contains a compound A having a group represented by General Formula (1).

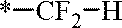

In the formula, * represents a bonding position.

### CROSS-REFERENCE TO RELATED APPLICATIONS

This application is a Continuation of PCT International Application No. PCT/JP2021/030597 filed on Aug. 20, 2021, which claims priority under 35 U.S.C. § 119(a) to Japanese Patent Application No. 2020-142918 filed on Aug. 26, 2020. Each of the above applications is hereby expressly incorporated by reference, in their entirety, into the present application.

### BACKGROUND OF THE INVENTION

### 1. Field of the Invention

The present invention relates to a transfer film, a manufacturing method for a laminate, a manufacturing method for a circuit wire, and an electronic device.

### 2. Description of the Related Art

In recent years, a transfer film such as a photosensitive transfer material has been increasingly used in various fields.

Since the photosensitive transfer material can contribute to cost reduction of the product, it has been proposed to use the photosensitive transfer material as a film for an etching resist, a film for a wire protective film, or the like.

On the other hand, the functions demanded on a photosensitive transfer material have been more and more sophisticated, and a configuration in which a plurality of functional layers are laminated is also being studied.

For example, WO2017/057348A discloses a transfer film for an etching resist and a transfer film for a wire protective film, which are obtained by laminating a plurality of functional layers. Specifically, it discloses a transfer film for an etching resist (paragraphs [0203] to [0207] and the like), which is obtained by laminating a temporary support / a thermoplastic resin layer / an interlayer / a photosensitive resin layer, and a transfer film for a wire protective film (paragraphs [0197], [0208], and the like), which is obtained by laminating a temporary support / a photosensitive resin layer / a second transparent resin layer. It is noted that the main components of the above-described interlayer are polyvinyl alcohol and polyvinylpyrrolidone, and the main components of the above-described second transparent resin layer are metal oxide particles and a copolymer of methacrylic acid/allyl methacrylate. That is, the above-described interlayer and the above-described second transparent resin layer contain a resin having high water solubility.

### SUMMARY OF THE INVENTION

With reference to WO2017/057348A, the inventors of the present invention produced a transfer film which includes a temporary support, a photosensitive resin layer, and a layer containing a highly water-soluble resin (a water-soluble resin layer), and which is obtained by laminating the temporary support, the water-soluble resin layer, and the photosensitive resin layers in this order, and studied the performance as a resist pattern, and as a result, it was revealed that the peeling of the protruding part and/or the generation of the residue of the recessed part may occur (that is, the resolution may be deteriorated). In addition, the inventors of the present invention produced a transfer film which includes a temporary support, a photosensitive resin layer, and a water-soluble resin layer, and which is obtained by laminating the temporary support, the photosensitive resin layer, and the water-soluble resin layers in this order, and studied the performance as a wire protective film, and as a result, it was revealed that surface defects due to optical unevenness may occur in a resin pattern that functions as a protective film (that is, the planarity may be deteriorated).

A first object of the present invention is to provide a transfer film that is capable of forming a resist pattern having excellent resolution.

In addition, a second object of the present invention is to provide a transfer film that is capable of forming a resin pattern having excellent planarity.

Further, a third object of the present invention is to provide a manufacturing method for a laminate, a manufacturing method for a circuit wire, and a manufacturing method for an electronic device, using the above-described transfer film.

As a result of carrying out intensive studies to achieve the objects, the inventors of the present invention found that the objects can be achieved by the following configurations.

[1] A transfer film comprising:
a temporary support; and
a composition layer disposed on the temporary support,
in which the composition layer includes a photosensitive resin layer and a water-soluble resin layer,
the transfer film is obtained by laminating the temporary support, the water-soluble resin layer, and the photosensitive resin layer in this order or obtained by laminating the temporary support, the photosensitive resin layer, and the water-soluble resin layer in this order, and
the water-soluble resin layer contains a compound A having a group represented by General Formula (1) described later.

The transfer film according to [1], in which the compound A is a compound having a group represented by General Formula (2) described later.

The transfer film according to [1] or [2], in which the compound A is a compound having a group represented by General Formula (3) described later.

The transfer film according to any one of [1] to [3], in which the compound A is a high-molecular-weight compound having a weight-average molecular weight of 5,000 or more.

The transfer film according to any one of [1] to [4], in which the compound A is a high-molecular-weight compound, and the high-molecular-weight compound contains a constitutional unit derived from a monomer represented by General Formula (4A) described later.

The transfer film according to [5], in which the high-molecular-weight compound further contains a constitutional unit derived from a monomer represented by General Formula (5) described later.

The transfer film according to any one of [1] to [3], in which a molecular weight of the compound A is 2,000 or less.

The transfer film according to any one of [1] to [3] or [7], in which the compound A is a compound represented by General Formula (6A) described later.

The transfer film according to [8], in which Z represents a monovalent organic group including a poly(oxyalkylene) structural moiety which may have a substituent.

The transfer film according to any one of [1] to [9], in which the photosensitive resin layer further contains an alkali-soluble resin and contains a polymerizable compound.

The transfer film according to any one of [1] to [10], in which the water-soluble resin layer further contains metal oxide particles.

The transfer film according to any one of [1] to [11], in which the water-soluble resin layer contains two or more kinds of water-soluble resins.

The transfer film according to any one of [1] to [12], further comprising a thermoplastic resin layer.

The transfer film according to any one of [1] to [13], in which the transfer film is obtained by laminating the temporary support, the water-soluble resin layer, and the photosensitive resin layer in this order.

The transfer film according to any one of [1] to [13], in which the transfer film is obtained by laminating the temporary support, the thermoplastic resin layer, the water-soluble resin layer, and the photosensitive resin layer in this order.

The transfer film according to any one of [1] to [13], in which the transfer film is obtained by laminating the temporary support, the photosensitive resin layer, and the water-soluble resin layer in this order.

A manufacturing method for a laminate using the transfer film according to any one of [1] to [16], the manufacturing method comprising:
an affixing step of bringing a substrate into contact with a surface of an outermost layer among composition layers disposed on the temporary support in the transfer film and affixing the transfer film to the substrate to obtain a transfer film-attached substrate;
an exposure step of subjecting the composition layer to pattern exposure;
a development step of developing the exposed composition layer to form a resin pattern; and
a peeling step of peeling the temporary support from the transfer film-attached substrate, between the affixing step and the exposure step or between the exposure step and the development step.

A manufacturing method for a circuit wire using the transfer film according to any one of [1] to [15], the manufacturing method comprising:
an affixing step of bringing a surface of an outermost layer among composition layers disposed on the temporary support in the transfer film into contact with a substrate having a conductive layer and bonding the transfer film to the substrate having the conductive layer to obtain a transfer film-attached substrate;
an exposure step of subjecting the composition layer to pattern exposure;
a development step of developing the exposed composition layer to form a resin pattern;
an etching step of subjecting the conductive layer in a region where the resin pattern is not disposed to an etching treatment; and
a peeling step of peeling the temporary support from the transfer film-attached substrate, between the affixing step and the exposure step or between the exposure step and the development step.

A manufacturing method for an electronic device, comprising:
the manufacturing method for a laminate according to [17],
in which the electronic device includes the resin pattern as a cured film.

According to the present invention, it is possible to provide a transfer film that is capable of forming a resist pattern having excellent resolution.

In addition, according to the present invention, it is possible to provide a transfer film that is capable of forming a resin pattern having excellent planarity.

Further, it is possible to provide a manufacturing method for a laminate, a manufacturing method for a circuit wire, and a manufacturing method for an electronic device, using the transfer film described above.

### BRIEF DESCRIPTION OF THE DRAWINGS

FIG. 1 is a schematic view illustrating an example of a configuration of a transfer film of a first aspect.

FIG. 2 is a schematic view illustrating an example of a configuration of a transfer film of a second aspect.

### DESCRIPTION OF THE PREFERRED EMBODIMENTS

Hereinafter, the present invention will be described in more detail.

The following description of configuration requirements is based on representative embodiments of the invention; however, the present invention is not limited thereto.

In the present invention, the numerical value range indicated by using “to” means a range including the numerical values before and after “to” as the lower limit value and the upper limit value, respectively.

In addition, a bonding direction of a divalent group (for example, —CO—O—) described in the present specification is not particularly limited.

In the present specification, (meth)acrylate indicates acrylate and methacrylate. The (meth)acrylic acid indicates acrylic acid and methacrylic acid. The (meth)acryloyl group indicates a methacryloyl group or an acryloyl group.

In describing a group (an atomic group) of the present specification, in a case where a description does not indicate substitution and non-substitution, the description means the group includes a group having a substituent as well as a group having no substituent. For example, the description “alkyl group” includes not only an alkyl group that does not have a substituent (an unsubstituted alkyl group) but also an alkyl group that has a substituent (a substituted alkyl group). Further, the “organic group” in the present specification means a group containing at least one carbon atom.

Further, in the present specification, the kind of substituent, the position of substituent, and the number of substituents are not particularly limited in a case of being described as “may have a substituent”. The number of substituents may be, for example, one, two, three, or more. In addition, it may be unsubstituted.

Examples of the substituent include a monovalent non-metal atomic group excluding a hydrogen atom, and for example, the following substituent group T can be selected.

### Substituent T

Examples of the substituent T include halogen atoms such as a fluorine atom, a chlorine atom, a bromine atom, and an iodine atom; alkoxy group such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and tert-butylsulfanyl group; arylsulfanyl groups such as a phenylsulfanyl group and a p-tolylsulfanyl group; an alkyl group; a cycloalkyl group; an aryl group; a heteroaryl group; a hydroxyl group; a carboxy group; a formyl group; a sulfo group; a cyano group; an alkylaminocarbonyl group; an arylaminocarbonyl group; a sulfonamide group; a silyl group; an amino group; a monoalkylamino group; a dialkylamino group; an arylamino group; and combinations thereof.

In the present specification, unless otherwise specified, the weight-average molecular weight (Mw) and the number-average molecular weight (Mn) are values calculated in terms of polystyrene by gel permeation chromatography (GPC).

The measurement by GPC is carried out under the following conditions.
[Eluent] tetrahydrofuran (THF)
[Device name] EcoSEC HLC-8320GPC (manufactured by Tosoh Corporation)
[Column] TSKgel SuperHZM-H, TSKgel SuperHZ4000, TSKgel SuperHZ200 (manufactured by Tosoh Corporation)
[Column temperature] 40° C.
[Flow rate] 0.35 ml/min

In the present specification, unless otherwise specified, the molecular weight of a compound having a molecular weight distribution is the weight-average molecular weight (Mw).

In the present specification, unless otherwise specified, the room temperature is 25° C.

In the present specification, “alkali-soluble” means that the solubility in 100 g of an aqueous solution of 1% by mass sodium carbonate at 22° C. is 0.1 g or more. As a result, for example, the alkali-soluble resin is intended to be a resin that satisfies the above-described solubility conditions.

In the present specification, “water-soluble” means that the solubility in 100 g of water having a liquid temperature of 22° C. and a pH of 7.0 is 0.1 g or more. As a result, for example, the water-soluble resin is intended to be a resin that satisfies the above-described solubility conditions.

In the present specification, the “solid content” of the composition means a component that forms a composition layer formed of the composition, and in a case where the composition contains a solvent (an organic solvent, water, or the like), the solid content means all components excluding the solvent. In addition, in a case where the components are components that form a composition layer, the components are considered to be the solid content even in a case where they are liquid components.

In the present specification, the layer thickness (the film thickness) of each layer included in a transfer film or the like is measured by observing a cross section of a layer (a film) in a direction perpendicular to the layer (film) with a scanning electron microscope (SEM), measuring the thickness of each layer at 10 points or more based on the obtained observation image, and calculating the average value thereof.

A transfer film according to the embodiment of the present invention includes a temporary support and a composition layer disposed on the temporary support,
in which the composition layer includes a photosensitive resin layer and a water-soluble resin layer,
where the transfer film is obtained by laminating the temporary support, the water-soluble resin layer, and the photosensitive resin layer in this order or obtained by laminating the temporary support, the photosensitive resin layer, and the water-soluble resin layer in this order.

In addition, the water-soluble resin layer contains a compound A having a group represented by General Formula (1) (hereinafter, abbreviated as a “compound A”).

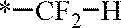

In the formula, * represents a bonding position.

That is, the transfer film according to the embodiment of the present invention has a configuration in which the transfer film of the present invention includes a temporary support and a composition layer disposed on the temporary support, in which the composition layer includes a photosensitive resin layer and a water-soluble resin layer, where the transfer film is obtained by laminating the temporary support, the water-soluble resin layer, and the photosensitive resin layer in this order, and the water-soluble resin layer contains the compound A (hereinafter, also referred to as “the transfer film of the first aspect”), or the transfer film according to the embodiment of the present invention has a configuration in which the transfer film according to the embodiment of the present invention includes a temporary support and a composition layer disposed on the temporary support, in which the composition layer includes a photosensitive resin layer and a water-soluble resin layer, where the transfer film is obtained by laminating the temporary support, the photosensitive resin layer, and the water-soluble resin layer in this order, and the water-soluble resin layer contains the compound A (hereinafter, also referred to as “the transfer film of the second aspect”).

According to the transfer film of the first aspect, it is possible to form a resist pattern having excellent resolution, and according to the transfer film of the second aspect, it is possible to form a resin pattern having excellent planarity.

The mechanism by which the objects of the present invention are achieved by such configurations is not clear; however, the inventors of the present invention presume as follows.

The inventors of the present invention conceive that in the transfer film having a temporary support, a photosensitive resin layer, and a water-soluble resin layer containing the compound A, the compound A functions to suppress the occurrence of film thickness unevenness of the water-soluble resin layer. As a result, in a case where a resist pattern is formed by using the transfer film of the first aspect, it is possible to suppress the peeling of the protruding part and/or the residue of the recessed part of the pattern, which may occur due to the film thickness unevenness. That is, according to the transfer film of the first aspect, it is possible to form a resist pattern having excellent resolution. In addition, in a case where a resin pattern is formed by using the transfer film of the second aspect, it is possible to suppress optical unevenness (surface defects) which may occur due to film thickness unevenness. That is, according to the transfer film of the second aspect, it is possible to form a film (for example, a cured film such as a wire protective film) having excellent planarity.

It is noted that hereinafter, the fact that a resist pattern having excellent resolution can be formed and/or the fact that a resin pattern having excellent planarity can be formed may be referred to as “the effect of the present invention is excellent”.

In addition, it has been revealed that in a case where the compound A is a low-molecular-weight compound A that has a molecular weight of 2,000 or less and is represented by General Formula (6B) described later, or it is a high-molecular-weight compound A that has a weight-average molecular weight of more than 2,000 and 15,000 or less and contains a constitutional unit represented by General Formula (4) described later and a constitutional unit represented by General Formula (5) described later, the effect of the present invention is more excellent.

The photosensitive resin layer may be a negative tone photosensitive resin layer or may be a chemical amplification type photosensitive resin layer; however, it is preferably a negative tone photosensitive resin layer.

In addition, the composition layer may include another layer other than the photosensitive resin layer and the water-soluble resin layer. Examples of the other layer include a thermoplastic resin layer.

Hereinafter, an example of the aspect of the transfer film according to the embodiment of the present invention will be shown, which is not limited thereto. It is noted that the following (1) and (3) correspond to an example of the transfer film of the first aspect, and the following (2) corresponds to an example of the transfer film of the second aspect.
(1) “Temporary support / thermoplastic resin layer / interlayer (water-soluble resin layer) / negative tone photosensitive resin layer / cover film”
(2) “Temporary support / negative tone photosensitive resin layer / refractive index adjusting layer (water-soluble resin layer) / cover film”
(3) “Temporary support/ interlayer (water-soluble resin layer) / negative tone photosensitive resin layer / cover film”

It is noted that in each of the above configurations, it is also preferable that the negative tone photosensitive resin layer is a coloration resin layer.

Hereinafter, the transfer film of the first aspect and the transfer film of the second aspect described above will be individually described.

### Transfer Film of First Aspect

Hereinafter, an example according to the embodiment of the transfer film of the first aspect will be described.

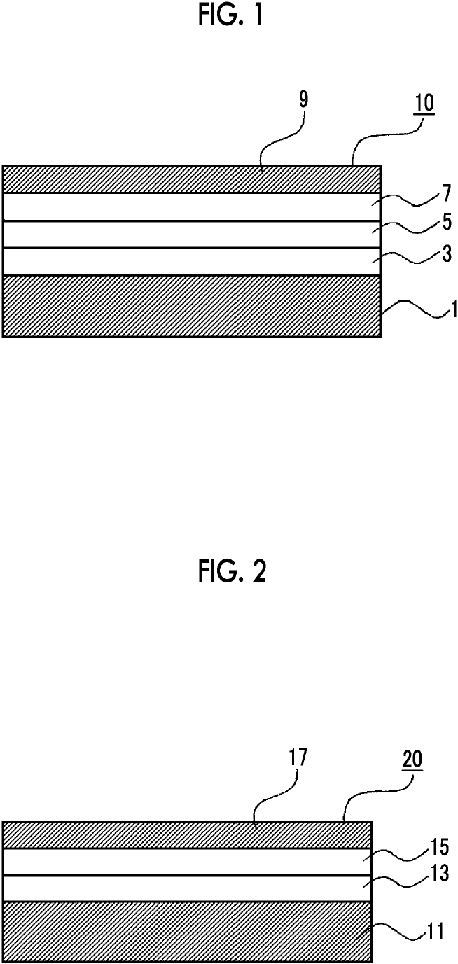

A transfer film 10 illustrated in FIG. 1 includes a temporary support 1, a thermoplastic resin layer 3, a water-soluble resin layer 5, a photosensitive resin layer 7, and a cover film 9 in this order.

It is noted that although the transfer film 10 illustrated in FIG. 1 has a form in which the cover film 9 is disposed, the cover film 9 may not be disposed.

In addition, although the transfer film 10 illustrated in FIG. 1 has a form in which the thermoplastic resin layer 3 is disposed, the thermoplastic resin layer 3 may not be disposed.

Hereinafter, each element that constitutes the transfer film will be described.

### Temporary Support

The transfer film of the first aspect has a temporary support.

The temporary support is a support that supports a plurality of composition layers (for example, a photosensitive resin layer, a water-soluble resin layer, or a thermoplastic resin layer corresponds to the composition layer), which are disposed on the temporary support, and can be peeled off from these composition layers.

The temporary support preferably has light transmittance from the viewpoint that exposure through a temporary support is possible in a case where the composition layer is subjected to pattern exposure. In addition, in this specification, “having light transmittance” means that the light transmittance at the wavelength used for pattern exposure is 50% or more.

From the viewpoint of improving exposure sensitivity, the temporary support preferably has a light transmittance of 60% or more and more preferably 70% or more at the wavelength (more preferably 365 nm) used for pattern exposure.

The light transmittance of the layer included in the transfer film is a rate of the intensity of the emitted light that has emitted and passed through a layer with respect to the intensity of the incident light in a case where the light is incident in a direction perpendicular to the main surface of the layer (the thickness direction), and it is measured by using MCPD Series manufactured by Otsuka Electronics Co., Ltd.

Examples of the material that constitutes the temporary support include a glass substrate, a resin film, and paper, and a resin film is preferable from the viewpoints of hardness, flexibility, and light transmittance.

Examples of the resin film include a polyethylene terephthalate (PET) film, a cellulose triacetate film, a polystyrene film, and a polycarbonate film. Among them, a PET film is preferable, and a biaxially stretched PET film is more preferable.

The thickness (the layer thickness) of the temporary support is not particularly limited, and it may be selected depending on the material from the viewpoints of the hardness as a support, the flexibility required for affixing to a substrate for forming a circuit wire, and the light transmittance required in the first exposure step.

The thickness of the temporary support is preferably 5 to 100 µm, more preferably 10 to 50 µm, still more preferably 10 to 20 µm, and particularly preferably 10 to 16 µm, from the viewpoints of ease of handling and general-purpose property.

In addition, it is preferable that the film to be used as the temporary support does not have deformation such as wrinkles, scratches, and defects.

From the viewpoint of pattern forming properties during pattern exposure through the temporary support and transparency of the temporary support, it is preferable that the number of fine particles, foreign substances, defects, and precipitates included in the temporary support is small. The number of fine particles having a diameter of 1 µm or more, foreign substances, and defects is preferably 50 pieces/10 mm² or less, more preferably 10 pieces/10 mm² or less, still more preferably 3 pieces/10 mm² or less, and particularly preferably 0 pieces/10 mm².

Preferred aspects of the temporary support are described in, for example, paragraph 0017 and paragraph 0018 of JP2014-085643A, paragraphs 0019 to 0026 of JP2016-027363A, paragraphs 0041 to 0057 of WO2012/081680A1, paragraphs 0029 to 0040 of WO2018/179370A1, and paragraph 0012 to paragraph 0032 of JP2019-101405A, the contents of these publications are incorporated in the present specification.

### Cover Film

It is preferable that the transfer film has a cover film that is in contact with the outermost surface of the composition layer that is farthest from the temporary support among the plurality of composition layers disposed on the temporary support.

Examples of the material that constitutes the cover film include a resin film and paper, where a resin film is preferable from the viewpoints of hardness and flexibility.

Examples of the resin film include a polyethylene film, a polypropylene film, a polyethylene terephthalate film, a cellulose triacetate film, a polystyrene film, and a polycarbonate film. Among them, a polyethylene film, a polypropylene film, or a polyethylene terephthalate film is preferable.

The thickness (the layer thickness) of the cover film is not particularly limited; however, it is preferably 5 to 100 µm and more preferably 10 to 50 µm.

In addition, the arithmetic average roughness Ra value of the surface of the cover film in contact with the composition layer (hereinafter, also simply referred to as “the surface of the cover film”) is preferably 0.3 µm or less, more preferably 0.1 µm or less, and still more preferably 0.05 µm or less since the resolution is more excellent. This is conceived to be because in a case where the Ra value on the surface of the cover film is in the above range, the uniformity of the layer thickness of the resin pattern to be formed is improved.

The lower limit of the Ra value of the surface of the cover film is not particularly limited; however, it is preferably 0.001 µm or more.

The Ra value of the surface of the cover film is measured by the following method.

Using a three-dimensional optical profiler (New View7300, manufactured by Zygo Corporation), the surface of the cover film is measured under the following conditions to obtain a surface profile of the optical film.

As the measurement and analysis software, Microscope Application of MetroPro ver. 8.3.2 is used. Next, the Surface Map screen is displayed with the above analysis software, and the histogram data is obtained in the Surface Map screen. From the obtained histogram data, the arithmetic average roughness is calculated, and the Ra value of the surface of the cover film is obtained.

In a case where the cover film is affixed to the transfer film, the cover film may be peeled from the transfer film to measure the Ra value of the surface on which the peeling has been carried out.

### Water-Soluble Resin Layer

In the transfer film 10, since the water-soluble resin layer 5 is present between the thermoplastic resin layer 3 and the photosensitive resin layer 7, It is possible to suppress the mixing of components, which may occur in a case of the coating formation of the thermoplastic resin layer 3 and the photosensitive resin layer 7 and in a case of storing after the coating formation. That is, as one aspect of the transfer film of the first aspect, the water-soluble resin layer can function as a layer (an interlayer) for suppressing interlayer mixing between a layer disposed on one surface side of the water-soluble resin layer and a layer disposed on the other surface side thereof.

The water-soluble resin layer 5 contains the compound A and a resin. The resin includes a water-soluble resin as a part or the whole thereof. As defined above, the “water-soluble resin” means a resin having a solubility of 0.1 g or more in 100 g of water having a liquid temperature of 22° C. and a pH of 7.0.

Hereinafter, each component that can be contained in the water-soluble resin layer will be described.

### Compound A

The water-soluble resin layer contains the compound A.

The compound A is a compound having a group represented by General Formula (1).

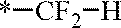

in the formula, * represents a bonding position.

The compound A may be a high-molecular-weight compound or may be a low-molecular-weight compound. In a case where the compound A is a high-molecular-weight compound, the compound A which is a high-molecular-weight compound may be referred to as a “high-molecular-weight compound A”. In addition, in a case where the compound A is a low-molecular-weight compound, the compound A which is a low-molecular-weight compound may be referred to as a “low-molecular-weight compound A”.

The lower limit value of the weight-average molecular weight of the high-molecular-weight compound A is preferably 1,000 or more, more preferably 1,500 or more, still more preferably more than 2,000, and particularly preferably 5,000 or more. In addition, the upper limit value thereof is preferably 100,000 or less, more preferably 80,000 or less, still more preferably 60,000 or less, still more preferably 40,000 or less, particularly preferably 20,000 or less, and most preferably 15,000 or less.

The number-average molecular weight (Mn) of the high-molecular-weight compound A is preferably 500 to 40,000, more preferably 600 to 20,000, and still more preferably 600 to 10,000.

The dispersivity (Mw/Mn) of the high-molecular-weight compound A is preferably 1.00 to 12.00, more preferably 1.00 to 11.00, and still more preferably 1.00 to 10.00.

The high-molecular-weight compound A preferably contains a constitutional unit having a group represented by General Formula (1).

The molecular weight of the low-molecular-weight compound A is preferably 100 or more and more preferably 500 or more. The upper limit of the molecular weight of the low-molecular-weight compound A is preferably 5,000 or less, more preferably 3,000 or less, and still more preferably 2,000 or less.

The number of groups represented by General Formula (1) in the low-molecular-weight compound A is not particularly limited as long as it is 1 or more; however, it is, for example, preferably 1 to 3.

Specific aspects of the high-molecular-weight compound A and the low-molecular-weight compound A will be described in the latter part.

In addition, from the viewpoint that the effect according to the embodiment of the present invention is more excellent, the compound A is preferably a compound having a group represented by General Formula (2) described later (hereinafter, also referred to as a “compound Aa”), and it is more preferably a compound having a group represented by General Formula (3) (hereinafter, also referred to as a “Compound Ab”) described later.

It is noted that the compound Aa corresponds to a compound in which the linking form of the group represented by General Formula (1) in the compound A is further limited. That is, —CF₂—H present at the terminal portion of the group represented by General Formula (2) in the compound Aa corresponds to the group represented by General Formula (1) described above. In addition, the compound Ab is intended to be a compound in which the linking form of the group represented by General Formula (1) in the compound A and the linking form of the group represented by General Formula (2) in the compound Aa are further limited. That is, —CF₂—H present at the terminal portion of the group represented by General Formula (3) in the compound Ab corresponds to the group represented by General Formula (1) described above, and —CF₂—CF₂—H present at the terminal portion of the group represented by General Formula (3) in the compound Ab corresponds to the group represented by General Formula (2) described above.

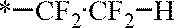

in the formula, * represents a bonding position.

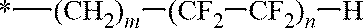

in the formula, m and n each independently represent an integer of 1 to 6, and
m is preferably 1 to 4 and more preferably 1 or 2.
n is preferably 1 to 4 and more preferably 2 or 3.
* represents a bonding position.

Hereinafter, the high-molecular-weight compound A and the low-molecular-weight compound A will be described.

### High-Molecular-Weight Compound A

As described above, the high-molecular-weight compound A is an aspect of the compound A in a case where it is a high-molecular-weight compound. The suitable aspects of the weight-average molecular weight and the dispersivity of the high-molecular-weight compound A are as described above.

The high-molecular-weight compound A preferably contains a constitutional unit having a group represented by any one of General Formulae (1) to (3) described above, more preferably contains a constitutional unit derived from a monomer represented by General Formula (4) described later, and still more preferably contains a constitutional unit derived from a monomer represented by General Formula (4A) described later. It is noted that the constitutional unit derived from a monomer represented by General Formula (4) described later corresponds to the constitutional unit having a group represented by General Formula (1) or (2) described above, and the constitutional unit derived from a monomer represented by General Formula (4A) described later corresponds to the constitutional unit having a group represented by General Formula (3) described above.

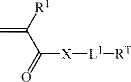

In General Formula (4), R¹ represents a hydrogen atom or a methyl group. X represents an oxygen atom, a sulfur atom, or —N(R²)—. R² represents a hydrogen atom or an alkyl group having 1 to 4 carbon atoms. L¹ represents a divalent linking group. R^{T} represents the group represented by General Formula (1) or (2) described above.

The alkyl group having 1 to 4 carbon atoms, which is represented by R², may be either linear or branched.

R¹ is preferably a hydrogen atom.

R² is preferably a hydrogen atom or an alkyl group having 1 or 2 carbon atoms and more preferably an alkyl group having 1 or 2 carbon atoms.

X is preferably an oxygen atom.

The divalent linking group represented by L¹ is not particularly limited. However, examples thereof include —O—, —CO—, —S—, —SO₂—, —NR^{X}— (R^{X} is a hydrogen atom or a substituent), an alkylene group, an alkenylene group, an alkynylene group, an aromatic ring group, an alicyclic group, and a group obtained by combining these. The substituent represented by R^{X} is not particularly limited, and examples thereof include the substituents exemplified in the substituent group T, where an alkyl group having 1 or 2 carbon atoms is preferable.

The alkylene group, the alkenylene group, the alkynylene group, the aromatic ring group, and the alicyclic group may further have a substituent. The substituent is not particularly limited, and examples thereof include the substituents exemplified in the substituent group T. Among them, the substituent is preferably a halogen atom and more preferably a fluorine atom.

The alkylene group, the alkenylene group, and the alkynylene group may be linear or branched.

In addition, the alkylene group preferably has 1 to 20 carbon atoms, more preferably 1 to 15 carbon atoms, still more preferably 1 to 11 carbon atoms, and particularly preferably 1 to 10 carbon atoms.

In addition, the alkenylene group and the alkynylene group preferably have 2 to 20 carbon atoms, more preferably 2 to 15 carbon atoms, still more preferably 2 to 11 carbon atoms, and particularly preferably 2 to 10 carbon atoms.

The aromatic ring group may be any one of an aromatic hydrocarbon ring group or an aromatic heterocyclic group.

The aromatic ring that constitutes the aromatic ring group may be a monocyclic ring or a polycyclic ring. The number of ring members of the aromatic ring that constitutes the aromatic ring group is not particularly limited; however, it is, for example, 5 to 15. In addition, the number of heteroatoms contained in the aromatic heterocyclic group is not particularly limited, and it is, for example, preferably 1 to 3 heteroatom atoms. The kind of heteroatom is not particularly limited; however, examples thereof include a nitrogen atom, an oxygen atom, and a sulfur atom.

Examples of the kind of the aromatic ring that constitutes the aromatic ring group include aromatic hydrocarbon rings such as a benzene ring, a naphthalene ring, an anthracene ring, and a phenanthroline ring; and aromatic heterocyclic rings such as a furan ring, a pyrrole ring, a thiophene ring, a pyridine ring, a thiazole ring, and a benzothiazole ring.

The alicyclic group may be any one of an aliphatic hydrocarbon ring group or an aliphatic heterocyclic group.

The alicyclic ring that constitutes the alicyclic group may be monocyclic or polycyclic. The number of ring members of the alicyclic ring that constitutes the alicyclic group is not particularly limited; however, it is, for example, 5 to 15. In addition, the number of heteroatoms contained in the aliphatic heterocyclic group is not particularly limited, and it is, for example, preferably 1 to 3 heteroatom atoms. The kind of heteroatom is not particularly limited; however, examples thereof include a nitrogen atom, an oxygen atom, and a sulfur atom.

Examples of the alicyclic ring that constitutes the alicyclic group include cycloalkane rings such as a cyclopropane ring, a cyclobutane ring, a cyclopentane ring, a cyclohexane ring, a cyclooctane ring, a cyclodecane ring, an adamantane ring, a norbornane ring, and an exo-tetrahydrodicyclopentadiene ring, as well as a cyclohexene ring.

Among them, the divalent linking group represented by L¹ is preferably an alkylene group-*^{B} which may be substituted with an *^{A}-fluorine atom, an alkenylene group-*^{B} which may be substituted with an *^{A}-fluorine atom, or an alkynylene group-*^{B} which may be substituted with an *^{A}-fluorine atom, and it is more preferably an alkylene group-*^{B} which may be substituted with an *^{A}-fluorine atom. It is noted that *^{A} represents a linking position to X in General Formula (4), and *^{B} represents a linking position to R^{T} in General Formula (4).

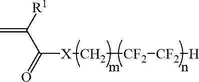

In General Formula (4A), R¹ and X have the same meanings as R¹ and X in General Formula (4), respectively, and the same applies to the preferred aspects thereof.

m and n each independently represent an integer of 1 to 6, and m is preferably 1 to 4 and more preferably 1 or 2. n is preferably 1 to 4 and more preferably 2 or 3.

In the high-molecular-weight compound A, the lower limit value of the content of the constitutional unit having the group represented by any one of General Formulae (1) to (3) is preferably 2% by mass or more, more preferably 3% by mass or more, and still more preferably 5% by mass or more, with respect to the total mass of the high-molecular-weight compound A. In addition, the upper limit value thereof is preferably 100% by mass or less, more preferably 90% by mass, and still more preferably 80% by mass.

One kind of the constitutional unit having a group represented by any one of General Formulae (1) to (3) may be used alone, or two or more kinds thereof may be used.

The constitutional unit having a group represented by any one of General Formulae (1) to (3) can be synthesized by a known method.

The high-molecular-weight compound A may have a constitutional unit other than the constitutional unit having a group represented by any one of General Formulae (1) to (3) (hereinafter, also referred to as the “other constitutional unit”).

The other constitutional unit is not particularly limited. However, it is preferable to include a constitutional unit having a poly(oxyalkylene) structure from the viewpoint that the effect of the present invention is more excellent.

The poly(oxyalkylene) structure is preferably a structure represented by General Formula (PAL).

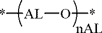

In General Formula (PAL), nAL represents an integer of 2 or more, where it is more preferably 2 to 100, still more preferably 4 to 20, particularly preferably 4 to 15, and most preferably 4 to 12.

AL represents an alkylene group. The alkylene group may be linear or branched. The alkylene group represented by AL preferably has 1 to 10 carbon atoms, more preferably 1 to 6 carbon atoms, still more preferably 2 to 4 carbon atoms, and particularly preferably 2 or 3 carbon atoms.

The nAL pieces of AL’s may be the same or different from each other.

Further, the alkylene group represented by AL may have a substituent. The substituent is not particularly limited, and examples thereof include the substituents exemplified in the substituent group T.

Among them, AL is preferably —CH₂CH₂—, —CH₂CH₂CH₂—, —CH(CH₃)CH₂—, or —CH(CH₂CH₃)CH₂—, and it is more preferably —CH(CH₃)CH₂— or —CH₂CH₂CH₂—.

* represents a bonding position.

The constitutional unit having a poly(oxyalkylene) structure is preferably a constitutional unit having a poly(oxyalkylene) structure in a side chain, and it is more preferably a constitutional unit derived from a monomer represented by General Formula (5) described later.

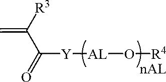

In the formula, R³ represents a hydrogen atom or a methyl group. Y represents an oxygen atom, a sulfur atom, or —N(R⁵)—. AL represents an alkylene group which may have a substituent. nAL represents an integer of 2 or more. R⁴ represents a hydrogen atom or a substituent, and R⁵ represents a hydrogen atom or an alkyl group having 1 to 4 carbon atoms.

AL and nAL in General Formula (5) have the same meanings as AL and nAL in General Formula (PAL), respectively, and the same applies to the preferred aspects thereof.

The substituent represented by R⁴ is not particularly limited, and examples thereof include the substituents exemplified in the substituent group T, where an alkyl group having 1 to 6 carbon atoms is preferable.

The alkyl group having 1 to 4 carbon atoms, which is represented by R⁵, may be either linear, branched, or cyclic.

R³ and R⁴ are preferably a hydrogen atom.

R⁵ is preferably a hydrogen atom or an alkyl group having 1 or 2 carbon atoms and more preferably an alkyl group having 1 or 2 carbon atoms.

Y is preferably an oxygen atom.

In a case where the high-molecular-weight compound A contains a constitutional unit having a poly(oxyalkylene) structure, the content thereof is preferably 10% by mass or more, more preferably 20% by mass or more, and still more preferably 50% by mass or more, with respect to the total mass of the high-molecular-weight compound A. In addition, the upper limit value thereof is preferably 95% by mass or less and more preferably 90% by mass or less.

One kind of constitutional unit having a poly(oxyalkylene) structure may be used alone, or two or more kinds thereof may be used.

In addition to the above-described constitutional units, the constitutional unit which can be contained in the high-molecular-weight compound A is, for example, preferably a constitutional unit derived from a (meth)acrylic acid ester or a constitutional unit derived from (meth)acrylic acid.

Examples of the (meth)acrylic acid ester include a (meth)acrylic acid alkyl ester having 1 to 18 carbon atoms in an alkyl group. Specific examples thereof include methyl (meth)acrylate, ethyl (meth)acrylate, n-butyl (meth)acrylate, isobutyl (meth)acrylate, 2-ethylhexyl (meth)acrylate, lauryl (meth)acrylate, and stearyl (meth)acrylate.

In a case where the high-molecular-weight compound A contains a constitutional unit selected from the group consisting of a constitutional unit derived from a (meth)acrylic acid ester and a constitutional unit derived from (meth)acrylic acid, the content thereof is preferably 10% by mass or more, more preferably 20% by mass or more, and still more preferably 30% by mass or more, with respect to the total mass of the high-molecular-weight compound A. In addition, the upper limit value thereof is preferably 90% by mass or less, more preferably 80% by mass or less, and still more preferably 70% by mass or less.

In a case where the high-molecular-weight compound A is a copolymer, it is also preferable that the high-molecular-weight compound A has a block structure, a graft structure, a branch structure, and/or a star structure.

Various monomers that constitute the high-molecular-weight compound A and the high-molecular-weight compound A can be produced according to known methods.

### Low-Molecular-Weight Compound A

As described above, the low-molecular-weight compound A is an aspect of the compound A in a case where it is a low-molecular-weight compound. The suitable aspect of the molecular weight of the low-molecular-weight compound A is as described above.

The low-molecular-weight compound A is preferably a compound having a group represented by any one of General Formulae (1) to (3) described above, more preferably a compound represented by (6) described later, still more preferably a compound represented by General Formula (6A) described later, and particularly preferably a compound represented by General Formula (6B) described later. It is noted that a compound represented by General Formula (6) described later corresponds to a compound having the group represented by General Formula (1) or (2) described above, and a compound represented by General Formula (6A) or (6B) described later corresponds to a compound having the group represented by General Formula (3) described above.

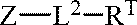

In General Formula (6), Z represents a monovalent organic group. L² represents a single bond or a divalent linking group, and R^{T} represents the group represented by General Formula (1) or (2) described above.

The monovalent organic group represented by Z is not particularly limited; however, examples thereof include an alkyl group, an alkenyl group, and an alkynyl group, which may have a heteroatom (it is noted that the heteroatom may be contained as —O—, —CO—, —S—, —SO₂, or -NR^{X}- (R^{X} is a hydrogen atom or a substituent)). The substituent represented by R^{X} is not particularly limited, and examples thereof include the substituents exemplified in the substituent group T.

The alkyl group, the alkenyl group, and the alkynyl group may further have a substituent. The substituent is not particularly limited, and examples thereof include the substituents exemplified in the substituent group T.

The alkyl group, the alkenyl group, and the alkynyl group may be linear, branched, or cyclic.

In addition, the number of carbon atoms of the alkyl group is not particularly limited. However, it is, for example, 1 to 40, and it is preferably 1 to 30 and more preferably 1 to 20.

In addition, the numbers of carbon atoms of the alkenyl group and the alkynyl group are not particularly limited. However, they are, for example, 2 to 40, and they are preferably 2 to 30 and more preferably 2 to 20.

Among the above, Z is preferably a monovalent organic group having a poly(oxyalkylene) structure. The poly(oxyalkylene) structure is preferably a structure represented by General Formula (PAL).

It is noted that the atom of Z at the linking position to L² in General Formula (6) is preferably a carbon atom.

Examples of the divalent linking group represented by L² include the same one as the divalent linking group represented by L¹ in General Formula (4) described above.

Among them, the divalent linking group represented by L² is preferably an alkylene group-*^{B} which may be substituted with an *^{A}-L²¹-fluorine atom, an alkenylene group-*^{B} which may be substituted with an *^{A}-L²¹-fluorine atom, or an alkynylene group-*^{B} which may be substituted with an *^{A}-L²¹-fluorine atom, and it is more preferably an alkylene group-*^{B} which may be substituted with an *^{A}-L²¹-fluorine atom.

L²¹ represents —O—, —CO—, —S—, —SO₂—, —NR^{X}— (R^{X} is a hydrogen atom or a substituent), or a group obtained by combining these. The substituent represented by R^{X} is not particularly limited, and examples thereof include the substituents exemplified in the substituent group T, where an alkyl group having 1 or 2 carbon atoms is preferable. Among the above, L²¹ is preferably —O—, —S—, or —NR^{X}—, and it is more preferably —O—.
*^{A} represents a linking position to Z in General Formula (6), and *^{B} represents a linking position to R^{T} in General Formula (6).

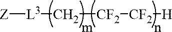

In the formula, Z represents a monovalent organic group. L³ represents an oxygen atom, a sulfur atom, or —N(R⁶)—. m and n each independently represent an integer of 1 to 6, and R⁶ represents a hydrogen atom or an alkyl group having 1 to 4 carbon atoms.

Examples of the monovalent organic group represented by Z in General Formula (6A) include the same one as the monovalent organic group represented by Z in General Formula (6), and the same applies to the preferred aspect thereof.

The alkyl group having 1 to 4 carbon atoms, which is represented by R⁶, may be either linear, branched, or cyclic.

L³ is preferably an oxygen atom.

m is preferably 1 to 4 and more preferably 1 or 2.

n is preferably 1 to 4 and more preferably 2 or 3.

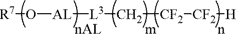

AL and nAL in General Formula (6B) have the same meanings as AL and nAL in General Formula (PAL), respectively, and the same applies to the preferred aspects thereof.

L³, m, and n in General Formula (6B) have the same meanings as L³, m, and n in General Formula (6A), respectively, and the same applies to the preferred aspects thereof.

In General Formula (6B), R⁷ represents a hydrogen atom or a substituent.

The substituent represented by R⁷ is not particularly limited, and examples thereof include the substituents exemplified in the substituent group T, where an alkyl group having 1 to 6 carbon atoms is preferable.

R⁷ is preferably a hydrogen atom.

The low-molecular-weight compound A can be produced according to a known method.

Hereinafter, specific examples of the compound A will be shown; however, the compound A in the present invention is not limited thereto.

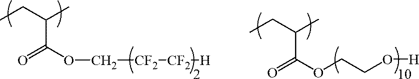

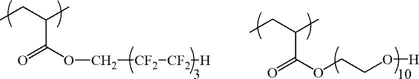

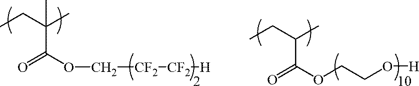

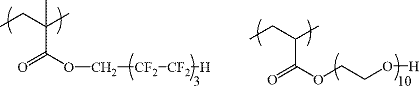

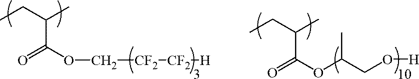

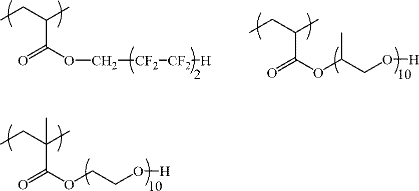

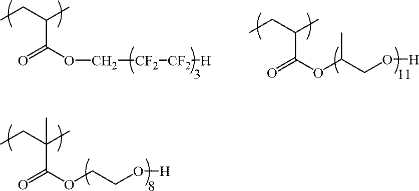

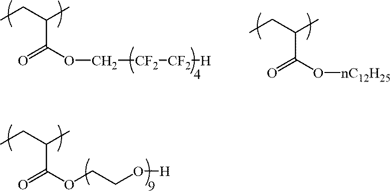

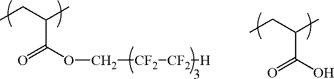

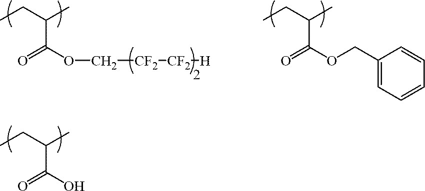

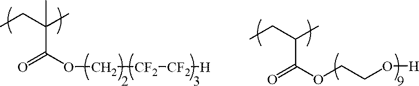

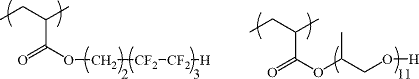

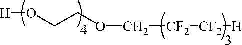

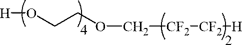

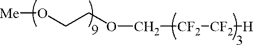

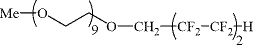

In a case where the compound A includes the high-molecular-weight compound A, one kind of the high-molecular-weight compound A may be used alone, or two or more kinds thereof may be used.

In a case where the compound A includes the low-molecular-weight compound A, one kind of the low-molecular-weight compound A may be used alone, or two or more kinds thereof may be used.

In the water-soluble resin layer, the compound A may have any form of a form in which only the high-molecular-weight compound A is used, a form in which only the low-molecular-weight compound A is used, or a form in which the high-molecular-weight compound A and the low-molecular-weight compound A are used in combination.

The content of the compound A (the total content thereof, in a case where a plurality of kinds thereof are contained) is preferably 0.001% to 10% by mass, more preferably 0.01% to 3% by mass, and still more preferably 0.02 to 1% by mass, with respect to the total mass of the water-soluble resin layer.

### Resin

The water-soluble resin layer contains a resin.

As described above, the resin includes a water-soluble resin as a part or the whole thereof.

Examples of the resin capable of being used as the water-soluble resin include resins such as a polyvinyl alcohol-based resin, a polyvinyl pyrrolidone-based resin, a cellulose-based resin, an acrylamide-based resin, a polyethylene oxide-based resin, gelatin, a vinyl ether-based resin, a polyamide resin, and a copolymer thereof.

In addition, as the water-soluble resin, a copolymer of (meth)acrylic acid and a vinyl compound, or the like can also be used. The copolymer of (meth)acrylic acid and a vinyl compound is preferably a copolymer of (meth)acrylic acid and allyl (meth)acrylate, and more preferably a copolymer of methacrylate and allyl methacrylate.

In a case where the water-soluble resin is a copolymer of (meth)acrylic acid and a vinyl compound, the compositional ratio (mol%) thereof is, for example, preferably 90/10 to 20/80 and more preferably 80/20 to 30/70.

The lower limit value of the weight-average molecular weight of the water-soluble resin is preferably 5,000 or more, more preferably 7,000 or more, and still more preferably more than 10,000. Further, the upper limit value thereof is preferably 200,000 or less, more preferably 100,000 or less, and still more preferably 50,000 or less.

The dispersivity (Mw/Mn) of the water-soluble resin is preferably 1 to 10 and more preferably 1 to 5.

From the viewpoint of further improving the ability to suppress interlayer mixing of the water-soluble resin layer, the resin in the water-soluble resin layer is preferably a resin different from a resin contained in a layer disposed on one surface side of the water-soluble resin layer and a resin contained in a layer disposed on the other surface side of the water-soluble resin layer. For example, in a case where the photosensitive resin layer 7 contains the polymer A described later and the thermoplastic resin layer 3 contains a thermoplastic resin (an alkali-soluble resin) described later, the resin of the water-soluble resin layer 5 is preferably a resin which is different from the polymer A and the thermoplastic resin (the alkali-soluble resin).

From the viewpoint of further improving the oxygen blocking properties and the ability to suppress interlayer mixing, the water-soluble resin preferably contains polyvinyl alcohol, and more preferably contains both polyvinyl alcohol and polyvinylpyrrolidone.

One kind of water-soluble resin may be used alone, or two or more kinds thereof may be used.

The content of the water-soluble resin is not particularly limited. However, from the viewpoint of further improving the oxygen blocking properties and the ability to suppress interlayer mixing, it is preferably 50% by mass or more, more preferably 70% by mass or more, still more preferably 80% by mass or more, and particularly preferably 90% by mass or more with respect to the total mass of the water-soluble resin layer. The upper limit value thereof is not particularly limited; however, it is, for example, preferably 99.9% by mass or less and more preferably 99.8% by mass or less.

The layer thickness of the water-soluble resin layer is not particularly limited; however, it is preferably 0.1 to 5 µm and more preferably 0.5 to 3 µm. In a case where the thickness of the water-soluble resin layer is within the above-described range, the oxygen blocking properties are not deteriorated, and the ability to suppress interlayer mixing is excellent. Further, it is possible to suppress an increase in the time for removing the water-soluble resin layer at the time of development.

### Photosensitive Resin Layer

In a display device (an organic electroluminescence (EL) display device, a liquid crystal display device, or the like) that includes a touch panel such as a capacitive input device, an electrode pattern corresponding to a sensor of a visual recognition part and a conductive layer pattern of a wire or the like of a peripheral wiring portion or a lead-out wiring portion are provided inside the touch panel. Generally, a method of providing a negative tone photosensitive resin layer (a photosensitive layer) on a substrate using a transfer film or the like, subjecting the photosensitive layer to exposure through a mask having a desired pattern, and then carrying out development is widely employed for forming a patterned layer. As a result, the photosensitive resin layer is preferably a negative tone photosensitive resin layer.

In a case where the photosensitive resin layer is a negative tone photosensitive resin layer, the negative tone photosensitive resin layer preferably contains a resin, a polymerizable compound, and a polymerization initiator. In addition, in a case where the photosensitive resin layer is a negative tone photosensitive resin layer, it is also preferable that an alkali-soluble resin (a polymer A or the like which is an alkali-soluble resin) is contained as a part or the whole of the resin, as will described later. That is, in one aspect, it is preferable that the photosensitive resin layer contains a resin including an alkali-soluble resin, a polymerizable compound, and a polymerization initiator.

Such a photosensitive resin layer (a negative tone photosensitive resin layer) preferably contains, in terms of the total mass of the photosensitive resin layer; a resin of 10% to 90% by mass, a polymerizable compound of 5% to 70% by mass, and polymerization initiator of 0.01% to 20% by mass.

Hereinafter, each component will be described in order.

### Polymer A (Resin)

In a case where the photosensitive resin layer is a negative tone photosensitive resin layer, the resin contained in the photosensitive resin layer is particularly referred to as the polymer A.

The polymer A is preferably an alkali-soluble resin.

The acid value of the polymer A is preferably 220 mgKOH/g or less, more preferably less than 200 mgKOH/g, and still more preferably less than 190 mgKOH/g, from the viewpoint of the more excellent resolution by suppressing the swelling of the negative tone photosensitive resin layer due to the developer.

The lower limit of the acid value of the polymer A is not particularly limited; however, it is preferably 60 mgKOH/g or more, more preferably 120 mgKOH/g or more, still more preferably 150 mgKOH/g or more, and particularly preferably 170 mgKOH/g or more, from the viewpoint of the more excellent developability.

It is noted that the acid value is the mass [mg] of potassium hydroxide required to neutralize 1 g of the sample, and the unit thereof is described as mgKOH/g in the present specification. The acid value can be calculated, for example, from the average content of acid groups in the compound.

The acid value of the polymer A may be adjusted according to the kind of the constitutional unit that constitutes the polymer A and the content of the constitutional unit including an acid group.

The weight-average molecular weight of the polymer A is preferably 5,000 to 500,000. A case where the weight-average molecular weight is 500,000 or less is preferable from the viewpoint of improving resolution and developability. The weight-average molecular weight is more preferably 100,000 or less and still more preferably 60,000 or less. On the other hand, a case where the weight-average molecular weight is 5,000 or more is preferable from the viewpoint of controlling property of the developed aggregate and the property of the unexposed film such as edge fuse property and cut chip property in a case of forming a negative tone photosensitive resin laminate. The lower limit of the weight-average molecular weight is more preferably 10,000 or more, still more preferably 20,000 or more, and particularly preferably 30,000 or more. The edge fuse property refers to a degree of ease with which a negative tone photosensitive resin layer protrudes from the edge face of a roll in a case of being wound backward in a roll shape as a negative tone photosensitive resin laminate. The cut chip property refers to a degree of ease of chip flying in a case where the unexposed film is cut with a cutter. In a case where this chip adheres to the upper surface of the negative tone photosensitive resin laminate or the like, it is transferred to the mask in the later exposure step or the like, which causes a defective product. The dispersivity of the polymer A is preferably 1.0 to 6.0, more preferably 1.0 to 5.0, still more preferably 1.0 to 4.0, and particularly preferably 1.0 to 3.0.

In the negative tone photosensitive resin layer, the polymer A preferably contains a constitutional unit based on a monomer having an aromatic hydrocarbon group from the viewpoint of suppressing line width thickening and deterioration of resolution in a case where the focal position has deviated during exposure. Examples of such an aromatic hydrocarbon group include a substituted or unsubstituted phenyl group and a substituted or unsubstituted aralkyl group. The content of the constitutional unit based on a monomer having an aromatic hydrocarbon group in the polymer A is preferably 20% by mass or more and more preferably 30% by mass or more with respect to the total mass of the polymer A. The upper limit thereof is not particularly limited; however, it is preferably 95% by mass or less and more preferably 85% by mass or less. In a case where a plurality of kinds of the polymer A are contained, the average value of the contents of the constitutional units based on a monomer having an aromatic hydrocarbon group is preferably within the above range.

Examples of the monomer having an aromatic hydrocarbon group include a monomer having an aralkyl group, styrene, and a polymerizable styrene derivative (for example, methyl styrene, vinyl toluene, tert-butoxy styrene, acetoxy styrene, 4-vinylbenzoic acid, a styrene dimer, or a styrene trimer). Among them, a monomer having an aralkyl group or styrene is preferable. In one aspect, in a case where the monomer component having an aromatic hydrocarbon group in the polymer A is styrene, the content of the constitutional unit based on the styrene is preferably 20% to 70% by mass, more preferably 25% to 65% by mass, still more preferably 30% to 60% by mass, and particularly preferably 30% to 55% by mass, with respect to the total mass of the polymer A.

Examples of the aralkyl group include a substituted or unsubstituted phenylalkyl group (excluding a benzyl group) and a substituted or unsubstituted benzyl group, where a substituted or unsubstituted benzyl group is preferable.

Examples of the monomer having a phenylalkyl group include phenylethyl (meth)acrylate.

Examples of the monomer having a benzyl group include (meth)acrylate having a benzyl group, for example, benzyl (meth)acrylate or chlorobenzyl (meth)acrylate; and a vinyl monomer having a benzyl group, for example, vinylbenzyl chloride or vinylbenzyl alcohol. Among them, benzyl (meth)acrylate is preferable. In one aspect, in a case where the monomer component having an aromatic hydrocarbon group in the polymer A is benzyl (meth)acrylate, the content of the constitutional unit based on the benzyl (meth)acrylate is preferably 50% to 95% by mass, more preferably 60% to 90% by mass, still more preferably 70% to 90% by mass, and particularly preferably 75% to 90% by mass, with respect to the total mass of the polymer A.

The polymer A containing a constitutional unit based on a monomer having an aromatic hydrocarbon group is preferably obtained by polymerizing a monomer having an aromatic hydrocarbon group with at least one kind of the first monomer described later and/or at least one kind of the second monomer described later.

The polymer A containing no constitutional unit based on a monomer having an aromatic hydrocarbon group is preferably obtained by polymerizing at least one kind of the first monomers described later, and more preferably obtained by copolymerizing at least one kind of the first monomer and at least one kind of the second monomer described later.

The first monomer is a monomer having a carboxy group in the molecule. Examples of the first monomer include (meth)acrylic acid, fumaric acid, cinnamic acid, crotonic acid, itaconic acid, 4-vinylbenzoic acid, a maleic acid anhydride, and a maleic acid semi-ester. Among these, (meth)acrylic acid is preferable.

The content of the constitutional unit based on the first monomer in the polymer A is preferably 5% to 50% by mass, more preferably 10% to 40% by mass, and still more preferably 15% to 30% by mass, with respect to the total mass of the polymer A.

It is preferable that the content is 5% by mass or more from the viewpoint of exhibiting good developability and the viewpoint of controlling the edge fuse property. It is preferable that the content is 50% by mass or less from the viewpoints of the high resolution of the resist pattern and the viewpoint of the skirt shape, as well as the viewpoint of the chemical resistance of the resist pattern.

The second monomer is a monomer that is non-acidic and has at least one polymerizable unsaturated group in the molecule. Examples of the second monomer include (meth)acrylate such as methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, 2-hydroxyethyl (meth)acrylate, 2-hydroxypropyl (meth)acrylate, cyclohexyl (meth)acrylate, 2-ethylhexyl (meth)acrylate; esters of vinyl alcohols such as vinyl acetate; and (meth)acrylonitriles. Among them, methyl (meth)acrylate, 2-ethylhexyl (meth)acrylate, or n-butyl (meth)acrylate is preferable, and methyl (meth)acrylate is more preferable.

The content of the constitutional unit based on the second monomer in the polymer A is preferably 5% to 60% by mass, more preferably 15% to 50% by mass, and still more preferably 17% to 45% by mass, with respect to the total mass of the polymer A.

A case where the polymer A contains a constitutional unit based on a monomer having an aralkyl group and/or a constitutional unit based on a monomer having styrene is preferable from the viewpoint of suppressing line width thickening and deterioration of resolution in a case where the focal position has deviated during exposure. For example, a copolymer containing a constitutional unit based on methacrylic acid, a constitutional unit based on benzyl methacrylate, and a constitutional unit based on styrene, a copolymer containing a constitutional unit based on methacrylic acid, a constitutional unit based on methyl methacrylate, a constitutional unit based on benzyl methacrylate, and a constitutional unit based on styrene, or the like is preferable.

In one aspect, the polymer A is preferably a polymer which contains 25% to 55% by mass of a constitutional unit based on a monomer having an aromatic hydrocarbon group, 20% to 35% by mass of a constitutional unit based on the first monomer, and 15% to 45% by mass of a constitutional unit based on the second monomer. In addition, in another aspect, it is preferably a polymer which contains 70% to 90% by mass of a constitutional unit based on a monomer having an aromatic hydrocarbon group and 10% to 25% by mass of a constitutional unit based on the first monomer.

The polymer A may have a branched structure and/or an alicyclic structure in the side chain. In addition, a linear structure may be included in the side chain. In a case where a monomer containing a group having a branched structure in the side chain or a monomer containing a group having an alicyclic structure in the side chain is used, it is possible to introduce a branched structure or an alicyclic structure into the side chain of polymer A. The group having an alicyclic structure may be a monocyclic ring or a polycyclic ring.

Specific examples of the monomer containing a group having a branched structure in the side chain include i-propyl (meth)acrylate, i-butyl (meth)acrylate, s-butyl (meth)acrylate, t-butyl (meth)acrylate, i-amyl (meth)acrylate, t-amyl (meth)acrylate, sec-iso-amyl (meth)acrylate, 2-octyl (meth)acrylate, 3-octyl (meth)acrylate, and t-octyl (meth)acrylate. Among these, i-propyl (meth)acrylate, i-butyl (meth)acrylate, or t-butyl methacrylate is preferable, and i-propyl methacrylate or t-butyl methacrylate is more preferable.

Specific examples of the monomer having an alicyclic structure in the side chain include an (meth)acrylate having an alicyclic hydrocarbon group having 5 to 20 carbon atoms. More specific examples thereof include (bicyclo[2.2.1]heptyl-2) (meth)acrylate, 1-adamantyl (meth)acrylate, 2-adamantyl (meth)acrylate, 3-methyl-1-adamantyl (meth)acrylate, 3,5-dimethyl-1-adamantyl (meth)acrylate, 3-ethyladamantyl (meth)acrylate, 3-methyl-5-ethyl-1-adamantyl (meth)acrylate, 3,5,8-triethyl-1-adamantyl (meth)acrylate, 3,5-dimethyl-8-ethyl-1-adamantyl (meth)acrylate, 2-methyl-2-adamantyl (meth)acrylate, 2-ethyl-2-adamantyl (meth)acrylate, 3-hydroxy-1-adamantyl (meth)acrylate, octahydro-4,7-menthanoinden-5-yl (meth)acrylate, octahydro-4,7-menthanoinden-1-ylmethyl (meth)acrylate, 1-menthyl (meth)acrylate, tricyclodecane (meth)acrylate, 3-hydroxy-2,6,6-trimethyl-bicyclo[3.1.1]heptyl (meth)acrylate, 3,7,7-trimethyl-4-hydroxy-bicyclo[4.1.0]heptyl (meth)acrylate, (nor)bornyl (meth)acrylate, isobornyl (meth)acrylate, fenchyl (meth)acrylate, 2,2,5-trimethylcyclohexyl (meth)acrylate, and cyclohexyl (meth)acrylate. Among these (meth)acrylic acid esters, cyclohexyl (meth)acrylate (nor)bornyl (meth)acrylate, isobornyl (meth)acrylate, 1-adamantyl (meth)acrylate, 2-adamantyl (meth)acrylate, fenchyl (meth)acrylate, 1-menthyl (meth)acrylate, or tricyclodecane (meth)acrylate is preferable, and cyclohexyl (meth)acrylate, (nor)bornyl (meth)acrylate, isobornyl (meth)acrylate, 2-adamantyl (meth)acrylate, or tricyclodecane (meth)acrylate is more preferable.

One kind of the polymer A may be used alone, or two or more kinds thereof may be used.

In a case where two or more kinds are used, it is preferable that two kinds of the polymer A containing a constitutional unit based on a monomer having an aromatic hydrocarbon group are mixed and used, or it is preferable that the polymer A containing a constitutional unit based on a monomer having an aromatic hydrocarbon group and the polymer A containing no constitutional unit based on a monomer having an aromatic hydrocarbon group are mixed and used. In the latter case, the using proportion of the polymer A containing a constitutional unit based on a monomer having an aromatic hydrocarbon group is preferably 50% by mass or more, more preferably 70% by mass or more, still more preferably 80% by mass or more, and particularly preferably 90% by mass or more, with respect to the total mass of the polymer A.

The synthesis of the polymer A is preferably carried out by adding an appropriate amount of a radical polymerization initiator such as benzoyl peroxide or azoisobutyronitrile to a solution obtained by diluting the one or more monomers described above with a solvent such as acetone, methyl ethyl ketone, or isopropanol, and then stirring and heating the resultant mixture. In some cases, the synthesis is carried out while a part of the mixture is added dropwise to the reaction solution. After completion of the reaction, a solvent may be further added to adjust the concentration to a desired level. As the synthesis means, bulk polymerization, suspension polymerization, or emulsion polymerization may be used in addition to the solution polymerization.

The glass transition temperature Tg of the polymer A is preferably 30° C. to 135° C. In a case where the polymer A having a Tg of 135° C. or lower is used, it is possible to suppress line width thickening and deterioration of resolution in a case where the focal position has deviated during exposure. From this viewpoint, the Tg of the polymer A is more preferably 130° C. or lower, still more preferably 120° C. or lower, and particularly preferably 110° C. or lower. Further, it is preferable to use the polymer A having a Tg of 30° C. or higher from the viewpoint of improving the edge fuse resistance. From this viewpoint, the Tg of the polymer A is more preferably 40° C. or higher, still more preferably 50° C. or higher, particularly preferably 60° C. or higher, and most preferably 70° C. or higher.

The negative tone photosensitive resin layer may contain a resin other than those described above, as the polymer A.

Examples of the other resin include an acrylic resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, polyethyleneimine, polyallylamine, and polyalkylene glycol.

As the polymer A, an alkali-soluble resin described in the description of the thermoplastic resin layer described later may be used.

The content of the polymer A is preferably 10% to 90% by mass, more preferably 20% to 80% by mass, still more preferably 30% to 70% by mass, and particularly preferably 40% to 60% by mass, with respect to the total mass of the negative tone photosensitive resin layer. It is preferable that the content of the polymer A is 90% by mass or less from the viewpoint of controlling the development time. On the other hand, it is preferable that the content of the polymer A is 10% by mass or more from the viewpoint of improving the edge fuse resistance.

### Polymerizable Compound

In a case where the photosensitive resin layer is a negative tone photosensitive resin layer, the negative tone photosensitive resin layer preferably contains a polymerizable compound having a polymerizable group. It is noted that in the present specification, the “polymerizable compound” means a compound that polymerizes under the action of a polymerization initiator described later, where it means a compound different from the above-described polymer A.

The polymerizable group contained in the polymerizable compound is not particularly limited as long as it is a group involved in the polymerization reaction, and examples thereof include groups having an ethylenically unsaturated group, such as a vinyl group, an acryloyl group, a methacryloyl group, a styryl group, and a maleimide group; and groups having a cationically polymerizable group, such as an epoxy group and an oxetane group.

The polymerizable group is preferably a group having an ethylenically unsaturated group, and more preferably an acryloyl group or a methacryloyl group.

From the viewpoint that the negative tone photosensitive resin layer is more excellent in photosensitivity, the polymerizable compound is preferably a compound having one or more ethylenically unsaturated groups (an ethylenically unsaturated compound) and more preferably a compound having two or more ethylenically unsaturated groups in one molecule (a polyfunctional ethylenically unsaturated compound).

In addition, from the viewpoint of being excellent in resolution and peelability, the number of ethylenically unsaturated groups contained in one molecule of the ethylenically unsaturated compound is preferably 6 or less, more preferably 3 or less, and still more preferably 2 or less.

From the viewpoint that the balance of the photosensitivity, the resolution, and the peelability of the negative tone photosensitive resin layer is more excellent a bifunctional or trifunctional ethylenically unsaturated compound having two or three ethylenically unsaturated groups in one molecule is preferably contained, and a bifunctional ethylenically unsaturated compound having two ethylenically unsaturated groups in one molecule is more preferably contained.

From the viewpoint of excellent peelability, the content of the bifunctional ethylenically unsaturated compound with respect to the total mass of the polymerizable compound is preferably 20% by mass or more, more preferably more than 40% by mass, and still more preferably 55% by mass or more, with respect to the total mass of the negative tone photosensitive resin layer. The upper limit thereof is not particularly limited and may be 100% by mass. That is, all the polymerizable compounds may be bifunctional ethylenically unsaturated compounds.

In addition, the ethylenically unsaturated compound is preferably an (meth)acrylate compound having an (meth)acryloyl group as the polymerizable group.

### Polymerizable Compound B1

It is also preferable that the negative tone photosensitive resin layer contains a polymerizable compound B1 having an aromatic ring and two ethylenically unsaturated groups. The polymerizable compound B1 is a bifunctional ethylenically unsaturated compound having one or more aromatic rings in one molecule among the above-described polymerizable compounds B.

From the viewpoint of the more excellent resolution, the mass ratio of the content of the polymerizable compound B1 to the total mass of the polymerizable compound in the negative tone photosensitive resin layer is preferably 40% by mass or more, more preferably 50% by mass or more, still more preferably 55% by mass or more, and particularly preferably 60% by mass or more. The upper limit thereof is not particularly limited. However, from the viewpoint of peelability, it is, for example, 100% by mass or less, and it is preferably 99% by mass or less, more preferably 95% by mass or less, still more preferably 90% by mass or less, and particularly preferably 85% by mass or less.

Examples of the aromatic ring contained in the polymerizable compound B1 include aromatic hydrocarbon rings such as a benzene ring, a naphthalene ring, and an anthracene ring, aromatic heterocyclic rings such as a thiophene ring, a furan ring, a pyrrole ring, an imidazole ring, a triazole ring, and a pyridine ring, and fused rings thereof, where an aromatic hydrocarbon ring is preferable, and a benzene ring is more preferable. It is noted that the aromatic ring may have a substituent.

The polymerizable compound B1 may have only one aromatic ring or may have two or more aromatic rings.

The polymerizable compound B1 preferably has a bisphenol structure from the viewpoint of improving the resolution by suppressing the swelling of the photosensitive resin layer due to the developer.

Examples of the bisphenol structure include a bisphenol A structure derived from bisphenol A (2,2-bis(4-hydroxyphenyl)propane) a bisphenol F structure derived from bisphenol F (2,2-bis(4-hydroxyphenyl)methane), and a bisphenol B structure derived from bisphenol B (2,2-bis(4-hydroxyphenyl)butane), where a bisphenol A structure is preferable.

Examples of the polymerizable compound B1 having a bisphenol structure include a compound having a bisphenol structure and two polymerizable groups (preferably (meth)acryloyl groups) bonded to both ends of the bisphenol structure.

Both ends of the bisphenol structure and the two polymerizable groups may be directly bonded or may be bonded through one or more alkyleneoxy groups. The alkyleneoxy group to be added to both ends of the bisphenol structure is preferably an ethyleneoxy group or a propyleneoxy group and more preferably an ethyleneoxy group. The number of alkyleneoxy groups to be added to the bisphenol structure is not particularly limited; however, it is preferably 4 to 16 and more preferably 6 to 14 per molecule.

The polymerizable compound B1 having a bisphenol structure is described in paragraphs 0072 to 0080 of JP2016-224162A, and the content described in this publication is incorporated in the present specification.

The polymerizable compound B1 is preferably a bifunctional ethylenically unsaturated compound having a bisphenol A structure, and it is more preferably 2,2-bis(4-((meth)acryloxypolyalkoxy)phenyl)propane.

Examples of the 2,2-bis(4-((meth)acryloxypolyalkoxy)phenyl)propane include 2,2-bis(4-(methacryloxydiethoxy)phenyl)propane (FA-324M, manufactured by Showa Denko Materials Co., Ltd.), 2,2-bis(4-(methacryloxyethoxypropoxy)phenyl)propane, 2,2-bis(4-(methacryloxypentaethoxy)phenyl)propane (BPE-500, manufactured by SHIN-NAKAMURA CHEMICAL Co., Ltd.), 2,2-bis(4-(methacryloxydodecaethoxytetrapropoxy)phenyl)propane (FA-3200MY, manufactured by Showa Denko Materials Co., Ltd.), 2,2-bis(4-(methacryloxypentadecaethoxy)phenyl)propane (BPE-1300, manufactured by SHIN-NAKAMURA CHEMICAL Co., Ltd.), 2,2-bis(4-(methacryloxydiethoxy)phenyl)propane (BPE-200, manufactured by SHIN-NAKAMURA CHEMICAL Co., Ltd.), and ethoxylated (10) bisphenol A diacrylate (NK Ester A-BPE-10, manufactured by SHIN-NAKAMURA CHEMICAL Co., Ltd.).

The polymerizable compound B1 is preferably a compound represented by General Formula (B1).

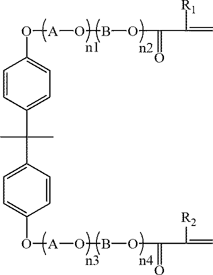

In General Formula B 1, R₁, and R₂ each independently represent a hydrogen atom or a methyl group. A represents C₂H₄. B represents C₃H₆. n1 and n3 are each independently an integer of 1 to 39, and n1 + n3 is an integer of 2 to 40. n2 and n4 are each independently an integer of 0 to 29, and n2 + n4 is an integer of 0 to 30. The sequences of constitutional units of —(A—O)— and —(B—O)— may be a random type or a block type. Here, in a case of a block type, any one of —(A—O)— or —(B—O)— may be on the bisphenyl group side.

In one aspect, n1 + n2 + n3 + n4 is preferably 2 to 20, more preferably 2 to 16, and still more preferably 4 to 12. In addition, n2 + n4 is preferably 0 to 10, more preferably 0 to 4, still more preferably 0 to 2, and particularly preferably 0.

One kind of the polymerizable compound B1 may be used alone, or two or more kinds thereof may be used.

From the viewpoint of the more excellent resolution, the content of the polymerizable compound B1 is preferably 10% by mass or more and more preferably 20% by mass or more with respect to the total mass of the negative tone photosensitive resin layer. The upper limit is not particularly limited; however, it is preferably 70% by mass or less and more preferably 60% by mass or less from the viewpoint of transferability and edge fusion (a phenomenon in which a photosensitive resin exudes from an end portion of a transfer member).

The negative tone photosensitive resin layer may contain a polymerizable compound other than the above-described polymerizable compound B1.

The polymerizable compound other than the polymerizable compound B1 is not particularly limited and can be appropriately selected from known compounds. Examples thereof include a compound having one ethylenically unsaturated group in one molecule (a monofunctional ethylenically unsaturated compound), a bifunctional ethylenically unsaturated compound having no aromatic ring, and a trifunctional or higher functional ethylenically unsaturated compound.

Examples of the monofunctional ethylenically unsaturated compound include ethyl (meth)acrylate, ethylhexyl (meth)acrylate, 2-(meth)acryloyloxyethyl succinate, polyethylene glycol mono(meth)acrylate, polypropylene glycol mono(meth)acrylate, and phenoxyethyl (meth)acrylate.

Examples of the bifunctional ethylenically unsaturated compound having no aromatic ring include alkylene glycol di(meth)acrylate, polyalkylene glycol di(meth)acrylate, urethane di(meth)acrylate, and trimethylolpropane diacrylate.

Examples of the alkylene glycol di(meth)acrylate include tricyclodecanedimethanol diacrylate (A-DCP, manufactured by SHIN-NAKAMURA CHEMICAL Co., Ltd.), tricyclodecanedimethanol dimethacrylate (DCP, manufactured by SHIN-NAKAMURA CHEMICAL Co., Ltd.), 1,9-nonandiol diacrylate (A-NOD-N, manufactured by SHIN-NAKAMURA CHEMICAL Co., Ltd.), 1,6-hexanediol diacrylate (A-HD-N, manufactured by SHIN-NAKAMURA CHEMICAL Co., Ltd.), ethylene glycol dimethacrylate, 1,10-decanediol diacrylate, and neopentyl glycol di(meth)acrylate.

Examples of the polyalkylene glycol di(meth)acrylate include polyethylene glycol di(meth)acrylate, dipropylene glycol diacrylate, tripropylene glycol diacrylate, and polypropylene glycol di(meth)acrylate.

Examples of the urethane di(meth)acrylate include propylene oxide-modified urethane di(meth)acrylate, as well as ethylene oxide- and propylene oxide-modified urethane di(meth)acrylates. Examples of the commercially available product include 8UX-015A (manufactured by Taisei Fine Chemical Co., Ltd.), UA-32P (manufactured by SHIN-NAKAMURA CHEMICAL Co., Ltd.), and UA-1100H (manufactured by SHIN-NAKAMURA CHEMICAL Co., Ltd.).

Examples of the trifunctional or higher functional ethylenically unsaturated compound include dipentaerythritol (tri/tetra/penta/hexa)(meth)acrylate, pentaerythritol (tri/tetra)(meth)acrylate, trimethylolpropane tri(meth)acrylate, ditrimethylolpropane tetra(meth)acrylate, trimethylolethane tri(meth)acrylate, isocyanuric acid tri(meth)acrylate, glycerin tri(meth)acrylate, and an alkylene oxide-modified product thereof.

Here, “(tri/tetra/penta/hexa)(meth)acrylate” has a concept including tri(meth)acrylate, tetra(meth)acrylate, penta(meth)acrylate, and hexa(meth)acrylate, and “(tri/tetra)(meth)acrylate” has a concept that includes tri(meth)acrylate and tetra(meth)acrylate.

In one aspect, the negative tone photosensitive resin layer also preferably contains the above-described polymerizable compound B1 and the above-described trifunctional or higher functional ethylenically unsaturated compound, and it more preferably contains the above-described polymerizable compound B1 and two or more kinds of trifunctional or higher functional ethylenically unsaturated compounds. In this case, the mass ratio of the polymerizable compound B1 to the trifunctional or higher functional ethylenically unsaturated compound ((the total mass of the polymerizable compound B1):(the total mass of the trifunctional or higher functional ethylenically unsaturated compound)) is preferably 1:1 to 5:1, more preferably 1.2:1 to 4:1, and still more preferably 1.5:1 to 3:1.

Further, in one aspect, the negative tone photosensitive resin layer preferably contains the above-described polymerizable compound B1 and two or more kinds of trifunctional ethylenically unsaturated compounds.

Examples of the alkylene oxide-modified product of the trifunctional or higher functional ethylenically unsaturated compound include a caprolactone-modified (meth)acrylate compound (KAYARAD (registered trade name) DPCA-20 manufactured by Nippon Kayaku Co., Ltd., A-9300-1CL manufactured by SHIN-NAKAMURA CHEMICAL Co., Ltd., or the like), an alkylene oxide-modified (meth)acrylate compound (KAYARAD RP-1040 manufactured by Nippon Kayaku Co., Ltd., ATM-35E or A-9300 manufactured by SHIN-NAKAMURA CHEMICAL Co., Ltd., EBECRYL (registered trade name) 135 manufactured by DAICEL-ALLNEX Ltd., or the like), ethoxylated glycerin triacrylate (A-GLY-9E manufactured by SHIN-NAKAMURA CHEMICAL Co., Ltd. or the like), ARONIX (registered trade name) TO-2349 (manufactured by Toagosei Co., Ltd.), ARONIX M-520 (manufactured by Toagosei Co., Ltd.), and ARONIX M-510 (manufactured by Toagosei Co., Ltd.).

Further, as the polymerizable compound, a polymerizable compound having an acid group (a carboxy group or the like) may be used. The acid group may form an acid anhydride group. Examples of the polymerizable compound having an acid group include ARONIX (registered trade name) TO-2349 (manufactured by Toagosei Co., Ltd.), ARONIX (registered trade name) M-520 (manufactured by Toagosei Co., Ltd.), and ARONIX (registered trade name) M-510 (manufactured by Toagosei Co., Ltd.).

As the polymerizable compound having an acid group, for example, the polymerizable compound having an acid group described in paragraphs 0025 to 0030 of JP2004-239942A may be used.

One kind of polymerizable compound may be used alone, or two or more kinds thereof may be used.

The content of the polymerizable compound is preferably 10% to 70% by mass, more preferably 15% to 70% by mass, and still more preferably 20% to 70% by mass, with respect to the total mass of the negative tone photosensitive resin layer.

The molecular weight (the weight-average molecular weight in a case of having a molecular weight distribution) of the polymerizable compound (including the polymerizable compound B1) is preferably 200 to 3,000, more preferably 280 to 2,200, and still more preferably 300 to 2,200.

### Polymerization Initiator

In a case where the photosensitive resin layer is a negative tone photosensitive resin layer, it is also preferable that the negative tone photosensitive resin layer contains a polymerization initiator.

The polymerization initiator is selected according to the type of the polymerization reaction, and examples thereof include a thermal polymerization initiator and a photopolymerization initiator.

The polymerization initiator may be a radical polymerization initiator or a cationic polymerization initiator.

The negative tone photosensitive resin layer preferably contains a photopolymerization initiator.

The photopolymerization initiator is a compound that initiates the polymerization of a polymerizable compound by receiving an actinic ray such as an ultraviolet ray, visible light, or an X-ray. The photopolymerization initiator is not particularly limited, and a known photopolymerization initiator can be used.

Examples of the photopolymerization initiator include a photoradical polymerization initiator and a photocationic polymerization initiator, where a photoradical polymerization initiator is preferable.

Examples of the photoradical polymerization initiator include a photopolymerization initiator having an oxime ester structure, a photopolymerization initiator having an α-aminoalkyl phenone structure, a photopolymerization initiator having an α-hydroxyalkyl phenone structure, a photopolymerization initiator having an acylphosphine oxide structure, and a photopolymerization initiator having an N-phenyl glycine structure.

Further, from the viewpoints of the photosensitivity, the visibility of the exposed portion and the non-exposed portion, and the resolution, the negative tone photosensitive resin layer preferably contains at least one selected from the group consisting of 2,4,5-triarylimidazole dimer and a derivative thereof, as a photoradical polymerization initiator. The two 2,4,5-triarylimidazole structures in the 2,4,5-triarylimidazole dimer and the derivative thereof may be the same or different from each other.

Examples of the derivative of the 2,4,5-triarylimidazole dimer include a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, a 2-(o-methoxyphenyl)-4,5-diphenylimidazole dimer, and a 2-(p-methoxyphenyl)-4,5-diphenylimidazole dimer.

Examples of the photoradical polymerization initiator which may be used include polymerization initiators described in paragraphs 0031 to 0042 of JP2011-095716A and paragraphs 0064 to 0081 of JP2015-014783A.

Examples of the photoradical polymerization initiator include ethyl dimethylaminobenzoate (DBE, CAS No. 10287-53-3), benzoin methyl ether, anisyl (p,p′-dimethoxybenzyl), TAZ-110 (product name: Midori Kagaku Co., Ltd.), benzophenone, 4,4′-bis(diethylamino)benzophenone, TAZ-111 (product name: Midori Kagaku Co., Ltd.), Irgacure OXE01, OXE02, OXE03, OXE04 (BASF SE), Omnirad 651 and 369 (product name: IGM Resins B.V), and 2,2′-bis(2-chlorophenyl)-4,4’,5,5′-tetraphenyl-1,2′-biimidazole (manufactured by Tokyo Chemical Industry Co., Ltd.).

Examples of the commercially available product of the photoradical polymerization initiator include 1-[4-(phenylthio)]-1,2-octanedione-2-(O-benzoyloxime) (product name: IRGACURE (registered trade name)), OXE-01 (manufactured by BASF SE), 1-[9-ethyl-6-(2-methylbenzoyl)-9H-carbazole-3-yl]ethanone-1-(O-acetyloxime) (product name: IRGACURE OXE-02, manufactured by BASF SE), IRGACURE OXE-03 (manufactured by BASF SE), IRGACURE OXE-04 (manufactured by BASF SE), 2-(dimethylamino)-2-[(4-methylphenyl)methyl]-1-[4-(4-morpholinyl)phenyl]-1-butanone (product name: Omnirad 379EG, manufactured by IGM Resins B.V), 2-methyl-1-(4-methylthiophenyl)-2-morpholinopropane-1-one (product name: Omnirad 907, manufactured by IGM Resins B.V), 2-hydroxy-1-{4-[4-(2-hydroxy-2-methylpropionyl)benzyl]phenyl}-2-methylpropane-1-one (product name: Omnirad 127, manufactured by IGM Resins B.V), 2-benzyl-2-dimethylamino-1-(4-morpholinophenyl)butanone-1 (product name: Omnirad 369, manufactured by IGM Resins B.V), 2-hydroxy-2-methyl-1-phenylpropane-1-one (product name: Omnirad 1173, manufactured by IGM Resins B.V), 1-hydroxycyclohexylphenylketone (product name: Omnirad 184, manufactured by IGM Resins B.V), 2,2-dimethoxy-1,2-diphenylethane-1-one (product name: Omnirad 651, manufactured by IGM Resins B.V), 2,4,6-trimethylbenzoyl-diphenylphosphinoxide (product name: Omnirad TPO H, IGM Resins B.V), bis(2,4,6-trimethylbenzoyl)phenylphosphine oxide (product name: Omnirad 819, manufactured by IGM Resins B.V), an oxime ester-based photopolymerization initiator (product name: Lunar 6, manufactured by DKSH Management Ltd.), 2,2′-bis(2-chlorophenyl)-4,4’,5,5′-tetraphenylbisimidazole (a 2-(2-chlorophenyl)-4,5-diphenylimidazole dimer (product name: B-CIM, manufactured by Hampford Research Inc.), a 2-(o-chlorophenyl)-4,5-diphenylimidazole dimer (product name: BCTB, manufactured by Tokyo Chemical Industry Co., Ltd.), 1-[4-(phenylthio)phenyl]-3-cyclopentylpropane-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propane-1,2-dione-2-(O-benzoyloxime) (product name: TR-PBG-391, manufactured by Changzhou Tronly New Electronic Materials Co., Ltd.).

The photocationic polymerization initiator (a photoacid generator) is a compound that generates an acid by receiving an actinic ray. The photocationic polymerization initiator is preferably a compound which becomes sensitive to an actinic ray having a wavelength of 300 nm or more, preferably 300 to 450 nm, and generates an acid; however, the chemical structure thereof is not limited. A photocationic polymerization initiator which does not directly become sensitive to an actinic ray having a wavelength of 300 nm or more can also be preferably used in combination with a sensitizing agent as long as it is a compound which becomes sensitive to an actinic ray having a wavelength of 300 nm or more and then generates an acid by being used in combination with the sensitizing agent.

The photocationic polymerization initiator is preferably a photocationic polymerization initiator that generates an acid having a pKa of 4 or less, more preferably a photocationic polymerization initiator that generates an acid having a pKa of 3 or less, and particularly preferably a photocationic polymerization initiator that generates an acid having a pKa of 2 or less. The lower limit value of pKa is not particularly defined; however, it is, for example, preferably -10.0 or more.

Examples of the photocationic polymerization initiator include an ionic photocationic polymerization initiator and a nonionic photocationic polymerization initiator.

Examples of the ionic photocationic polymerization initiator include onium salt compounds such as diaryliodonium salts and triarylsulfonium salts, and quaternary ammonium salts.

As the ionic photocationic polymerization initiator, the ionic photocationic polymerization initiators described in paragraphs 0114 to 0133 of JP2014-085643A may be used.

Examples of the nonionic photocationic polymerization initiator include trichloromethyl-s-triazines, diazomethane compounds, imide sulfonate compounds, and oxime sulfonate compounds. As the trichloromethyl-s-triazines, the diazomethane compounds, and the imide sulfonate compounds, the compounds described in paragraphs 0083 to 0088 of JP2011-221494A may be used. Further, as the oxime sulfonate compound, the compounds described in paragraphs 0084 to 0088 of WO2018/179640A may be used.

The negative tone photosensitive resin layer preferably contains a photoradical polymerization initiator, and it more preferably contains at least one selected from the group consisting of a 2,4,5-triarylimidazole dimer and a derivative thereof.

One kind of polymerization initiator may be used alone, or two or more kinds thereof may be used.

The content of the polymerization initiator (preferably, the photopolymerization initiator) is not particularly limited. However, it is preferably 0.1% by mass or more, more preferably 0.5% by mass or more, and still more preferably 1.0% by mass or more, with respect to the total mass of the negative tone photosensitive resin layer. The upper limit thereof is not particularly limited; however, it is preferably 20% by mass or less, more preferably 15% by mass or less, and still more preferably 10% by mass or less, with respect to the total mass of the negative tone photosensitive resin layer.

### Coloring Agent

From the viewpoints of visibility of the exposed portion and the non-exposed portion, the pattern visibility after development, and the resolution, it is also preferable that the photosensitive resin layer contains a coloring agent (also referred to as a “coloring agent N”) that has a maximum absorption wavelength of 450 nm or more in a wavelength range of 400 to 780 nm at the time of color development, where the maximum absorption wavelength is changed by an acid, a base, or a radical. In a case where the coloring agent N is contained, the adhesiveness to an adjacent layer (for example, the water-soluble resin layer) is improved, and thus the resolution is more excellent although the detailed mechanism is unknown.

In the present specification, the description that “the maximal absorption wavelength of the coloring agent is changed by an acid, a base, or a radical” may mean any one of an aspect in which a coloring agent in a colored state is decolorized by an acid, a base, or a radical, an aspect in which a coloring agent in a decolorized state develops a color by an acid, a base, or a radical, or an aspect in which a colored state of a coloring agent changes to a colored state of another color tone.

Specifically, the coloring agent N may be a compound that changes from the decolorized state to develop a color upon exposure or may be a compound that changes from the colored state to be decolorized upon exposure. In this case, it may be a coloring agent of which the color developing state or decolorized state changes by an action of an acid, a base, or a radical, which is generated upon exposure in the photosensitive resin layer, or it may be a coloring agent of which the color developing state or decolorized state changes due to a change in the state (for example, pH) of the inside of the photosensitive resin layer, the change being caused by an acid, a base, or a radical. Further, it may be a coloring agent of which the color developing state or decolorized state changes by directly receiving an acid, a base, or a radical as a stimulus without undergoing exposure.

Among the above, the coloring agent N is preferably a coloring agent of which the maximum absorption wavelength is changed by an acid or a radical, and more preferably a coloring agent of which the maximum absorption wavelength is changed by a radical, from the viewpoints of the visibility of the exposed portion and the non-exposed portion and the resolution.

In a case where the photosensitive resin layer is a negative tone photosensitive resin layer, the negative tone photosensitive resin layer preferably contains both a coloring agent of which the maximum absorption wavelength is changed by a radical as the coloring agent N and a photoradical polymerization initiator from the viewpoints of the visibility of the exposed portion and the non-exposed portion and the resolution.

Further, from the viewpoint of the visibility of the exposed portion and the non-exposed portion, the coloring agent N is preferably a coloring agent that develops color by an acid, a base, or a radical.

Examples of the color development mechanism of the coloring agent N include an aspect in which a photoradical polymerization initiator, a photocationic polymerization initiator (a photoacid generator), or a photobase generator is added to the photosensitive resin layer so that a radical-reactive coloring agent, an acid-reactive coloring agent, or a base-reactive coloring agent (for example, a leuco coloring agent) develops a color by a radical, an acid, or a base, which is generated after exposure from the photoradical polymerization initiator, the photocationic polymerization initiator, or the photobase generator.

From the viewpoint of the visibility of the exposed portion and the non-exposed portion, the coloring agent N preferably has a maximal absorption wavelength of 550 nm or more, more preferably 550 to 700 nm, and still more preferably 550 to 650 nm, in a wavelength range of 400 to 780 nm at the time of color development.

In addition, the coloring agent N may have only one maximal absorption wavelength in a wavelength range of 400 to 780 nm at the time of color development or may have two or more coloring agents N. In a case where the coloring agent N has two or more maximal absorption wavelengths in a wavelength range of 400 to 780 nm at the time of color development, it suffices that the maximal absorption wavelength having the highest absorbance among the two or more maximal absorption wavelengths may be 450 nm or more.

The maximal absorption wavelength of the coloring agent N is obtained by measuring a transmission spectrum of a solution (solution temperature: 25° C.) containing the coloring agent N in a range of 400 to 780 nm using a spectrophotometer: UV3100 (manufactured by Shimadzu Corporation) in atmospheric air and detecting a wavelength (a maximal absorption wavelength) at which the intensity of light is minimal.

Examples of the coloring agent that develops a color or is decolorized upon exposure include a leuco compound.

Examples of the coloring agent that is decolorized upon exposure include a leuco compound, a diarylmethane-based coloring agent, an oxazine-based coloring agent, a xanthene-based coloring agent, an iminonaphthoquinone-based coloring agent, an azomethine-based coloring agent, and an anthraquinone-based coloring agent.

From the viewpoint of the visibility of the exposed portion and the non-exposed portion, the coloring agent N is preferably a leuco compound.

Examples of the leuco compound include a leuco compound having a triarylmethane skeleton (a triarylmethane-based coloring agent), a leuco compound having a spiropyran skeleton (a spiropyran-based coloring agent), a leuco compound having a fluoran skeleton (a fluoran-based coloring agent), a leuco compound having a diarylmethane skeleton (a diarylmethane-based coloring agent), a leuco compound having a rhodamine lactam skeleton (a rhodamine lactam-based coloring agent), a leuco compound having an indolyl phthalide skeleton (an indolyl phthalide-based coloring agent), and a leuco compound having a leuco auramine skeleton (a leuco auramine-based coloring agent).

Among them, a triarylmethane-based coloring agent or a fluoran-based coloring agent is preferable, and a leuco compound having a triphenylmethane skeleton (a triphenylmethane-based coloring agent) or a fluoran-based coloring agent is more preferable.

From the viewpoint of the visibility of the exposed portion and the non-exposed portion, the leuco compound preferably has a lactone ring, a sultine ring, or a sultone ring. As a result, the lactone ring, the sultine ring, or the sultone ring contained in the leuco compound is reacted with a radical generated from the photoradical polymerization initiator or an acid generated from the photocationic polymerization initiator to change the leuco compound into a closed ring state, thereby being decolorized, or change the leuco compound to an open ring state, whereby a color is developed. It is preferable that the leuco compound is a compound having a lactone ring, a sultine ring, or a sultone ring, where the lactone ring, the sultine ring, or the sultone ring is opened by a radical or an acid to develop a color, and it is more preferable that it is a compound having a lactone ring, where the lactone ring is opened by a radical or an acid to develop a color.

Examples of the coloring agent N include the following dyes and leuco compounds.

Among the coloring agents N, specific examples of the dye include Brilliant green, Ethyl violet, Methyl green, Crystal violet, Basic fuchsine, Methyl violet 2B, Quinaldine red, Rose bengal, Metanil yellow, thymol sulfonphthalein, Xylenol blue, Methyl orange, Paramethyl red, Congo red, Benzopurpurine 4B, α-Naphthyl red, Nile blue 2B, Nile blue A, Methyl violet, Malachite green, Parafuchsine, Victoria pure blue-naphthalene sulfonate, Victoria pure blue BOH (manufactured by HODOGAYA CHEMICAL CO., LTD.), Oil blue # 603 (manufactured by ORIENT CHEMICAL INDUSTRIES CO., LTD.), Oil pink #312 (manufactured by ORIENT CHEMICAL INDUSTRIES CO., LTD.), Oil red 5B (manufactured by ORIENT CHEMICAL INDUSTRIES CO., LTD.), Oil scarlet # 308 (manufactured by ORIENT CHEMICAL INDUSTRIES CO., LTD.), Oil red OG (manufactured by ORIENT CHEMICAL INDUSTRIES CO., LTD.), Oil red RR (manufactured by ORIENT CHEMICAL INDUSTRIES CO., LTD.), Oil green # 502 (manufactured by ORIENT CHEMICAL INDUSTRIES CO., LTD.), Spiron red BEH special (manufactured by HODOGAYA CHEMICAL CO., LTD.), m-Cresol purple, Cresol red, rhodamine B, rhodamine 6G, sulforhodamine B, auramine, 4-p-diethylaminophenyliminonaphthoquinone, 2-carboxyanilino-4-p-diethylaminophenyliminonaphthoquinone, 2-carboxystearylamino-4-p-N,N-bis(hydroxyethyl) amino-phenyliminonaphthoquinone, 1-phenyl-3-methyl-4-p-diethylaminophenylimino-5-pyrazolone, and 1-β-naphthyl-4-p-diethylaminophenylimino-5-pyrazolone.

Among the coloring agents N, specific examples of the leuco compound include p,p′,p″-hexamethyltriaminotriphenylmethane (Leucocrystal violet), Pergascript blue SRB (manufactured by Ciba-Geigy AG), Crystal violet lactone, Malachite green lactone, benzoyl leucomethylene blue, 2-(N-phenyl-N-methylamino)-6-(N-p-tolyl-N-ethyl) aminofluoran, 2-anilino-3-methyl-6-(N-ethyl-p-toluidino) fluoran, 3,6-dimethoxyfluoran, 3-(N,N-diethylamino)-5-methyl-7-(N,N-dibenzylamino) fluoran, 3-(N-cyclohexyl-N-methylamino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-aminofluoran, 3-(N,N-diethylamino)-7-(4-chloroanilino) fluoran, 3-(N,N-diethylamino)-7-chlorofluoran, 3 -(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindole-3-yl)phthalide, 3,3-bis(1-n-butyl-2-methylindole-3-yl)phthalide, 3,3-bis(p-dimethylaminophenyl)-6-dimethylaminophthalide, 3-(4-diethylamino-2-ethoxyphenyl)-3-(1-ethyl-2-methylindole-3-yl)-4-azaphthalide, 3-(4-diethylaminophenyl)-3-(1-ethyl-2-methylindole-3-yl)phthalide, and 3′,6′-bis(diphenylamino)spiroisobenzofuran-1 (3H),9′-[9H]xanthene-3-one.

From the viewpoints of visibility of the exposed portion and the non-exposed portion, the pattern visibility after development, and the resolution, the coloring agent N is preferably a coloring agent of which the maximum absorption wavelength is changed by a radical, and more preferably a coloring agent that develops a color by a radical.

The coloring agent N is preferably Leucocrystal violet, Crystal violet lactone, Brilliant green, or Victoria pure blue-naphthalene sulfonate.

One kind of the coloring agent N may be used alone, or two or more kinds thereof may be used.

From the viewpoints of visibility of the exposed portion and the non-exposed portion, the pattern visibility after development, and the resolution, the content of the coloring agent N is preferably 0.1% by mass or more, more preferably 0.1% to 10% by mass, still more preferably 0.1% to 5% by mass, and particularly preferably 0.1% to 1% by mass, with respect to the total mass of the photosensitive resin layer.

The content of the coloring agent N means the content of the coloring agent in a case where the whole coloring agent N contained in the total mass of the photosensitive resin layer is in a colored state. Hereinafter, a method of quantifying the content of the coloring agent N will be described by taking a coloring agent that develops color by a radical as an example.

0.001 g and 0.01 g of a coloring agent are each dissolved in 100 mL of methyl ethyl ketone to prepare a solution. A photoradical polymerization initiator Irgacure OXE01 (product name, BASF Japan Ltd.) is added to each of the obtained solutions, and radicals are generated by the irradiation with light of 365 nm to bring the whole coloring agent into a colored state. Then, in the atmospheric air, the absorbance of each solution having a liquid temperature of 25° C. is measured using a spectrophotometer (UV3100, manufactured by Shimadzu Corporation), and a calibration curve is created.

Next, the absorbance of the solution in which the coloring agent has been caused to develop a color is measured by the same method as the above except that 3 g of the photosensitive resin layer is dissolved in methyl ethyl ketone instead of the coloring agent. From the obtained absorbance of the solution containing the photosensitive resin layer, the content of the coloring agent contained in the photosensitive resin layer is calculated based on the calibration curve.

It is noted that the 3 g of the photosensitive resin layer is the same as the 3 g of the total solid content of in the photosensitive resin composition.

### Thermal Crosslinking Compound

In a case of being a negative tone photosensitive resin layer, the photosensitive resin layer preferably contains a thermal crosslinking compound from the viewpoint of the hardness of the cured film to be obtained and the pressure-sensitive adhesiveness of the uncured film to be obtained. In the present disclosure, the thermal crosslinking compound having an ethylenically unsaturated group described later shall be not treated as a polymerizable compound but shall be treated as a thermal crosslinking compound.

Examples of the thermal crosslinking compound include a methylol compound and a blocked isocyanate compound. Among these, from the viewpoint of the hardness of the cured film to be obtained and the pressure-sensitive adhesiveness of the uncured film to be obtained, a blocked isocyanate compound is preferable.

By the way, the blocked isocyanate compound reacts with a hydroxy group and a carboxy group. As a result, for example, in a case where the resin and/or the polymerizable compound has at least one of a hydroxy group or a carboxy group, a film to be formed has a low hydrophilicity, and thus in a case where a film obtained by curing the negative tone photosensitive resin layer is used as a protective film, the function thereof tends to be enhanced.

The blocked isocyanate compound refers to a “compound having a structure in which the isocyanate group of isocyanate is protected (so-called masked) by a blocking agent”.

The dissociation temperature of the blocked isocyanate compound is not particularly limited; however, it is preferably 100° C. to 160° C. and more preferably 130° C. to 150° C.

The dissociation temperature of blocked isocyanate means “temperature at an endothermic peak accompanied with a deprotection reaction of blocked isocyanate, in a case where the measurement is carried out by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonate (such as dimethyl malonate, diethyl malonate, di-n-butyl malonate, or di-2-ethylhexyl malonate)] and an oxime compound (a compound having a structure represented by —C(═N—OH)— in the molecule, such as formaldoxime, acetoaldoxime, acetoxime, methyl ethyl ketoxime, or cyclohexanoneoxime).

Among these, the blocking agent having a dissociation temperature of 100° C. to 160° C. is preferably, for example, at least one selected from oxime compounds from the viewpoint of storage stability.

The blocked isocyanate compound preferably has an isocyanurate structure, for example, from the viewpoint of improving the brittleness of the film and improving the adhesion force to a transferred material.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group.

The polymerizable group is not particularly limited, and a known polymerizable group can be used, where a radically polymerizable group is preferable.

Examples of the polymerizable group include a (meth)acryloxy group, a (meth)acrylamide group, an ethylenically unsaturated group such as styryl group, and an epoxy group such as a glycidyl group.

Among them, the polymerizable group is preferably an ethylenically unsaturated group, more preferably an (meth)acryloxy group, and still more preferably an acryloxy group.

As the blocked isocyanate compound, a commercially available product can be used.

Examples of the commercially available blocked isocyanate compound include compounds such as Karenz (registered trade name), AOI-BM, Karenz (registered trade name), MOI-BM, Karenz (registered trade name), and MOI-BP (all of which are manufactured by Showa Denko K.K.); and block type DURANATE series (for example, DURANATE (registered trade name)), TPA-B80E, DURANATE (registered trade name), and WT32-B75P, manufactured by Asahi Kasei Chemicals Co., Ltd.).

Further, as the blocked isocyanate compound, a compound having the following structure can also be used.

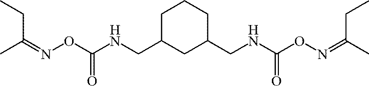 [SMILES: CC/C(C)=N\OC(=O)NCC1CCCC(CNC(=O)O/N=C(/C)CC)C1]

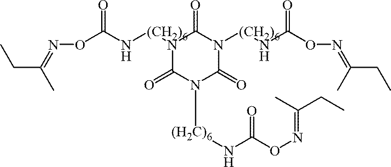

One kind of thermal crosslinking compound may be used alone, or two or more kinds thereof may be used.

In a case where the photosensitive resin layer contains a thermal crosslinking compound, the content of the thermal crosslinking compound is preferably 1% to 50% by mass and more preferably 5% to 30% by mass with respect to the total mass of the photosensitive resin layer.

### Other Additives

The photosensitive resin layer may contain a known additive in addition to the above-described components, as necessary.

Examples of the additive include a radical polymerization inhibitor, a sensitizing agent, a plasticizer, a heterocyclic compound (triazole or the like), benzotriazoles, carboxybenzotriazoles, pyridines (isonicotinamide and the like), a purine base (adenine or the like), and a surfactant.

One kind of each additive may be used alone, or two or more kinds thereof may be used.

The photosensitive resin layer may contain a radical polymerization inhibitor.

Examples of the radical polymerization inhibitor include the thermal polymerization inhibitors described in paragraph 0018 of JP4502784B. Among them, phenothiazine, phenoxazine, or 4-methoxyphenol is preferable. Examples of other radical polymerization inhibitors include naphthylamine, cuprous chloride, a nitrosophenylhydroxyamine aluminum salt, and diphenylnitrosamine. It is preferable to use a nitrosophenylhydroxyamine aluminum salt as a radical polymerization inhibitor so that the sensitivity of the photosensitive resin layer is not impaired.

Examples of the benzotriazoles include 1,2,3-benzotriazole, 1-chloro-1,2,3-benzotriazole, bis(N-2-ethylhexyl)aminomethylene-1,2,3-benzotriazole, bis(N-2-ethylhexyl)aminomethylene-1,2,3-tolyltriazole, and bis(N-2-hydroxyethyl)aminomethylene-1,2,3-benzotriazole.

Examples of the carboxybenzotriazoles include 4-carboxy-1,2,3-benzotriazole, 5-carboxy-1,2,3-benzotriazole, N-(N,N-di-2-ethylhexyl)aminomethylenecarboxybenzotriazole, N-(N,N-di-2-hydroxyethyl)aminomethylenecarboxybenzotriazole, and N-(N,N-di-2-ethylhexyl)aminoethylenecarboxybenzotriazole. As the carboxybenzotriazoles, it is possible to use, for example, a commercially available product such as CBT-1 (product name, JOHOKU CHEMICAL Co., Ltd.).

The total content of the radical polymerization inhibitor, the benzotriazoles, and the carboxybenzotriazoles is preferably 0.01% to 3% by mass and more preferably 0.05% to 1% by mass with respect to the total mass of the photosensitive resin layer. In a case where the content of the photosensitive resin layer is 0.01% by mass or more, the storage stability thereof is more excellent. On the other hand, in a case where the content thereof is 3% by mass or less, the maintenance of sensitivity and the suppression of decolorization of a dye are more excellent.

The photosensitive resin layer may contain a sensitizing agent.

The sensitizing agent is not particularly limited, and a known sensitizing agent, a dye, or a pigment can be used. Examples of the sensitizing agent include a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound (for example, 1,2,4-triazole), a stilbene compound, a triazine compound, a thiophene compound, a naphthalimide compound, a triarylamine compound, and an aminoacridine compound.

One kind of sensitizing agent may be used alone, or two or more kinds thereof may be used.

In a case where the photosensitive resin layer contains a sensitizing agent, the content of the sensitizing agent can be appropriately selected depending on the intended purpose; however, from the viewpoints of improving the sensitivity to the light source and improving the curing rate by balancing the polymerization rate and the chain transfer, it is preferably 0.01% to 5% by mass and more preferably 0.05% to 1% by mass with respect to the total mass of the photosensitive resin layer.

The photosensitive resin layer may contain at least one selected from the group consisting of a plasticizer and a heterocyclic compound.

Examples of the plasticizer and the heterocyclic compound include the compounds described in paragraphs 0097 to 0103 and 0111 to 0118 of WO2018/179640A.

In addition, the photosensitive resin layer may further contain known additives such as metal oxide particles, an antioxidant, a dispersing agent, an acid proliferation agent, a development accelerator, a conductive fiber, an ultraviolet absorbing agent, a thickener, a crosslinking agent, and an organic or inorganic precipitation inhibitor.

The additives contained in the photosensitive resin layer are described in paragraphs 0165 to 0184 of JP2014-085643A, and the content of this publication is incorporated in the present specification.

From the viewpoint of improving reliability and laminating property, the content of water in the photosensitive resin layer is preferably 0.01% to 1.0% by mass and more preferably 0.05% to 0.5% by mass.

The layer thickness (the film thickness) of the photosensitive resin layer is generally 0.1 to 300 µm, preferably 0.2 to 100 µm, more preferably 0.5 to 50 µm, still more preferably 0.5 to 15 µm, particularly preferably 0.5 to 10 µm, and most preferably 0.5 to 8 µm. This makes it possible for the developability of the photosensitive resin layer to be improved and makes it possible for the resolution to be improved.

In addition, in one aspect, it is preferably 0.5 to 5 µm, more preferably 0.5 to 4 µm, and still more preferably 0.5 to 3 µm.

In addition, from the viewpoint of excellent adhesiveness, the light transmittance of light having a wavelength of 365 nm in the photosensitive resin layer is preferably 10% or more, more preferably 30% or more, and still more preferably 50% or more. The upper limit thereof is not particularly limited; however, it is preferably 99.9% or less.

### Impurity and the Like

The photosensitive resin layer may include a predetermined amount of impurities.

Specific examples of the impurities include sodium, potassium, magnesium, calcium, iron, manganese, copper, aluminum, titanium, chromium, cobalt, nickel, zinc, tin, halogen, and ions thereof. Among these, a halide ion, a sodium ion, and a potassium ion are easily mixed as impurities, and thus it is preferable to set the content of the impurities to the following content.

The content of impurities in the photosensitive resin layer is preferably 80 ppm or less, more preferably 10 ppm or less, and still more preferably 2 ppm or less in terms of mass. The content of the impurities can be 1 ppb or more or may be 0.1 ppm or more in terms of mass.

Examples of the method of keeping the impurities in the above range include selecting a raw material having a low content of impurities as a raw material for the composition, preventing the impurities from being mixed during the production of the photosensitive resin layer, and washing and removing the impurities. Such a method makes it possible for the amount of impurities to be kept within the above range.

The impurities can be quantified by a known method such as inductively coupled plasma (ICP) emission spectroscopy, atomic absorption spectroscopy, and ion chromatography.

In the photosensitive resin layer, it is preferable that the content of the compound such as benzene, formaldehyde, trichloroethylene, 1,3-butadiene, carbon tetrachloride, chloroform, N,N-dimethylformamide, N,N-dimethylacetamide, or hexane is low. The content of this compound with respect to the total mass of the photosensitive resin layer is preferably 100 ppm or less, more preferably 20 ppm or less, and still more preferably 4 ppm or less in terms of mass.

The lower limit thereof can be 10 ppb or more or can be 100 ppb or more in terms of mass, with respect to the total mass of the photosensitive resin layer. The content of these compounds can be suppressed in the same manner as in the above-described metal as impurities. Further, it can be quantified by a known measuring method.

From the viewpoint of improving reliability and laminating property, the content of water in the photosensitive resin layer is preferably 0.01% to 1.0% by mass and more preferably 0.05% to 0.5% by mass.

### Pigment

The photosensitive resin layer may be a coloration resin layer containing a pigment.

In recent years, a liquid crystal display window included in an electronic device may be attached with a cover glass having a black frame-shaped light shielding layer formed on the peripheral portion of the back surface of a transparent glass substrate or the like in order to protect the liquid crystal display window. A coloration resin layer can be used to form such a light shielding layer.

The pigment may be appropriately selected depending on the desired color tone, and it can be selected from a black pigment, a white pigment, and chromatic pigments other than black and white. Among them, in a case of forming a black pattern, a black pigment is suitably selected as the pigment.

As the black pigment, a known black pigment (an organic pigment, an inorganic pigment, or the like) can be appropriately selected as long as the effect of the present disclosure is not impaired. Among them, from the viewpoint of optical density, suitable examples of the black pigment include carbon black, titanium oxide, titanium carbide, iron oxide, and graphite, where carbon black is particularly preferable. From the viewpoint of surface resistance, the carbon black is preferably a carbon black in which at least a part of the surface is coated with a resin.

From the viewpoint of dispersion stability, the particle diameter of the black pigment is preferably 0.001 to 0.1 µm and more preferably 0.01 to 0.08 µm in terms of number average particle diameter.

Here, the particle diameter refers to a diameter of a circle in a case where the area of the pigment particles is determined from the photographic image of the pigment particles captured with an electronic microscope and a circle having the same area as the area of the pigment particles is assumed, and the number average particle diameter is an average value obtained by determining the above particle diameter for any 100 particles and averaging the determined diameters of the 100 particles.

As the pigment other than the black pigment, the white pigments described in paragraphs 0015 and 0114 of JP2005-007765A can be used as the white pigment. Specifically, among the white pigments, the inorganic pigment is preferably titanium oxide, zinc oxide, lithopone, light calcium carbonate, white carbon, aluminum oxide, aluminum hydroxide, or barium sulfate, more preferably titanium oxide or zinc oxide, and still more preferably titanium oxide. The inorganic pigment is preferably a rutile-type or anatase-type titanium oxide, and particularly preferably a rutile-type titanium oxide.

Further, the surface of titanium oxide may be subjected to a silica treatment, an alumina treatment, a titania treatment, a zirconia treatment, or an organic substance treatment, or may be subjected to two or more treatments. As a result, the catalytic activity of titanium oxide is suppressed, and thus heat resistance, light resistance, and the like are improved.

From the viewpoint of reducing the thickness of the photosensitive resin layer after heating, the surface treatment of the surface of titanium oxide is preferably at least one of an alumina treatment or a zirconia treatment, and particularly preferably both alumina treatment and zirconia treatment.

Further, in a case where the photosensitive resin layer is a coloration resin layer, the photosensitive resin layer preferably further contains a chromatic pigment other than the black pigment and the white pigment from the viewpoint of transferability. In a case where a chromatic pigment is contained, the particle diameter of the chromatic pigment is preferably 0.1 µm or less and more preferably 0.08 µm or less in terms of more excellent dispersivity.

Examples of the chromatic pigment include Victoria pure blue BO (Color Index (hereinafter C.I.) 42595), Auramine (C.I. 41000), Fat black HB (C.I. 26150), Monolite yellow GT (C.I. Pigment yellow 12), Permanent yellow GR (C.I. Pigment yellow 17), Permanent yellow HR (C.I. Pigment yellow 83), Permanent carmine FBB (C.I. Pigment red 146), Hoster balm red ESB (C.I. Pigment violet 19), Permanent ruby FBH (C.I. Pigment red 11), Pastel pink B supra (C.I. Pigment red 81), Monastral first blue (C.I. Pigment blue 15), Monolite first black B (C.I. Pigment black 1), and Carbon, as well as C.I. Pigment red 97, C.I. Pigment red 122, C.I. Pigment red 149, C.I. Pigment red 168, C.I. Pigment red 177, C.I. Pigment red 180, C.I. Pigment red 192, C.I. Pigment red 215, C.I. Pigment Green 7, C.I. Pigment blue 15:1, C.I. Pigment blue 15:4, C.I. Pigment blue 22, C.I. Pigment blue 60, C.I. Pigment blue 64, and C.I. Pigment violet 23. Among them, C.I. Pigment red 177 is preferable.

In a case where the photosensitive resin layer contains a pigment, the content of the pigment is preferably more than 3% by mass and 40% by mass or less, more preferably more than 3% by mass and 35% by mass or less, still more preferably more than 5% by mass and 35% by mass or less, and particularly preferably 10% by mass or more and 35% by mass or less, with respect to the total mass of the photosensitive resin layer.

In a case where the photosensitive resin layer contains a pigment (a white pigment and a chromatic pigment) other than the black pigment, the content of the pigment other than the black pigment is preferably 30% by mass or less, preferably 1% to 20% by mass, and still more preferably 3% to 15% by mass, with respect to the black pigment.

In a case where the photosensitive resin layer contains a black pigment and the photosensitive resin layer is formed from a photosensitive resin composition, the black pigment (preferably carbon black) is preferably introduced into the photosensitive resin composition in a form of a pigment dispersion liquid.

The dispersion liquid may be a dispersion liquid prepared by adding a mixture obtained by mixing in advance a black pigment and a pigment dispersing agent to an organic solvent (or a vehicle) and dispersing it with a disperser. The pigment dispersing agent may be selected depending on the pigment and the solvent, and for example, a commercially available dispersing agent can be used. It is noted that the vehicle refers to a medium portion which disperses a pigment in a case where the pigment is made to be a pigment dispersion liquid, where the vehicle is liquid and contains a binder component that holds the black pigment in a dispersed state and a solvent component (an organic solvent) that dissolves and dilutes the binder component.

The disperser is not particularly limited, and examples thereof include known dispersers such as a kneader, a roll mill, an attritor, a super mill, a dissolver, a homogenization mixer, and a sand mill. Further, fine pulverization may be carried out by mechanical grinding using frictional force. Regarding the disperser and fine pulverization, the description in “Encyclopedia of Pigments” (Kunizo Asakura, First Edition, Asakura Publishing Co., Ltd., 2000, 438, 310) can be referred to.

### Thermoplastic Resin Layer

The thermoplastic resin layer is generally disposed between the temporary support and the photosensitive resin layer. In a case where the transfer film includes a thermoplastic resin layer, the followability to the substrate in the affixing step of the transfer film and the substrate is improved, and the mixing of air bubbles between the substrate and the transfer film is suppressed. As a result, it is possible to ensure the adhesiveness to a layer (for example, the temporary support) adjacent to the thermoplastic resin layer.

The thermoplastic resin layer contains a resin. The resin includes a thermoplastic resin as a part or the whole thereof. That is, in one aspect, it is also preferable that, in the thermoplastic resin layer, the resin is a thermoplastic resin.

### Alkali-Soluble Resin (Thermoplastic Resin)

The thermoplastic resin is preferably an alkali-soluble resin.

Examples of the alkali-soluble resin include an acrylic resin, a polystyrene resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, polyethyleneimine, polyallylamine, and polyalkylene glycol.

The alkali-soluble resin is preferably an acrylic resin from the viewpoint of developability and adhesiveness to an adjacent layer.

Here, the acrylic resin means a resin having at least one constitutional unit selected from the group consisting of a constitutional unit derived from (meth)acrylic acid, a constitutional unit derived from a (meth)acrylic acid ester, and a constitutional unit derived from a (meth)acrylic acid amide.

In the acrylic resin, the total content of the constitutional unit derived from (meth)acrylic acid, the constitutional unit derived from a (meth)acrylic acid ester, and the constitutional unit derived from a (meth)acrylic acid amide is preferably 50% by mass or more with respect to the total mass the acrylic resin.

Among the above, the total content of the constitutional unit derived from (meth)acrylic acid and the constitutional unit derived from a (meth)acrylic acid ester is preferably 30% to 100% by mass and more preferably 50% to 100% by mass with respect to the total mass of the acrylic resin.

Further, the alkali-soluble resin is preferably a polymer having an acid group.

Examples of the acid group include a carboxy group, a sulfo group, a phosphoric acid group, and a phosphonic acid group, where a carboxy group is preferable.

From the viewpoint of developability, the alkali-soluble resin is more preferably an alkali-soluble resin having an acid value of 60 mgKOH/g or more and still more preferably a carboxy group-containing acrylic resin having an acid value of 60 mgKOH/g or more.

The upper limit of the acid value of the alkali-soluble resin is not particularly limited; however, it is preferably 300 mgKOH/g or less, more preferably 250 mgKOH/g or less, still more preferably 200 mgKOH/g or less, and particularly preferably 150 mgKOH/g or less.

The carboxy group-containing acrylic resin having an acid value of 60 mgKOH/g or more is not particularly limited and can be appropriately selected from known resins and used.

Examples thereof include an alkali-soluble resin which is the carboxy group-containing acrylic resin having an acid value of 60 mgKOH/g or more among the polymers described in paragraph 0025 of JP2011-095716A, the carboxy group-containing acrylic resin having an acid value of 60 mgKOH/g or more among the polymers described in paragraphs 0033 to 0052 of JP2010-237589A, and the carboxy group-containing acrylic resin having an acid value of 60 mgKOH/g or more among the binder polymers described in paragraphs 0053 to 0068 of JP2016-224162A.

The copolymerization ratio of the constitutional unit having a carboxy group in the above-described carboxy group-containing acrylic resin is preferably 5% to 50% by mass, more preferably 10% to 40% by mass, and still more preferably 12% to 30% by mass, with respect to the total mass of the acrylic resin.

The alkali-soluble resin is particularly preferably an acrylic resin having a constitutional unit derived from (meth)acrylic acid from the viewpoints of developability and adhesiveness to an adjacent layer.

The alkali-soluble resin may have a reactive group. It suffices that the reactive group is any addition-polymerizable group. Examples of the reactive group include an ethylenically unsaturated group; a polycondensable group such as a hydroxy group or a carboxy group; and a polyaddition reactive group such as an epoxy group or a (blocked) isocyanate group.

The weight-average molecular weight (Mw) of the alkali-soluble resin is preferably 1,000 or more, more preferably 10,000 to 100,000, and still more preferably 20,000 to 50,000.

One kind of alkali-soluble resin may be used alone, or two or more kinds thereof may be used.

From the viewpoint of developability and adhesiveness to an adjacent layer, the content of the alkali-soluble resin is preferably 10% to 99% by mass, more preferably 20% to 90% by mass, still more preferably 40% to 80% by mass, and particularly preferably 50% to 75% by mass, with respect to the total mass of the thermoplastic resin layer.

### Coloring Agent

The thermoplastic resin layer preferably contains a coloring agent (hereinafter, simply also referred to as a “coloring agent B”) that has a maximum absorption wavelength of 450 nm or more in a wavelength range of 400 to 780 nm at the time of color development, where the maximum absorption wavelength is changed by an acid, a base, or a radical.

The preferred aspect of the coloring agent B is the same as the preferred aspect of the coloring agent N described above, except for the points described later.

From the viewpoints of the visibility of the exposed portion and the non-exposed portion and the resolution, the coloring agent B is preferably a coloring agent of which the maximum absorption wavelength is changed by an acid or a radical, and more preferably a coloring agent of which the maximum absorption wavelength is changed by an acid.

From the viewpoints of the visibility of the exposed portion and the non-exposed portion and the resolution, the thermoplastic resin layer preferably contains both a coloring agent of which the maximum absorption wavelength is changed by an acid as the coloring agent B and a compound that generates an acid due to light described later.

One kind of the coloring agent B may be used alone, or two or more kinds thereof may be used.

From the viewpoint of visibility of the exposed portion and the non-exposed portion, the content of the coloring agent B is preferably 0.2% by mass or more, more preferably 0.2% to 6% by mass, still more preferably 0.2% to 5% by mass, and particularly preferably 0.25% to 3.0% by mass, with respect to the total mass of the thermoplastic resin layer.

Here, the content of the coloring agent B means the content of the coloring agent in a case where the whole coloring agent B contained in the thermoplastic resin layer is in a colored state. Hereinafter, a method of quantifying the content of the coloring agent B will be described by taking a coloring agent that develops color by a radical as an example.

0.001 g and 0.01 g of a coloring agent are each dissolved in 100 mL of methyl ethyl ketone to prepare a solution. A photoradical polymerization initiator Irgacure OXE01 (product name, BASF Japan Ltd.) is added to each of the obtained solutions, and radicals are generated by the irradiation with light of 365 nm to bring the whole coloring agent into a colored state. Then, in the atmospheric air, the absorbance of each solution having a liquid temperature of 25° C. is measured using a spectrophotometer (UV3100, manufactured by Shimadzu Corporation), and a calibration curve is created.

Next, the absorbance of the solution in which the coloring agent has been caused to develop a color is measured by the same method as the above except that the thermoplastic resin layer (0.1 g) is dissolved in methyl ethyl ketone instead of the coloring agent. From the obtained absorbance of the solution containing the thermoplastic resin layer, the amount of the coloring agent contained in the thermoplastic resin layer is calculated based on the calibration curve.

It is noted that the 3 g of the thermoplastic resin layer is the same as the 3 g of the solid content of the composition.

### Compound That Generates Acid, Base, or Radical Due to Light

The thermoplastic resin layer may contain a compound that generates an acid, a base, or a radical due to light (hereinafter, also simply referred to as a “compound C”).

The compound C is preferably a compound that generates an acid, a base, or a radical by receiving an actinic ray such as an ultraviolet ray or a visible ray.

As the compound C, a known compound such as a photoacid generator, a photobase generator, or a photoradical polymerization initiator (a photoradical generator) can be used. Among the above, a photoacid generator is preferable.

### Photoacid Generator

From the viewpoint of resolution, the thermoplastic resin layer preferably contains a photoacid generator.

Examples of the photoacid generator include a photocationic polymerization initiator which may be contained in the above-described negative tone photosensitive resin layer, and the same applies to the preferred aspect thereof except for the points described later.

From the viewpoints of sensitivity and resolution, the photoacid generator preferably contains at least one compound selected from the group consisting of an onium salt compound and an oxime sulfonate compound, and from the viewpoints of sensitivity, resolution, and adhesiveness, it more preferably contains an oxime sulfonate compound.

Further, the photoacid generator is preferably a photoacid generator having the following structure.

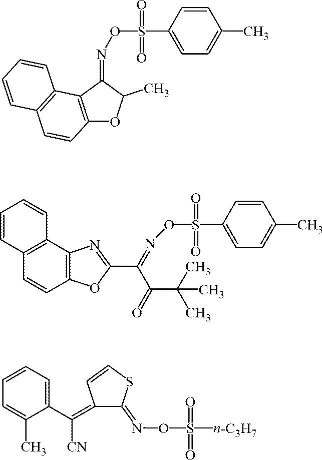

### Photoradical Polymerization Initiator

The thermoplastic resin layer may contain a photoradical polymerization initiator.

Examples of the photoradical polymerization initiator include a photoradical polymerization initiator which may be contained in the above-described negative tone photosensitive resin layer, and the same applies to the preferred aspect thereof.

### Photobase Generator

The thermoplastic resin composition may contain a photobase generator.

The photobase generator is not particularly limited as long as it is a known photobase generator, and examples thereof include 2-nitrobenzylcyclohexylcarbamate, triphenyl methanol, O-carbamoylhydroxylamide, O-carbamoyloxime, [[(2,6-dinitrobenzyl)oxy]carbonyl]cyclohexylamine, bis[[(2-nitrobenzyl)oxy]carbonyl]hexane-1,6-diamine, 4-(methylthiobenzoyl)-1-methyl-1-morpholinoethane, (4-morpholinobenzoyl)-1-benzyl-1-dimethylaminopropane, N-(2-nitrobenzyloxycarbonyl)pyrrolidine, hexaammine cobalt (III) tris(triphenylmethylborate), 2-benzyl-2-dimethylamino-1-(4-morpholinophenyl)-butanone, 2,6-dimethyl-3,5-diacetyl-4-(2-nitrophenyl)-1,4-dihydropyridine, and 2,6-dimethyl-3,5-diacetyl-4-(2,4-dinitrophenyl)-1,4-dihydropyridine.

One kind of the compound C may be used alone, or two or more kinds thereof may be used.

From the viewpoints of the visibility of the exposed portion and the non-exposed portion and the resolution, the content of the compound C is preferably 0.1% to 10% by mass and more preferably 0.5% to 5% by mass with respect to the total mass of the thermoplastic resin layer.

### Plasticizer

The thermoplastic resin layer preferably contains a plasticizer from the viewpoints of resolution, adhesiveness to an adjacent layer, and developability.

The plasticizer preferably has a molecular weight (a weight-average molecular weight in a case where the plasticizer is an oligomer or a polymer and has a molecular weight distribution) smaller than that of the alkali-soluble resin. The molecular weight (the weight-average molecular weight) of the plasticizer is preferably 200 to 2,000.

The plasticizer is not particularly limited as long as it is a compound that is compatible with an alkali-soluble resin and exhibits plasticity. However, from the viewpoint of imparting plasticity, the plasticizer preferably has an alkyleneoxy group in the molecule, and it is more preferably a polyalkylene glycol compound. The alkyleneoxy group contained in the plasticizer more preferably has a polyethyleneoxy structure or a polypropyleneoxy structure.

In addition, the plasticizer preferably contains an (meth)acrylate compound from the viewpoints of resolution and storage stability. From the viewpoint of compatibility, resolution, and adhesiveness to an adjacent layer, it is more preferable that the alkali-soluble resin is an acrylic resin and the plasticizer contains a (meth)acrylate compound.

Examples of the (meth)acrylate compound that is used as the plasticizer include the (meth)acrylate compound described as the polymerizable compound contained in the negative tone photosensitive resin layer described above.

In a transfer film, in a case where the thermoplastic resin layer and the negative tone photosensitive resin layer are laminated in direct contact with each other, it is preferable that both the thermoplastic resin layer and the photosensitive resin layer contain the same (meth)acrylate compound. This is due to the reason that in a case where the thermoplastic resin layer and the negative tone photosensitive resin layer each contain the same (meth)acrylate compound, the diffusion of components between the layers is suppressed and the storage stability is improved.

In a case where the thermoplastic resin layer contains a (meth)acrylate compound as a plasticizer, it is preferable that the (meth)acrylate compound does not polymerize even in the exposed portion after exposure from the viewpoint of adhesiveness to a layer adjacent to the thermoplastic resin layer.

In addition, the (meth)acrylate compound that is used as a plasticizer is preferably a polyfunctional (meth)acrylate compound having two or more a (meth)acryloyl groups in one molecule from the viewpoints of the resolution of the thermoplastic resin layer, the adhesiveness to an adjacent layer, and the developability.

Further, the (meth)acrylate compound that is used as a plasticizer is also preferably a (meth)acrylate compound having an acid group or a urethane (meth)acrylate compound.

One kind of plasticizer may be used alone, or two or more kinds thereof may be used.

From the viewpoints of the resolution of the thermoplastic resin layer, the adhesiveness to an adjacent layer, and the developability, the content of the plasticizer is preferably 1% to 70% by mass, more preferably 10% to 60% by mass, and still more preferably 20% to 50% by mass, with respect to the total mass of the thermoplastic resin layer.

### Sensitizing Agent

The thermoplastic resin layer may contain a sensitizing agent.

The sensitizing agent is not particularly limited, and examples thereof include a sensitizing agent which may be contained in the negative tone photosensitive resin layer described above.

One kind of sensitizing agent may be used alone, or two or more kinds thereof may be used.

The content of the sensitizing agent can be appropriately selected depending on the intended purpose. However, it is preferably 0.01% to 5% by mass and more preferably 0.05% to 1% by mass with respect to the total mass of the thermoplastic resin layer from the viewpoints of the improvement of the sensitivity to the light source and the visibility of the exposed portion and the non-exposed portion.

### Additive and the Like

The thermoplastic resin layer may contain known additives in addition to the above components, as necessary.

In addition, the thermoplastic resin layer is described in paragraphs 0189 to 0193 of JP2014-085643A, and the content described in this publication is incorporated in the present specification.

The layer thickness of the thermoplastic resin layer is not particularly limited; however, it is preferably 1 µm or more and more preferably 2 µm or more from the viewpoint of adhesiveness to an adjacent layer. The upper limit is not particularly limited. However, it is preferably 20 µm or less, more preferably 10 µm or less, and still more preferably 8 µm or less from the viewpoints of developability and resolution.

It is noted that although the transfer film 10 of FIG. 1 has been described as an example of the transfer film of the first aspect, the present invention is not limited thereto. For example, a configuration in which another layer other than the thermoplastic resin layer 3, the water-soluble resin layer 5, and the photosensitive resin layer 7 is provided between the temporary support 1 and the cover film 9 may be adopted, or a configuration in which the thermoplastic resin layer 3 is not provided may be adopted. Further, a configuration in which the thermoplastic resin layer 3, the water-soluble resin layer 5, the photosensitive resin layer 7, and the cover film 9 are provided not only on one surface of the temporary support 1 but also on both surfaces thereof may be adopted.

### Manufacturing Method for Transfer Film of First Aspect

The manufacturing method for the transfer film of the first aspect is not particularly limited, and a known manufacturing method, for example, a known method of forming each layer can be used.

Hereinafter, a manufacturing method for the transfer film of the first aspect will be described with reference to FIG. 1. However, the transfer film of the first aspect is not limited to that having the configuration illustrated in FIG. 1.

Examples of the manufacturing method for the transfer film 10 include a method including a step of applying the thermoplastic resin composition onto the surface of the temporary support 1 to form a coating film and then drying the coating film to form the thermoplastic resin layer 3, a step of applying the water-soluble resin composition onto the surface of the thermoplastic resin layer 3 to form a coating and then drying the coating film to form the water-soluble resin layer 5, and a step of applying the photosensitive resin composition (the negative tone photosensitive resin composition) onto the surface of the water-soluble resin layer 5 to form a coating film and then drying the coating film to form the photosensitive resin layer 7 (the negative tone photosensitive resin layer).

The methods of forming the thermoplastic resin composition and the thermoplastic resin layer, the methods of forming the water-soluble resin composition and the water-soluble resin layer, and the methods of forming the photosensitive resin composition (the negative tone photosensitive resin composition) and the photosensitive resin layer (the negative tone photosensitive resin layer) will be described later.

The cover film 9 is subjected to pressure bonding to the photosensitive resin layer 7 of the laminate manufactured by the manufacturing method described above, whereby the transfer film 10 is manufactured.

It is preferable that the manufacturing method for the transfer film of the first aspect includes a step of providing a cover film 9 to be in contact with a surface of the photosensitive resin layer 7 on a side opposite to a side where the temporary support 1 is provided, whereby the transfer film 10 including the temporary support 1, the thermoplastic resin layer 3, the water-soluble resin layer 5, the photosensitive resin layer 7, and the cover film 9 is manufactured.

After manufacturing the transfer film 10 according to the above-described manufacturing method, the transfer film 10 may be wound backward to produce and store the transfer film having a form of a roll. The transfer film having a roll form can be provided as it is in the affixing step to a substrate by the roll-to-roll method described later.

In addition, the manufacturing method for the transfer film 10 described above may be a method in which the photosensitive resin layer 7 and the water-soluble resin layer 5 are formed on the cover film 9, and then the thermoplastic resin layer 3 is formed on the surface of the water-soluble resin layer 5.

### Methods of Forming Thermoplastic Resin Composition and Thermoplastic Resin Layer

It is preferable that the thermoplastic resin composition contains various components that form the thermoplastic resin layer described above, and a solvent. It is noted that in the thermoplastic resin composition, the suitable range of the content of each component with respect to the total solid content of the composition is the same as the suitable range of the content of each component with respect to the total mass of the thermoplastic resin layer described above.

The solvent contained is not particularly limited as long as each component other than the solvent can be dissolved or dispersed, and a known solvent can be used. Specific examples thereof include an alkylene glycol ether solvent, an alkylene glycol ether acetate solvent, an alcohol solvent (methanol, ethanol, or the like), a ketone solvent (acetone, methyl ethyl ketone, or the like), an aromatic hydrocarbon solvent (toluene or the like), an aprotonic polar solvent (N,N-dimethylformamide or the like), a cyclic ether solvent (tetrahydrofuran or the like), an ester solvent (n-propyl acetate or the like), an amide solvent, a lactone solvent, and a mixed solvent containing two or more of these.

The solvent preferably contains at least one selected from the group consisting of an alkylene glycol ether solvent and an alkylene glycol ether acetate solvent. Among the above, the solvent is more preferably a mixed solvent containing at least one solvent selected from the group consisting of an alkylene glycol ether solvent and an alkylene glycol ether acetate solvent and at least one solvent selected from the group consisting of a ketone solvent and a cyclic ether solvent, and still more preferably a mixed solvent containing at least three solvents of at least one solvent selected from the group consisting of an alkylene glycol ether solvent and an alkylene glycol ether acetate solvent, a ketone solvent, and a cyclic ether solvent.

Examples of the alkylene glycol ether solvent include ethylene glycol monoalkyl ether, ethylene glycol dialkyl ether, propylene glycol monoalkyl ether (propylene glycol monomethyl ether acetate or the like), propylene glycol dialkyl ether, diethylene glycol dialkyl ether, dipropylene glycol monoalkyl ether, and dipropylene glycol dialkyl ether.

Examples of the alkylene glycol ether acetate solvent include ethylene glycol monoalkyl ether acetate, propylene glycol monoalkyl ether acetate, diethylene glycol monoalkyl ether acetate, and dipropylene glycol monoalkyl ether acetate.

As the solvent, the solvents described in paragraphs 0092 to 0094 of WO2018/179640A and the solvents described in paragraph 0014 of JP2018-177889A may be used, the contents of which are incorporated in the present specification.

The content of the solvent is preferably 50 to 1,900 parts by mass and more preferably 100 to 900 parts by mass with respect to 100 parts by mass of the total solid content of the composition.

The method of forming the thermoplastic resin layer is not particularly limited as long as it is a method capable of forming a layer containing the above components, and examples thereof include known coating methods (slit coating, spin coating, curtain coating, and inkjet coating).

### Methods of Forming Water-Soluble Resin Composition and Water-Soluble Resin Layer

It is preferable that the water-soluble resin composition contains various components that form the water-soluble resin layer described above, and a solvent. It is noted that in the water-soluble resin composition, the suitable range of the content of each component with respect to the total solid content of the composition is the same as the suitable range of the content of each component with respect to the total mass of the water-soluble resin layer described above.

The solvent is not particularly limited as long as the water-soluble resin is capable of being dissolved or dispersed, and the solvent is preferably at least one selected from the group consisting of water and a water-miscible organic solvent, and it is more preferably water or a mixed solvent of water and a water-miscible organic solvent.

Examples of the water-miscible organic solvent include alcohol having 1 to 3 carbon atoms, acetone, ethylene glycol, and glycerin, where alcohol having 1 to 3 carbon atoms is preferable, and methanol or ethanol is more preferable.

One kind of solvent may be used alone, or two or more kinds thereof may be used.

The content of the solvent is preferably 50 to 2,500 parts by mass, more preferably 50 to 1,900 parts by mass, still more preferably 100 to 900 parts by mass, with respect to 100 parts by mass of the total solid content of the composition.

The method of forming the water-soluble resin layer is not particularly limited as long as it is a method capable of forming a layer containing the above components, and examples thereof include known coating methods (slit coating, spin coating, curtain coating, and inkjet coating).

### Methods of Forming Photosensitive Resin Composition (Negative Tone Photosensitive Resin Composition) and Photosensitive Resin Layer (Negative Tone Photosensitive Resin Layer)

It is preferable that the photosensitive resin composition (the negative tone photosensitive resin composition) contains various components that form the photosensitive resin layer (the negative tone photosensitive resin layer) described above, and a solvent. It is noted that in the photosensitive resin composition (the negative tone photosensitive resin composition), the suitable range of the content of each component with respect to the total solid content of the composition is the same as the suitable range of the content of each component with respect to the total mass of the photosensitive resin layer (the negative tone photosensitive resin layer) described above.

The solvent contained is not particularly limited as long as each component (the compound A, the polymer A, or the like) other than the solvent can be dissolved or dispersed, and a known solvent can be used. Examples of the solvent include the same ones as the solvents described in the above-described thermoplastic resin composition, and the same applies to the preferred aspect thereof.

One kind of solvent may be used alone, or two or more kinds thereof may be used.

The content of the solvent is preferably 50 to 1,900 parts by mass, more preferably 100 to 1,200 parts by mass, and still more preferably 100 to 900 parts by mass, with respect to 100 parts by mass of the total solid content of the composition.

The method of forming the photosensitive resin layer (the negative tone photosensitive resin layer) is not particularly limited as long as it is a method capable of forming a layer containing the above components, and examples thereof include known coating methods (slit coating, spin coating, curtain coating, and inkjet coating).

### Transfer Film of Second Aspect

Hereinafter, an example according to the embodiment of the transfer film of the second aspect will be described.

A transfer film 20 illustrated in FIG. 2 has a temporary support 11, a photosensitive resin layer 13, a water-soluble resin layer 15, and a cover film 17 in this order.

It is noted that although the transfer film 20 illustrated in FIG. 2 has a form in which the cover film 17 is disposed, the cover film 17 may not be disposed.

Hereinafter, each element that constitutes the transfer film of the second aspect will be described.

In the transfer film of the second aspect, examples of the temporary support 11, the photosensitive resin layer 13, and the cover film 17 respectively include the same ones as the temporary support 1, the photosensitive resin layer 7, and the cover film 9 of the first embodiment described above, and the same applies to the preferred aspects thereof.

### Water-Soluble Resin Layer

In the transfer film 20, the water-soluble resin layer 15 functions as a refractive index adjusting layer for adjusting the refractive index. That is, as one aspect of the transfer film of the second aspect, the water-soluble resin layer can function as a refractive index adjusting layer for adjusting the refractive index.

The water-soluble resin layer 15 contains the compound A, a resin, and a material for adjusting the refractive index (a refractive index adjusting material: for example, at least one material selected from the group consisting of a metal oxide, a compound having a triazine ring, and a compound having a fluorene skeleton). The resin includes a water-soluble resin as a part or the whole thereof. As defined above, the “water-soluble resin” means a resin having a solubility of 0.1 g or more in 100 g of water having a liquid temperature of 22° C. and a pH of 7.0.

Hereinafter, each component that can be contained in the water-soluble resin layer will be described.

### Compound A

The water-soluble resin layer contains the compound A.

Examples of the compound A include the same one as the compound A contained in the water-soluble resin layer of the transfer film of the first aspect, and the same applies to the suitable aspect thereof.

One kind of the compound A may be used alone, or two or more kinds thereof may be used.

The content of the compound A is preferably 0.001% to 10% by mass, more preferably 0.01% to 3% by mass, and still more preferably 0.02% to 1% by mass, with respect to the total mass of the water-soluble resin layer.

### Resin

The water-soluble resin layer contains a resin.

As described above, the resin includes a water-soluble resin as a part or the whole thereof.

Examples of the resin contained in the water-soluble resin layer include the same one as the water-soluble resin contained in the water-soluble resin layer of the transfer film of the first aspect.

One kind of water-soluble resin may be used alone, or two or more kinds thereof may be used.

The content of the water-soluble resin is preferably 1% to 50% by mass, more preferably 1% to 40% by mass, still more preferably 5% to 30% by mass, and particularly preferably 5% to 20% by mass, with respect to the total mass of the water-soluble resin layer.

In addition, the water-soluble resin layer may contain an alkali-soluble resin.

As the alkali-soluble resin, an alkali-soluble resin contained in the thermoplastic resin layer and the photosensitive resin layer in the transfer film of the first aspect can also be used.

In addition, the alkali-soluble resin is preferably a copolymer of (meth)acrylic acid and a vinyl compound, more preferably a copolymer of (meth)acrylic acid and allyl (meth)acrylate, and still more preferably a copolymer of methacrylic acid and allyl methacrylate.

In a case where the water-soluble resin is a copolymer of (meth)acrylic acid and a vinyl compound, the compositional ratio (mol%) thereof is, for example, preferably 90/10 to 20/80 and more preferably 80/20 to 30/70.

One kind of alkali-soluble resin may be used alone, or two or more kinds thereof may be used.

The content of the alkali-soluble resin is preferably 1% to 50% by mass, more preferably 1% to 40% by mass, still more preferably 5% to 30% by mass, and particularly preferably 5% to 20% by mass, with respect to the total mass of the water-soluble resin layer.

It is also preferable that the above-described water-soluble resin is an alkali-soluble resin.

### Refractive Index Adjusting Material

In addition, the water-soluble resin layer contains at least one material (refractive index adjusting material) selected from the group consisting of a metal oxide, a compound having a triazine ring, and a compound having a fluorene skeleton.

### Metal Oxide

The kind of metal oxide is not particularly limited, and examples of the metal oxide include known metal oxides. The metal of the metal oxide includes semimetals such as B, Si, Ge, As, Sb, and Te.

Examples of the metal oxide include zirconium oxide, titanium oxide, tin oxide, zinc oxide, indium tin oxide, indium oxide, aluminum oxide, and yttrium oxide.

Among these, the metal oxide is preferably, for example, at least one selected from the group consisting of zirconium oxide and titanium oxide from the viewpoint of easily adjusting the refractive index.

The metal oxide preferably has a particle shape.

The average primary particle diameter of the metal oxide particles is, for example, preferably 1 to 200 nm and more preferably 3 to 80 nm from the viewpoint of the transparency of the cured film.

The average primary particle diameter of the particles is calculated by measuring the particle diameters of 200 particles randomly selected using an electron microscope and arithmetically averaging the measurement results. It is noted that in a case where the shape of the particle is not spherical, the longest side of the particle is regarded as the particle diameter.

Examples of the commercially available product of the metal oxide particle include baked zirconium oxide particle (manufactured by CIK NanoTek Corporation, product name: ZRPGM15WT%-F04), baked zirconium oxide particle (manufactured by CIK NanoTek Corporation, product name: ZRPGM15WT%-F74), baked zirconium oxide particle (manufactured by CIK NanoTek Corporation, product name: ZRPGM15WT%-F75), baked zirconium oxide particle (manufactured by CIK NanoTek Corporation, product name: ZRPGM15WT%-F76), zirconium oxide particle (NanoUse OZ-S30M, manufactured by Nissan Chemical Industries, Ltd.), and zirconium oxide particles (NanoUse OZ-S30K, manufactured by Nissan Chemical Industries, Ltd.).

### Compound Having Triazine Ring

Examples of the compound having a triazine ring include a polymer having a triazine ring in the structural unit, where a compound having a structural unit represented by General Formula (X) is included.

It is preferable that the polymer having a triazine ring in the structural unit is different from the above-described resin which can be contained in the water-soluble resin.

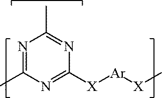

In the formula, Ar represents a divalent group including at least one selected from an aromatic ring (having, for example, 6 to 20 carbon atoms) or a heterocyclic ring (having, for example, 5 to 20 carbon atoms).

X’s each independently represent NR¹. R¹′s each independently represent a hydrogen atom, an alkyl group (having, for example, 1 to 20 carbon atoms), an alkoxy group (having, for example, 1 to 20 carbon atoms), an aryl group (having, for example, 6 to 20 carbon atoms), or an aralkyl group (having, for example, 7 to 20 carbon atoms). A plurality of X’s may be the same or different from each other.

Specifically, it is preferably a hyperbranched polymer having a triazine ring, and it is commercially available, for example, as HYPERTECH series (product name, manufactured by Nissan Chemical Industries, Ltd.).

### Compound Having Fluorene Skeleton

The compound having a fluorene skeleton is preferably a compound having a 9,9-bis[4-2-(meth)acryloyloxyethoxyphenyl]fluorene skeleton. The above compound may be modified with (poly)oxyethylene or (poly)oxypropylene. These are commercially available, for example, as EA-0200 (product name, manufactured by Osaka Gas Chemicals Co., Ltd.). Further, epoxy modification may be carried out with epoxy acrylate. These are commercially available, for example, as GA5000 or EG200 (product name, manufactured by Osaka Gas Chemicals Co., Ltd.).

One kind of the refractive index adjusting material may be used alone, or two or more kinds thereof may be used.

The content of the refractive index adjusting material in the water-soluble resin layer is preferably 50% by mass or more, more preferably 60% by mass or more, and particularly preferably 70% by mass or more, with respect to the total mass of the water-soluble resin layer. The upper limit thereof is not particularly limited; however, it is preferably 95% by mass or less and more preferably 90% by mass or less.

### Metal Oxidation Inhibitor

In addition, the water-soluble resin layer preferably contains a metal oxidation inhibitor.

In a case where the water-soluble resin layer contains a metal oxidation inhibitor, the oxidation of a metal in the water-soluble resin layer can be suppressed.

The metal oxidation inhibitor is preferably, for example, a compound having an aromatic ring containing a nitrogen atom in the molecule. Examples of the metal oxidation inhibitor include imidazoles, benzimidazoles, tetrazoles, mercaptothiadiazoles, benzotriazoles, pyridines (isonicotinamide and the like), and purine bases (adenine and the like).

As the benzotriazoles, it is also possible to use, for example, the benzotriazoles described in the description of the photosensitive resin layer in the transfer film of the first aspect.

The content of the metal oxidation inhibitor is preferably 0.01% to 10% by mass and more preferably 0.1% to 5% by mass with respect to the total mass of the water-soluble resin layer.

### Polymerizable Compound

The water-soluble resin layer may contain a polymerizable compound.

The content of the polymerizable compound is, for example, preferably 0.01% to 10% by mass and more preferably 0.1% to 5% by mass with respect to the total mass of the water-soluble resin layer.

Examples of the polymerizable compound include the same one as the polymerizable compound which can be contained in the photosensitive resin layer of the transfer film of the first aspect, among which a polymerizable compound having an acid group is preferable.

### Other Components

The water-soluble resin layer may include components other than the above components.

Examples of the other components also include amino alcohol (N-methyldiethanolamine, monoisopropanolamine, and the like). The amino alcohol is preferably a compound having one or more (for example, 1 to 5) primary alcohol groups and one or more (for example, 1 to 5) primary to tertiary amino groups. The content of the amino alcohol is, for example, preferably 0.01% to 10% by mass and more preferably 0.1% to 5% by mass with respect to the total mass of the water-soluble resin layer.

The refractive index of the water-soluble resin layer is preferably 1.60 or more and more preferably 1.63 or more. The upper limit of the refractive index is preferably 2.10 or less, and more preferably 1.85 or less.

The thickness of the water-soluble resin layer is preferably 500 nm or less, more preferably 110 nm or less, and still more preferably 100 nm or less. The lower limit of the thickness is, for example, 20 nm or more.

### Manufacturing Method for Transfer Film of Second Aspect

The manufacturing method for the transfer film of the second aspect is not particularly limited, and a known manufacturing method, for example, a known method of forming each layer can be used.

Hereinafter, a manufacturing method for the transfer film of the second aspect will be described with reference to FIG. 2. However, the transfer film of the second aspect is not limited to that having the configuration illustrated in FIG. 2.

Examples of the manufacturing method for the transfer film 20 include a step of applying the photosensitive resin composition (the negative tone photosensitive resin composition) onto the surface of the temporary support 11 to form a coating film and then drying the coating film to form the photosensitive resin layer 13 (the negative tone photosensitive resin layer) and a step of applying the water-soluble resin composition onto the surface of the photosensitive resin layer 13 (the negative tone photosensitive resin layer) to form a coating film and then drying the coating film to form the water-soluble resin layer 15.

The water-soluble resin composition and the method for forming the water-soluble resin layer will be described later. The methods of forming the photosensitive resin composition (the negative tone photosensitive resin composition) and the photosensitive resin layer (the negative tone photosensitive resin layer) are the same as those described in the manufacturing method for the transfer film of the first aspect described, and the same applies to the preferred aspects thereof.

The cover film 17 is subjected to pressure bonding to the water-soluble resin layer 15 of the laminate manufactured by the manufacturing method described above, whereby the transfer film 20 is manufactured.

It is preferable that the manufacturing method for the transfer film of the second aspect includes a step of providing the cover film 17 to be in contact with the surface of the water-soluble resin layer 15 on a side opposite to a side where the temporary support 11 is provided, whereby the transfer film 20 including the temporary support 11, the photosensitive resin layer 13, the water-soluble resin layer 15, and the cover film 17 is manufactured.

After manufacturing the transfer film 20 according to the above-described manufacturing method, the transfer film 20 may be wound backward to produce and store the transfer film having a form of a roll. The transfer film having a roll form can be provided as it is in the affixing step to a substrate by the roll-to-roll method described later.

In addition, the manufacturing method for the transfer film 20 described above may be a method in which the water-soluble resin layer 15 is formed on the cover film 17, and then the photosensitive resin layer 13 is formed on the surface of the water-soluble resin layer 15.

### Methods of Forming Water-Soluble Resin Composition and Water-Soluble Resin Layer

It is preferable that the water-soluble resin composition contains various components that form the water-soluble resin layer described above, and a solvent. It is noted that in the water-soluble resin composition, the suitable range of the content of each component with respect to the total solid content of the composition is the same as the suitable range of the content of each component with respect to the total mass of the water-soluble resin layer described above.

The solvent is not particularly limited as long as the compound A and the water-soluble resin are capable of being dissolved or dispersed, and the solvent is preferably at least one selected from the group consisting of water and a water-miscible organic solvent, and it is more preferably water or a mixed solvent of water and a water-miscible organic solvent.

Examples of the water-miscible organic solvent include alcohol having 1 to 3 carbon atoms, acetone, ethylene glycol, and glycerin, where alcohol having 1 to 3 carbon atoms is preferable, and methanol or ethanol is more preferable.

One kind of solvent may be used alone, or two or more kinds thereof may be used.

The content of the solvent is preferably 50 to 2,500 parts by mass, more preferably 50 to 1,900 parts by mass, still more preferably 100 to 900 parts by mass, with respect to 100 parts by mass of the total solid content of the composition.

The method of forming the water-soluble resin layer is not particularly limited as long as it is a method capable of forming a layer containing the above components, and examples thereof include known coating methods (slit coating, spin coating, curtain coating, and inkjet coating).

### Manufacturing Method for Laminate and Manufacturing Method for Circuit Wire

The present invention also relates to a manufacturing method for a laminate.

The manufacturing method for a laminate is not particularly limited as long as it is a manufacturing method for a laminate using the transfer film of the first aspect and the second aspect described above.

The manufacturing method for a laminate preferably includes an affixing step of bringing a substrate (preferably a substrate having conductivity) into contact with a surface of the outermost layer among composition layers disposed on a temporary support in a transfer film and affixing the transfer film to the substrate (preferably the substrate having conductivity) to obtain a transfer film-attached substrate (hereinafter, also referred to as the “affixing step”), an exposure step of subjecting the composition layer to pattern exposure (hereinafter, also referred to as the “exposure step”), a development step of developing the exposed composition layer to form a resin pattern (hereinafter, also referred to the “development step”), and a peeling step of peeling the temporary support from the transfer film-attached substrate, between the affixing step and the exposure step or between the exposure step and the development step (hereinafter, also referred to as the “peeling step”).

The manufacturing method for a circuit wire is not particularly limited as long as it is a manufacturing method for a circuit wire using the transfer film of the first aspect and the second aspect described above.

In a laminate in which a substrate, a conductive layer (a conductive layer included in the substrate), and a resin pattern manufactured by using the above-described transfer film are laminated in this order, the manufacturing method for a circuit wire is preferably a method including a step (hereinafter, also referred to as an “etching step”) of subjecting the conductive layer present in a region where the resin pattern is not disposed to an etching treatment.

That is, the manufacturing method for a circuit wire is preferably a method including an affixing step of bringing a substrate having a conductive layer into contact with a surface of an outermost layer among composition layers disposed on a temporary support in a transfer film and affixing the transfer film to the substrate having the conductive layer to obtain a transfer film-attached substrate (hereinafter, also referred to as the “affixing step”), an exposure step of subjecting the composition layer to pattern exposure (hereinafter, also referred to as the “exposure step”), a development step of developing the exposed composition layer to form a resin pattern (hereinafter, also referred to the “development step”), a step of subjecting the conductive layer present in a region where the resin pattern is not disposed to an etching treatment (hereinafter, also referred to as the “etching step”), and a peeling step of peeling the temporary support from the transfer film-attached substrate, between the affixing step and the exposure step or between the exposure step and the development step (hereinafter, also referred to as the “peeling step”).

Hereinafter, each step included in the manufacturing method for a laminate and the manufacturing method for a circuit wire will be described. However, unless otherwise specified, the content of the description for each step included in the manufacturing method for a laminate shall also apply to the manufacturing method for a circuit wire.

### Affixing Step

The manufacturing method for a laminate preferably includes an affixing step.

In the affixing step, it is preferable that a substrate (a conductive layer in a case where a conductive layer is provided on a surface of a substrate) is brought into contact with a surface of an outermost layer of composition layers disposed on a temporary support in a transfer film, and the transfer film is subjected to pressure bonding to the substrate. Since the above aspect improves the adhesiveness between the composition layer and the substrate, it can be suitably used as an etching resist, in particular, in a case where a conductive layer is etched by using a resin pattern on which a pattern is formed after the exposure and the development.

In a case where the transfer film includes a cover film, the cover film may be removed from the surface of the transfer film and then affixed.

The method of subjecting the substrate to pressure bonding to the transfer film is not particularly limited, and a known transfer method or a laminating method can be used.

The affixing of the transfer film to the substrate is preferably carried out by superposing the substrate on a surface of the transfer film on a side opposite to the temporary support and then applying pressure using a means such as a roll and carrying out heating. For affixing, it is possible to use a known laminator such as a laminator, a vacuum laminator, or an auto-cut laminator capable of further improving productivity.

The manufacturing method for a laminate including the affixing step and the manufacturing method for a circuit wire are preferably carried out according to a roll-to-roll method.

The roll-to-roll method refers to a method that includes, in a case of using a substrate capable of being wound backward and wound forward as the substrate, a step (also referred to as a “forward winding step”) of winding forward the substrate or a structure body including the substrate before any one of the steps included in the manufacturing method for a laminate or the manufacturing method for a circuit wire and a step (also referred to as a “backward winding step”) of winding backward the substrate or the structure body including the substrate after any one of the above steps, and at least any one of the steps (preferably all steps or all steps other than the heating step) is carried out while transporting the substrate or the structure body including the substrate.

The forward winding method in the forward winding step and the backward winding method in the backward winding step are not particularly limited, and known methods may be used in the manufacturing method to which the roll-to-roll method is applied.

### Substrate

As the substrate used for forming the resin pattern using the transfer film of the first aspect and the second aspect, a known substrate may be used; however, a substrate having a conductive layer is preferable, and it is more preferable to have a conductive layer on the surface of the base material.

The substrate may have any layer other than the conductive layer, as necessary.

Examples of the base material that constitutes the substrate include glass, silicon, and a film.

The base material that constitutes the substrate is preferably transparent. In the present specification, “transparent” means that the transmittance of light having a wavelength of 400 to 700 nm is 80% or more.

In addition, the refractive index of the base material that constitutes the substrate is preferably 1.50 to 1.52.

Examples of the transparent glass base material include reinforced glass represented by Gorilla Glass manufactured by Corning Incorporated. Further, as the transparent glass base material, the materials used in JP2010-086684A, JP2010-152809A, and JP2010-257492A can be used.

In a case where a film base material is used as the base material, it is preferable to use a film base material having low optical distortion and/or high transparency. Examples of such a film base material include polyethylene terephthalate (PET), polyethylene naphthalate, polycarbonate, triacetyl cellulose, and a cycloolefin polymer.

The base material of the substrate is preferably a film base material in a case of being manufactured by a roll-to-roll method. Further, in a case where a circuit wire for a touch panel is manufactured by a roll-to-roll method, it is preferable that the base material is a sheet-shaped resin composition.

Examples of the conductive layer included in the substrate include a conductive layer that is used for a general circuit wire and a touch panel wire.

From the viewpoint of conductivity and thin wire forming properties, the conductive layer is preferably at least one layer selected from the group consisting of a metal layer, a conductive metal oxide layer, a graphene layer, a carbon nanotube layer, and a conductive polymer layer, more preferably a metal layer, and still more preferably a copper layer or a silver layer.

The substrate may have one conductive layer alone or may have two or more conductive layers. In a case of having two or more conductive layers, it is preferable to have conductive layers made of different materials.

Examples of the material of the conductive layer include a metal and a conductive metal oxide.

Examples of the metal include Al, Zn, Cu, Fe, Ni, Cr, Mo, Ag, and Au.

Examples of the conductive metal oxide include indium tin oxide (ITO), indium zinc oxide (IZO), and SiO₂.

In the present specification, “conductivity” means that the volume resistivity is less than 1 × 10⁶ Ωcm. The volume resistivity of the conductive metal oxide is preferably less than 1 × 10⁴ Ωcm.

In a case where a resin pattern is manufactured using a substrate having a plurality of conductive layers, it is preferable that at least one conductive layer among the plurality of conductive layers contains a conductive metal oxide.

The conductive layer is preferably an electrode pattern corresponding to a sensor of a visible part that is used in a capacitance type touch panel or a wire of a peripheral lead-out part.

### Exposure Step

The manufacturing method for a laminate preferably includes, after the affixing step, a step (an exposure step) of subjecting the composition layer to pattern exposure.

The detailed arrangement and the specific size of the pattern in the pattern exposure are not particularly limited. At least a part of the pattern (preferably, a portion of the electrode pattern and/or lead-out wire of the touch panel)preferably contains a thin wire having a width of 20 µm or less and more preferably contains a thin wire having a width of 10 µm or less so that the display quality of the display device (for example, a touch panel) including an input device having a circuit wire manufactured according to the manufacturing method for a circuit wire improved and the area occupied by the lead-out wire is reduced.

The light source that is used for exposure can be appropriately selected and used as long as it is a light source that emits light having a wavelength (for example, 365 nm or 405 nm) with which the photosensitive resin layer can be exposed. Specific examples thereof include an ultra-high pressure mercury lamp, a high pressure mercury lamp, a metal halide lamp, and a light emitting diode (LED).

The exposure amount is preferably 5 to 200 mJ/cm² and more preferably 10 to 100 mJ/cm².

### Peeling Step

The peeling step is a step of peeling the temporary support from the photosensitive composition layer-attached substrate between the affixing step and the exposure step, or between the exposure step and the development step described later.

The peeling method is not particularly limited, and a mechanism similar to the cover film peeling mechanism described in paragraphs [0161] and [0162] of JP2010-072589A can be used.

As a result, in the exposure step, the pattern exposure may be carried out after the temporary support is peeled off from the composition layer, or the pattern exposure may be carried out through the temporary support before the temporary support is peeled off, and then the temporary support may be peeled off. In a case where the temporary support is peeled off before exposure, the mask may be exposed in a state of being brought into contact with the composition layer or may be exposed in a state of being in close proximity without being brought into contact with the composition layer. In a case where the temporary support is exposed without peeling, the mask may be exposed in a state of being brought into contact with the temporary support or may be exposed in a state of being in close proximity without being brought into contact with the temporary support. In order to prevent mask contamination due to contact between the composition layer and the mask and to avoid the influence of foreign substances adhered to the mask on the exposure, it is preferable to carry out pattern exposure without peeling off the temporary support. The exposure method can be carried out by appropriately selecting and using a contact exposure method in a case of contact exposure, and in a case of a non-contact exposure method, a proximity exposure method, a lens-based and mirror-based projection exposure method, and a direct exposure method using an exposure laser or the like. In a case of the lens-based or mirror-based projection exposure, an exposure machine having a proper numerical aperture (NA) of a lens in response to the required resolving power and the focal depth can be used. In a case of the direct exposure method, drawing may be carried out directly on the photosensitive layer, or reduced projection exposure may be carried out on the photosensitive layer through a lens. Further, the exposure may be carried out not only in the atmospheric air but also under reduced pressure or vacuum, or the exposure may be carried out by interposing a liquid such as water between the light source and the photosensitive layer.

### Development Step

The manufacturing method for a laminate preferably includes, after the exposure step, a step (a development step) of developing the exposed composition layer to form a resin pattern.

In a case where the composition layer includes a negative tone photosensitive resin layer, the composition layer undergoes a curing reaction according to the exposed pattern to form a cured film (a patterned cured film), and only the non-exposed portion of the composition layer can be removed with a developer (an alkali developer or the like).

In a case where the transfer film has, together with the negative tone photosensitive resin layer, an additional different composition layer, only a portion similar to the portion of the different composition layer, which is removed in the negative tone photosensitive resin layer, may be removed, or an entire portion thereof including a portion other than the portion removed in the negative tone photosensitive resin layer may be removed.

For example, in a case where the transfer film has the thermoplastic resin layer and the water-soluble resin layer together with the negative tone photosensitive resin layer, only the thermoplastic resin layer and the water-soluble resin layer of the non-exposed portion may be removed in the development step together with the negative tone photosensitive resin layer of the non-exposed portion. In addition, in the development step, the thermoplastic resin layer and the water-soluble resin layer in both regions of the exposed portion and the non-exposed portion may be removed in a form of being dissolved or dispersed in the developer.

The development of the exposed composition layer in the development step can be carried out using a developer.

The developer may be appropriately selected depending on the properties of the composition layer included in the transfer film and the type of development, and examples thereof include an alkali developer and an organic developer.

As the alkali developer, it is possible to use, for example, a known developer such as the developer described in JP1993-072724A (JP-H5-072724A).

The alkali developer is preferably an alkaline aqueous solution-based developer containing a compound having pKa = 7 to 13 at a concentration of 0.05 to 5 mol/L (liter). The alkali developer may contain a water-soluble organic solvent and/or a surfactant. The alkali developer is also preferably the developer described in paragraph 0194 of WO2015/093271A. The content of the organic solvent in the alkali developer is preferably 0% by mass or more and less than 90% by mass with respect to the total mass of the developer.

As the organic developer, it is possible to use a developer containing one or more kinds of solvents among polar solvents of a ketone-based solvent, an ester-based solvent, an alcohol-based solvent, an amide-based solvent, and an ether-based solvent, and hydrocarbon-based solvents. The content of the organic solvent in the organic developer is preferably 90% to 100% by mass and more preferably 95% to 100% by mass with respect to the total mass of the developer.

The development method is not particularly limited, and it may be any of puddle development, shower development, shower, and spin development, and dip development. The shower development is a development treatment of removing the non-exposed portion by spraying a developer onto the photosensitive resin layer after exposure with a shower.

After the development step, it is preferable to spray a cleaning agent with a shower to remove the development residue while rubbing it with a brush.

The liquid temperature of the developer is not particularly limited; however, it is preferably 20° C. to 40° C.

### Etching Step

In a laminate in which a substrate, a conductive layer (a conductive layer included in the substrate), and a resin pattern (more preferably, a resin pattern manufactured according to the manufacturing method including the affixing step, the exposure step, and the development step) are laminated in this order, the manufacturing method for a circuit wire preferably contains a step (an “etching step”) of subjecting the conductive layer present in a region where the resin pattern is not disposed to an etching treatment.

In the etching step, the resin pattern formed from the photosensitive resin layer is used as an etching resist to carry out an etching treatment of the conductive layer.

As the method of etching treatment, a known method can be applied, and examples thereof include the methods described in paragraphs 0209 to 0210 of JP2017-120435A and paragraphs 0048 to 0054 of JP2010-152155A, a wet etching method in which immersion in an etchant is carried out, and a dry etching method such as plasma etching.

As the etchant that is used for wet etching, an acidic or alkaline etchant may be appropriately selected according to the etching target.

Examples of the acidic etchant include an aqueous solution of an acidic component alone selected from hydrochloric acid, sulfuric acid, nitric acid, acetic acid, hydrofluoric acid, oxalic acid, and phosphoric acid, and a mixed aqueous solution of an acidic component with a salt selected from iron (III) chloride, ammonium fluoride, or potassium permanganate. The acidic component may be a component in which a plurality of acidic components are combined.

Examples of the alkaline etchant include an aqueous solution of an alkaline component alone selected from sodium hydroxide, potassium hydroxide, ammonia, an organic amine, and a salt of an organic amine (tetramethylammonium hydroxide or the like), and a mixed aqueous solution of an alkaline component with a salt (potassium permanganate or the like). The alkaline component may be a component in which a plurality of alkaline components are combined.

### Removal Step

In the manufacturing method for a circuit wire, it is preferable to carry out a step (a removal step) of removing the remaining resin pattern.

The removal step is not particularly limited and can be carried out as necessary; however, it is preferably carried out after the etching step.

The method of removing the remaining resin pattern is not particularly limited; however, examples thereof include a method of carrying out removal by a chemical treatment, and a method of carrying out removal with a removing liquid is preferable.

Examples of the method of removing the photosensitive resin layer include a method in which a substrate having the remaining resin pattern is immersed in a removing liquid under stirring, having a liquid temperature of preferably 30° C. to 80° C. and more preferably 50° C. to 80° C. for 1 to 30 minutes.

Examples of the removing liquid include a removing liquid in which an inorganic alkaline component or an organic alkaline component is dissolved in water, dimethyl sulfoxide, N-methylpyrrolidone, or a mixed solution thereof. Examples of the inorganic alkaline component include sodium hydroxide and potassium hydroxide. Examples of the organic alkaline component include a primary amine compound, a secondary amine compound, a tertiary amine compound, and a quaternary ammonium salt compound.

Further, a removing liquid may be used and then removed by a known method such as a spray method, a shower method, or a puddle method.

### Other Steps

The manufacturing method for a circuit wire may include any steps (other steps) other than the above-described steps. Examples thereof include the following steps, which are not limited to these steps.

Further, examples of the exposure step, the development step, and the other steps, which are applicable to the manufacturing method for a circuit wire, include the steps described in paragraphs 0035 to 0051 of JP2006-023696A.

### Cover Film Peeling Step

In a case where the transfer film includes a cover film, the manufacturing method for a laminate preferably includes a step of peeling the cover film from the transfer film. The method of peeling the cover film is not limited, and a known method can be applied.

### Step of Reducing Visible Light Reflectivity

The manufacturing method for a circuit wire may include a step of carrying out a treatment of reducing the visible light reflectivity of a part or all of a plurality of conductive layers included in the base material.

Examples of the treatment of reducing the visible light reflectivity include an oxidation treatment. In a case where the base material has a conductive layer containing copper, the visible light reflectivity of the conductive layer can be reduced by subjecting copper to the oxidation treatment to obtain copper oxide and then blackening the conductive layer.

The treatment of reducing the visible light reflectivity is described in paragraphs 0017 to 0025 of JP2014-150118A and paragraph 0041, paragraph 0042, paragraph 0048, and paragraph 0058 of JP2013-206315A, and the contents described in these publications are incorporated in the present specification.

### Step of Forming Insulating Film and Step of Forming New Conductive Layer on Surface of Insulating Film

The manufacturing method for a circuit wire preferably includes a step of forming an insulating film on the surface of the circuit wire and a step of forming a new conductive layer on the surface of the insulating film.

These steps make it possible to form a second electrode pattern insulated from the first electrode pattern.

The step of forming an insulating film is not particularly limited, and examples thereof include a known method of forming a permanent film. Further, an insulating film having a desired pattern may be formed by photolithography using a photosensitive material having an insulating property.

The step of forming a new conductive layer on the insulating film is not particularly limited, and a new conductive layer having a desired pattern may be formed by, for example, photolithography using a photosensitive material having conductivity.

In the manufacturing method for a circuit wire, it is also preferable that a substrate having a plurality of conductive layers on both surfaces of the base material is used, and a conductive pattern is formed sequentially or simultaneously on the conductive layers formed on both surfaces of the base material. With such a configuration, it is possible to form a circuit wire for a touch panel in which the first conductive pattern is formed on one surface of the base material and the second conductive pattern is formed on the other surface thereof. It is also preferable to form a circuit wire for a touch panel, having such a configuration, from both surfaces of the base material in a roll-to-roll manner.

### Use Application of Circuit Wire

The circuit wire manufactured according to the manufacturing method for a circuit wire can be applied to various devices. Examples of the device including the circuit wire manufactured according to the above-described manufacturing method include an input device, where a touch panel is preferable, and a capacitance type touch panel is more preferable. In addition, the input device can be applied to display devices such as an organic EL display device and a liquid crystal display device.

### Manufacturing Method for Electronic Device

The present invention also relates to a manufacturing method for an electronic device.

The manufacturing method for an electronic device is preferably a manufacturing method for an electronic device using the transfer film of the first aspect and the second aspect described above.

Among the above, the manufacturing method for an electronic device preferably includes the above-described manufacturing method for a laminate.

Examples of the electronic device include an input device, where a touch panel is preferable. Further, the input device can be applied to display devices such as an organic electroluminescence display device and a liquid crystal display device.

In a laminate in which a substrate, a conductive layer (a conductive layer included in the substrate), and a resin pattern manufactured by using the transfer film of the first aspect and the second aspect are laminated in this order, the manufacturing method for a touch panel is also preferably a method including a step of subj ecting the conductive layer present in a region where the resin pattern is not disposed to an etching treatment to form a wire for a touch panel, and it is more preferably a method using a resin pattern that is manufactured by a manufacturing method including the affixing step, the exposure step, and the development step.

The specific aspect of each step in the manufacturing method for a touch panel including a step of forming a wire for a touch panel and the embodiment associated with the order for carrying out respective steps are as described in the above-described “manufacturing method for a circuit wire”, and the same applies to the preferred aspect thereof.

In addition, the manufacturing method for a touch panel including a step of forming a wire for a touch panel may include any steps (other steps) other than those described above.

As the method for forming a wire for a touch panel, the method described in FIG. 1 of WO2016/190405A can also be referred to.

A touch panel having at least a wire for a touch panel is manufactured by the above-described manufacturing method for a touch panel. The touch panel preferably has a transparent substrate, electrodes, and an insulating layer or protective layer.

Examples of the detection method for the touch panel include known methods such as a resistive membrane method, a capacitance method, an ultrasonic method, an electromagnetic induction method, and an optical method. Among the above, a capacitance method is preferable.

Examples of the touch panel include a so-called in-cell type (for example, those illustrated in FIG. 5, FIG. 6, FIG. 7, and FIG. 8 of JP2012-517051A), a so-called on-cell type (for example, one described in FIG. 19 of JP2013-168125A and those described in FIG. 1 and FIG. 5 of JP2012-89102A), an one glass solution (OGS) type, a touch-on-lens (TOL) type (for example, one described in FIG. 2 of JP2013-54727A), various out-cell types (so-called GG, G1·G2, GFF, GF2, GF1, GlF, and the like), and other configurations (for example, those described in FIG. 6 of JP2013-164871A).

Examples of the touch panel include those described in paragraph 0229 of JP2017-120345A.

In the manufacturing method for an electronic device using the transfer film of the first aspect or the second aspect, it is also preferable that an electronic device to be manufactured includes a resin pattern as a cured film (in particular, in a case where the transfer film includes a negative tone photosensitive composition layer).

Such a cured film having a resin pattern can be used as a protective film (a permanent film) that covers a part or the whole of an electrode or the like included in an electronic device (a touch panel or the like). In a case of disposing the cured film of the resin pattern on the electrode or the like as a protective film (a permanent film), it is possible to prevent problems such as metal corrosion, an increase in the electrical resistance between the electrode and the driving circuit, and disconnection.

### EXAMPLES

Hereinafter, the present invention will be described in more detail based on Examples below. The materials, amounts of use, proportions, treatments, procedures, and the like described in the following Examples can be modified as appropriate as long as the gist of the invention is maintained. Accordingly, the scope of the present invention shall not be restrictively interpreted by Examples shown below.

In the following Examples, unless otherwise specified, “parts” and “%” mean “parts by mass” and “% by mass”, respectively.

### Synthesis of Compound A

### Synthesis Examples 1 to 4: Synthesis of High-Molecular-Weight Compound A

### Synthesis Example 1

25.0 g of cyclohexanone (FUJIFILM Wako Pure Chemical Corporation) was charged into a three-neck flask of 300 ml and equipped with a stirrer, a thermometer, a reflux condenser, and a nitrogen gas introduction pipe, and the temperature was raised to 80° C. Next, a mixed solution consisting of 10.40 g (36.6 mmol) of 1H,1H,5H-octafluoropentyl acrylate (manufactured by Tokyo Chemical Industry Co., Ltd.), 60.5 g (111.8 mmol) of polyethylene glycol-monoacrylate (Blemmer AE-400, (n ≈ 10, manufactured by NOF CORPORATION), 25.0 g of cyclohexanone, and 0.342 g of an initiator “V-601” (manufactured by Fujifilm Wako Pure Chemical Corporation) were added dropwise thereto at a constant rate so that the dropwise addition was completed in 180 minutes. After completion of the dropwise addition, stirring was further continued for 1 hour, and then a solution consisting of 0.342 g of “V-601” and 1.00 g of cyclohexanone was further added thereto. Next, the temperature was raised to 93° C. immediately after the addition, and stirring was further continued for 2 hours to obtain 121.5 g of a cyclohexanone solution of a polymer A-1 shown in the latter part. The weight-average molecular weight (Mw) of this polymer was 11,000 (calculated in terms of polystyrene by gel permeation chromatography (EcoSEC HLC-8320GPC (manufactured by Tosoh Corporation)), measurement conditions of an eluent of THF, a flow rate of 0.35 ml/min, and a temperature of 40° C., used column: TSKgel SuperHZM-H, TSKgel SuperHZ4000, and TSKgel SuperHZ200 (manufactured by Tosoh Corporation).

### Synthesis Examples 2 to 4

Polymers A-5, A-6, and A-9 were synthesized according to the same method except that the monomer and the compositional ratio used in Synthesis Example 1 were each changed as shown in Table 1.

The structures of the polymers A-1, A-5, A-6, and A-9 are shown below. It is noted that the numerical value attached to the constitutional unit in the polymer indicates a content (in terms of% by mass) with respect to the total mass of the polymer.

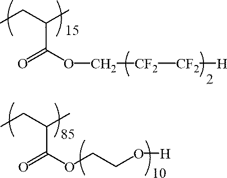

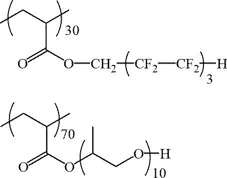

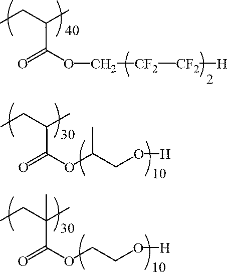

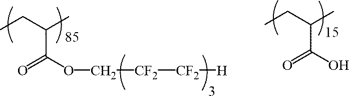

The weight-average molecular weight (Mw), the number-average molecular weight (Mn), and the dispersivity (Mw/Mn) of each polymer were as follows.

TABLE 1

| Synthesis Example | Kind of polymer | Mw | Mn | Mw/Mn |
|---|---|---|---|---|
| 1 | A-1 | 11000 | 5000 | 2.2 |
| 2 | A-5 | 12000 | 6030 | 1.99 |
| 3 | A-6 | 18000 | 7400 | 2.43 |
| 4 | A-9 | 9000 | 3900 | 2.29 |

### Synthesis Example 5: Synthesis of Low-Molecular-Weight Compound A

The following low-molecular-weight compound B-1 was synthesized with reference to the documents (“Tatematsu et al., Oil Chemistry, 1980, Vol.29 (1), p23” and “Tatematsu et al., Pharmaceutical Sciences, 1976, Vol.25 (5), p287”).

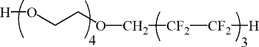

### Examples 1 to 8 and Comparative Examples 1 and 2

### Preparation of Photosensitive Resin Composition

### Production of Resin

In the following synthesis examples, the following abbreviations respectively indicates the following compounds.

St: Styrene (manufactured by FUJIFILM Wako Pure Chemical Corporation)
MAA: Methacrylic acid (manufactured by Fujifilm Wako Pure Chemical Corporation)
MMA: Methyl methacrylate (manufactured by FUJIFILM Wako Pure Chemical Corporation)
BzMA: Benzyl methacrylate (manufactured by Fujifilm Wako Pure Chemical Corporation)
AA: Acrylic acid (manufactured by Tokyo Chemical Industry Co., Ltd.)
PGMEA: Propylene glycol monomethyl ether acetate (manufactured by Showa Denko K.K.)
MEK: Methyl ethyl ketone (manufactured by SANKYO CHEMICAL Co., Ltd.)
V-601: Dimethyl-2,2′-azobis(2-methylpropionate) (manufactured by FUJIFILM Wako Pure Chemical Corporation)

### Synthesis of Resin P-1

PGMEA (116.5 parts) was placed in a three-neck flask, and the temperature was raised to 90° C. in a nitrogen atmosphere. A solution obtained by adding St (52.0 parts), MMA (19.0 parts), MAA (29.0 parts), V-601 (4.0 parts), and PGMEA (116.5 parts) was added dropwise over 2 hours to the solution in the flask maintained at 90° C. ± 2° C. After completion of the dropwise addition, the solution in the flask was stirred at 90° C. ± 2° C. for 2 hours to obtain a resin P-1 (solid content concentration: 30.0% by mass).

### Synthesis of Resins P-2 and P-3

The kind and the like of the monomer to be used were changed as shown Table 1, and the other conditions were the same as those in the method for the resin P-1, thereby obtaining a solution containing a resin P-2 and a solution containing a resin P-3. The solid content concentrations of the solution containing the resin P-2 and the solution containing the resin P-3 were each 30% by mass.

The kind of each monomer used for synthesizing each resin, the mass percentage (in terms of % by mass) of the constitutional unit derived from each monomer, and the weight-average molecular weight of each resin are shown below.

It is noted that all of the resins P-1 to P-3 correspond to the alkali-soluble resin.

TABLE 2

| | P-1 | P-2 | P-3 |
|---|---|---|---|
| St | 52 | | 32 |
| BzMA | | 81 | |
| MAA | 29 | 19 | 28 |
| MMA | 19 | | 40 |
| Weight-average molecular weight (Mw) | 60,000 | 4,0000 | 40,000 |

### Preparation of Photosensitive Resin Compositions 1 to 4

According to the prescriptions shown in Table 3 shown in the latter part, components were mixed with stirring to prepare photosensitive resin compositions 1 to 4. It is noted that the unit of the amount of each component is part by mass.

The formulation of each of the photosensitive resin compositions 1 to 4 is shown below.

In the table, the numerical value for each component in each photosensitive resin composition indicates the adding amount (in terms of part by mass) of each component.

It is noted that the resin was added to each photosensitive resin composition in a form of a solution containing the resin. In the table, the numerical value indicating the adding amount of the resin is the mass of the added “solution containing the resin”.

Hereinafter, the same shall apply to components which are added to the composition in a form of being contained in the mixed solution, unless otherwise specified.

TABLE 3

| | | Photosensitive resin composition r1 | Photosensitive resin composition r2 | Photosensitive resin composition r3 | Photosensitive resin composition r4 |
|---|---|---|---|---|---|
| Resin | P-1 | 500.0 | | | 51.00 |
| | P-2 | | | 59.20 | |
| | P-3 | | 62.20 | | |
| Polymerizab le compound, (Plasticizer) | BPE-500 | 36.20 | | 27.00 | 15.00 |
| | BPE-200 | | 20.00 | | |
| | Dimethacrylate of polyethylene glycol which is obtained by adding 15 mol of ethylene oxide in average and 2 mol of propylene oxide in average to both ends of bisphenol A, respectively | | | | 10.00 |
| | M-270 | 5.00 | | | |
| | A-TMPT | | 6.00 | | 5.00 |
| | SR-454 | | 9.00 | | 5.00 |
| | SR502 | | | 4.00 | |
| | A-9300-CL1 | | | 7.80 | 9.77 |
| Photopolym erization initiator | B-CIM | 7.00 | 1.90 | 1.10 | 3.00 |
| | SB-PI 701 | 0.60 | 0.30 | 0.10 | 0.30 |
| Coloring agent | Leucocrystal violet | 0.40 | 0.40 | 0.66 | 0.60 |
| | Brilliant green | | 0.05 | | 0.02 |
| Additive | N-phenylglycine | 0.20 | | | |
| | CBT-1 | 0.10 | 0.03 | 0.03 | |
| | 1:1 mixture (in terms of mass ratio) of 1-(2-di-n-butylaminomethyl)-5-carboxybenzotriazole and 1-(2-di-n-butylaminomethyl)-6-carboxybenzotriazole | | | | 0.10 |
| | TDP-G | 0.30 | | | |
| | Irganox 245 | | 0.10 | 0.10 | 0.20 |
| | N-nitrosophenyl hydroxylamine aluminum salt | | 0.02 | 0.01 | 0.01 |
| | Phenidone | 0.01 | | | |
| Surfactant | MEGAFACE F552 | 0.29 | | | 0.29 |
| Solvent | 1-methoxy-2-propylacetate | 227 | 227 | 227 | 227 |
| | Methyl ethyl ketone | 340 | 340 | 340 | 340 |
| Average film thickness of photosensitive resin layer (µm) | | 2.0 | 2.0 | 2.0 | 2.0 |

Details of each component in Table 3 are as follows.
BPE-500: 2,2-bis(4-((meth)acryloxypentethoxy)phenyl)propane, manufactured by SHIN-NAKAMURA CHEMICAL Co., Ltd.
BPE-200: 2,2-bis(4-((meth)acryloxydiethoxy)phenyl)propane, manufactured by SHIN-NAKAMURA CHEMICAL Co., Ltd.
M-270: Polypropylene glycol diacrylate (n ≈ 12), manufactured by Toagosei Co., Ltd.
A-TMPT: Trimethylolpropane triacrylate, manufactured by SHIN-NAKAMURA CHEMICAL Co., Ltd.
SR-454: Ethoxylated (3) trimethylolpropane triacrylate, manufactured by Arkema S.A.
SR-502: Ethoxylated (9) trimethylolpropane triacrylate, manufactured by Arkema S.A.
A-9300-CL1: A caprolactone-modified (meth)acrylate compound, manufactured by SHIN-NAKAMURA CHEMICAL Co., Ltd.
B-CIM: 2,2′-bis(2-chlorophenyl)-4,4’,5,5′-tetraphenylbiimidazole, manufactured by Hampford Research Inc.
SB-PI701: 4,4′-bis(diethylamino)benzophenone, manufactured by Sanyo Trading Co., Ltd.
Leucocrystal violet: manufactured by Tokyo Chemical Industry Co., Ltd.
Brilliant green: Manufactured by Tokyo Chemical Industry Co., Ltd.
N-phenylglycine: Manufactured by Tokyo Chemical Industry Co., Ltd.
CBT-1: Carboxybenzotriazole, manufactured by JOHOKU CHEMICAL Co., Ltd.
TDP-G: Phenothiazine, manufactured by Kawaguchi Chemical Industry Company, Limited
Irganox 245: A hindered phenol-based antioxidant, manufactured by BASF SE
N-nitrosophenyl hydroxylamine aluminum salt: Manufactured by Fujifilm Wako Pure Chemical Corporation
Phenidone: Manufactured by Tokyo Chemical Industry Co., Ltd.
MEGAFACE F552, manufactured by DIC Corporation

### Preparation of Thermoplastic Resin Composition

### Synthesis of Resin P-4

The kind and the like of the monomer to be used were changed as shown Table 4, and the other conditions were the same as those in the method for the resin P-1, thereby obtaining a solution containing a resin P-4. The solid content concentration of the solution containing the resin P-4 was set to 30% by mass.

It is noted that the resin P-4 corresponds to the alkali-soluble resin.

The kind of each monomer used for synthesizing the resin, the mass percentage (in terms of % by mass) of the constitutional unit derived from each monomer, and the weight-average molecular weight of the resin are shown below.

TABLE 4

| | P-4 |
|---|---|
| BzMA | 75 |
| MAA | 10 |
| MMA | 15 |
| Weight-average molecular weight (Mw) | 30.000 |

### Preparation of Thermoplastic Resin Compositions 1 and 2

The following components were mixed according to parts by mass shown in Table 5 below to prepare thermoplastic resin compositions 1 and 2.

TABLE 5

| | | Thermoplastic resin composition 1 | Thermoplastic resin composition 2 |
|---|---|---|---|
| Resin | P-4 | 42.85 | 35.15 |
| | ACRYBASE FF187 (manufactured by Fujikura Kasei Co., Ltd.) | | 35.15 |
| Coloring agent | BB-1 | 0.08 | |
| Photoacid generator | C-1 | 0.32 | |
| Polymerizable compound (Plasticizer) | Tricyclodecanedimethanol diacrylate (A-DCP, manufactured by SHIN-NAKAMURA CHEMICAL Co, Ltd.) | 4.63 | 6.01 |
| | Monomer having carboxy group, ARONIX TO-2349 (manufactured by Toagosei Co., Ltd.) | 2.31 | 3.00 |
| | Urethane acrylate 8UX-015A (manufactured by Taisei Fine Chemical Co., Ltd.) | 0.77 | 1.00 |
| Surfactant | MEGAFACE F552 (manufactured by DIC Corporation) | 0.03 | |
| | MEGAFACE F551A (manufactured by DIC Corporation) | | 0.03 |
| Solvent | MEK | 39.5 | 39.5 |
| | PGMEA | 9.51 | 9.51 |
| Average film thickness of thermoplastic resin layer (µm) | | 2.0 | 2.0 |

In Table 5, the abbreviations indicate the following compounds, respectively.

P-4: A resin that contains a constitutional unit based on benzyl methacrylate, a constitutional unit based on methyl methacrylate, and a constitutional unit based on acrylic acid by 75% by mass, 10% by mass, and 15% by mass, respectively, with respect to the total mass of the resin, and has a weight-average molecular weight of 30,000. It is noted that P-4 corresponds to a resin which is an alkali-soluble resin which is a thermoplastic resin. In addition, P-4 was added to the thermoplastic resin composition in a form of a solution containing P-4 (solid content concentration: 30.0% by mass, solvent: PGMEA).
ACRYBASE FF187: A solution containing a resin which is an alkali-soluble thermoplastic resin (solid content concentration: 40% by mass, solvent: PGMEA, manufactured by Fujikura Kasei Co., Ltd.)
BB-1: A compound having the structure shown below (a coloring agent that develops color by an acid)

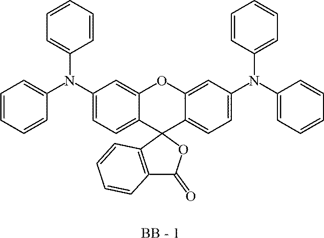

C-1: A compound having a structure shown below (a photoacid generator, the compound described in paragraph 0227, which is synthesized according to the method described in paragraph 0227 of JP2013-047765A)

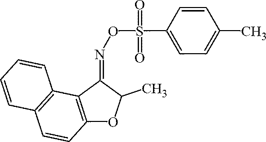 [SMILES: Cc1ccc(S(=O)(=O)O/N=C2/c3c(ccc4ccccc34)OC2C)cc1]

### Preparation of Water-Soluble Resin Composition

### Preparation of Water-Soluble Resin Compositions 1 to 7

The following components were mixed according to parts by mass shown in Table 6 below to prepare water-soluble resin compositions 1 to 7.

It is noted that the water-soluble resin compositions 1 to 7 are suitable compositions for forming the interlayer.

In addition, Kuraray Poval 4-88LA, Kuraray Poval 205, and polyvinylpyrrolidone, which had been used in the preparation of the water-soluble resin compositions 1 to 7, have a solubility of 10 g or more in 100 g of water having a liquid temperature of 22° C. and a pH of 7.0.

TABLE 6

| | | Water-soluble resin composition 1 | Water-soluble resin composition 2 | Water-soluble resin composition 3 | Water-soluble resin composition 4 | Water-soluble resin composition 5 | Water-soluble resin composition 6 | Water-soluble resin composition 7 |
|---|---|---|---|---|---|---|---|---|
| Water-soluble resin | PVA 4-88LA (manufactured by KURARAY Co., Ltd.) | 32.2 | | 32.2 | 32.2 | 32.2 | | |
| | PVA205 (manufactured by KURARAY Co., Ltd.) | | 32.2 | | | | 32.2 | 32.2 |
| | Polyvinylpyrrolidone (manufactured by Nippon Shokubai Co., Ltd.) | 14.9 | 14.9 | 14.9 | 14.9 | 14.9 | 14.9 | 14.9 |
| Compound A and comparative compound | A-1 | 0.01 | | | | | | |
| | A-5 | | 0.01 | | | | 0.01 | |
| | A-6 | | | 0.01 | | | | |
| | A-9 | | | | 0.01 | | | |
| | B-1 | | | | | 0.01 | 0.01 | |
| | MEGAFACE F444 (manufactured by DIC Corporation) | | | | | | | 0.01 |
| Solvent | Ion exchange water | 524.0 | 524.0 | 524.0 | 524.0 | 524.0 | 524.0 | 524.0 |
| | Methanol (manufactured by Mitsubishi Gas Chemical Company, Inc.) | 429.0 | 429.0 | 429.0 | 429.0 | 429.0 | 429.0 | 429.0 |
| Average film thickness of interlayer (water-soluble resin composition layer) (µm) | | 1.0 | 1.0 | 1.0 | 1.0 | 1.0 | 1.0 | 1.0 |

### Preparation of Transfer Film

### Example 1

Using a slit-shaped nozzle, the adjusted thermoplastic resin composition 1 was applied onto a polyethylene terephthalate film (Lumirror 16KS40 (manufactured by Toray Industries, Inc.)) having a thickness of 16 µm so that the width was 1.0 m and the average film thickness of the composition layer after drying was the specific film thickness (the thickness described in Table 5: 2.0 µm), and it was allowed to pass through, over 60 seconds, a drying zone of 3 m in which the temperature was set to 80° C. and the film surface wind speed was set to be 0.2 m/sec by adjusting the intake amount and the exhaust amount, thereby obtaining a laminate A of the temporary support and the thermoplastic resin layer.

Subsequently, the coating amount was adjusted so that the width was 1.0 m and the average film thickness of the composition layer after drying was the specific film thickness (the film thickness described in Table 6: 1.0 µm), and using a slit-shaped nozzle, a water-soluble resin composition 1 was applied onto the thermoplastic resin layer of the produced laminate A. Then, the laminate A was allowed to pass through, over 60 seconds, a drying zone of 3 m in which the temperature was set to 100° C. and the film surface wind speed was set to be 3 m/sec by adjusting the intake amount and the exhaust amount, thereby obtaining a laminate B in which a water-soluble resin layer was formed on the thermoplastic resin layer.

Subsequently, the coating amount was adjusted so that the width was 1.0 m and the average film thickness of the composition layer after drying was the specific film thickness (the film thickness described in Table 3: 2.0 µm), and using a slit-shaped nozzle, a photosensitive resin composition 1 was applied onto the water-soluble resin layer of the produced laminate B. Then, the laminate B was allowed to pass through, over 60 seconds, a drying zone of 3 m in which the temperature was set to 80° C. and the film surface wind speed was set to be 0.2 m/sec by adjusting the intake amount and the exhaust amount, thereby obtaining a transfer film of Example 1 in which a photosensitive resin layer was formed on the water-soluble resin layer.

### Examples 2 to 8 and Comparative Examples 1 and 2

A transfer film was prepared in the same manner as in Example 1, except that the kinds of the thermoplastic resin composition, the water-soluble resin composition, and the photosensitive resin composition were changed as shown in Table 7.

However, in Examples 2 to 8 and Comparative Examples 1 and 2, the film thickness of the composition layer formed from each composition is also changed depending on the kinds of the thermoplastic resin composition, the water-soluble resin composition, and the photosensitive resin composition. The film thickness of the composition layer to be formed is intended to be an average film thickness (µm) that is shown together with the composition of each of the compositions in Table 3, Table 5, and Table 6.

It is noted that the transfer films of Examples 1 to 8 correspond to the transfer film of the first aspect.

### Evaluation of Resolution

A copper layer having a thickness of 200 nm was provided on a polyethylene terephthalate (PET) film having a thickness of 100 µm by a sputtering method, and a PET substrate attached with a copper layer was prepared.

The prepared transfer films (Examples 1 to 8 and Comparative Examples 1 and 2) were wound forward, and then the surface of the outermost layer (the photosensitive resin layer) of the composition layers disposed on the temporary support was affixed to the above-described PET substrate attached with a copper layer under laminating conditions of a roll temperature of 100° C., a linear pressure of 1.0 MPa, and a linear speed of 4.0 m/min, thereby laminating the PET substrate with a copper layer to the transfer film. Next, after exposure with an ultra-high pressure mercury lamp through a line-and-space pattern mask (Duty ratio 1:1, line width: 20 µm) without peeling off the temporary support, the temporary support was peeled off and developed. Development was carried out using a 1.0% sodium carbonate aqueous solution at 25° C. for 30 seconds by shower development. An exposure amount at which the resist line width was 20 µm was defined as the optimum exposure amount, when a line-and-space pattern was formed by the above method.

Any region of 1 cm² in the line-and-space pattern formed at the optimum exposure amount was observed with a scanning electron microscope (SEM), and the minimum line width resolved without peeling of the resist pattern and without forming residues was evaluated as the resolution according to the following evaluation standards. Among them, ranks A, B, and C are practically acceptable ranges. The results are shown in Table 7.

### Evaluation Standard

A: Resolution is less than 5 µm.

B: Resolution is 5 µm or more and less than 7 µm.

C: Resolution is 7 µm or more and less than 9 µm.

D: Resolution is 9 µm or more and less than 11 µm.

E: Resolution is 11 µm or more.

TABLE 7

| | Configuration of transfer film | | | | Resolution evaluation |
|---|---|---|---|---|---|
| | First layer | Second layer | | Third layer | |
| | | Kind of composition | Kind of compound A or comparative compound | | |
| Example 1 | Thermoplastic resin composition 1 | Water-soluble resin composition 1 | A-1 | Photosensitive resin composition 1 | A |
| Example 2 | Thermoplastic resin composition 1 | Water-soluble resin composition 2 | A-5 | Photosensitive resin composition 2 | A |
| Example 3 | Thermoplastic resin composition 1 | Water-soluble resin composition 3 | A-6 | Photosensitive resin composition 3 | B |
| Example 4 | Thermoplastic resin composition 1 | Water-soluble resin composition 4 | A-9 | Photosensitive resin composition 4 | C |
| Example 5 | Thermoplastic resin composition 1 | Water-soluble resin composition 5 | B-1 | Photosensitive resin composition 1 | A |
| Example 6 | Thermoplastic resin composition 2 | Water-soluble resin composition 6 | B-1/A-5 | Photosensitive resin composition 4 | A |
| Example 7 | Thermoplastic resin composition 2 | Water-soluble resin composition 4 | A-9 | Photosensitive resin composition 4 | C |
| Example 8 | Thermoplastic resin composition 2 | Water-soluble resin composition 5 | B-1 | Photosensitive resin composition 1 | A |
| Comparative Example 1 | Thermoplastic resin composition 1 | Water-soluble resin composition 7 | MEGAFACE F444 | Photosensitive resin composition 1 | D |
| Comparative Example 2 | Thermoplastic resin composition 2 | Water-soluble resin composition 7 | MEGAFACE F444 | Photosensitive resin composition 4 | E |

From the results shown in Table 7, it has been confirmed that according to the transfer films of Examples, a resist pattern having excellent resolution can be formed.

In addition, from the comparison among Examples, it was revealed that the resolution is more excellent in a case where the compound A is a low-molecular-weight compound A that has a molecular weight of 2,000 or less and is represented by General Formula (6B) described above (corresponding to Examples 5, 6, and 8), or a case where it is a high-molecular-weight compound A that contains the constitutional unit represented by General Formula (4) described above and the constitutional unit represented by General Formula (5) described above (corresponding to Examples 1 to 3 and 6). Among the above, it was revealed that the resolution is more excellent in a case where the compound A is a low-molecular-weight compound A that has a molecular weight of 2,000 or less and is represented by General Formula (6B) described above (corresponding to Examples 5, 6, and 8), or a case where it is a high-molecular-weight compound A that has a weight-average molecular weight of 15,000 or less and contains the constitutional unit represented by General Formula (4) described above and the constitutional unit represented by General Formula (5) described above (corresponding to Examples 1, 2, and 6).

### Examples 9 to 16 and Comparative Examples 3 and 4

### Preparation of Photosensitive Resin Composition

### Production of Resin

### Synthesis of Polymer P-5

Propylene glycol monomethyl ether acetate (60 g, Fujifilm Wako Pure Chemical Corporation) and propylene glycol monomethyl ether (240 g, Fujifilm Wako Pure Chemical Corporation) were introduced into a flask having a capacity of 2,000 mL. The obtained liquid was heated to 90° C. while being stirred at a stirring speed of 250 rounds per minute (rpm; the same applies hereinafter).

For the preparation of a dropping liquid (1), methacrylic acid (107.1 g, manufactured by Mitsubishi Chemical Corporation, product name: Acryester M), methyl methacrylate (5.46 g, manufactured by Mitsubishi Gas Chemical Company, Inc., product name: MMA), and cyclohexyl methacrylate (231.42 g, manufactured by Mitsubishi Gas Chemical Company, Inc., product name: CHMA) were mixed and diluted with propylene glycol monomethyl ether acetate (60.0 g) to obtain the dropping liquid (1).

For the preparation of a dropping liquid (2), dimethyl 2,2′-azobis(2-methylpropionate) (9.637 g, FUJIFILM Wako Pure Chemical Corporation, product name: V-601) was dissolved in propylene glycol monomethyl ether acetate (136.56 g) to obtain a dropping liquid (2).

The dropping liquid (1) and the dropping liquid (2) were simultaneously added dropwise over 3 hours to the above-described flask (specifically, the 2,000 mL flask containing a liquid heated to 90° C.) having a capacity of 2,000 mL. After completion of the dropwise addition, V-601 (2.401 g) was added to the flask every hour three times. Then, stirring was further carried out at 90° C. for 3 hours.

Then, the solution (the reaction solution) obtained in the flask was diluted with propylene glycol monomethyl ether acetate (178.66 g). Next, tetraethylammonium bromide (1.8 g, Fujifilm Wako Pure Chemical Corporation) and hydroquinone monomethyl ether (0.8 g, Fujifilm Wako Pure Chemical Corporation) were added to the above reaction solution. Thereafter, the temperature of the reaction solution was raised to 100° C.

Next, 76.03 g of glycidyl methacrylate (manufactured by NOF Corporation, product name: Blemmer G) was dropwise added to the reaction solution over 1 hour. The above reaction solution was reacted at 100° C. for 6 hours to obtain 1,158 g of a solution of the resin P-5 (solid content concentration: 36.3% by mass). The obtained resin P-5 had a weight-average molecular weight of 27,000, a number-average molecular weight of 15,000, and an acid value of 95 mgKOH/g. The amount of the residual monomer measured by using gas chromatography was less than 0.1% by mass with respect to the polymer solid content.

### Synthesis of Resin P-6

A resin P-6 was obtained with reference to the synthesis method for the resin P-5.

Specifically, in the dropping liquid (1) used in the synthesis of the resin P-5, the configuration in which methacrylic acid (107.1 g), methyl methacrylate (5.46 g), and cyclohexyl methacrylate (231.42 g) were used as monomers were changed to a configuration in which the monomers were used so that the mass ratio shown in Table 8 below was obtained. In addition, the adding amount of glycidyl methacrylate (76.03 g) was also changed so that the composition of MAA-GMA in Table 8 below was obtained.

The solid content concentration of the obtained solution of the resin P-6 was 36.3% by mass, and the weight-average molecular weight of the obtained resin P-6 was 17,000.

Table 8 shows the kind of each monomer used for synthesizing the resin, the mass percentage (in terms of % by mass) of the constitutional unit derived from each monomer, and the weight-average molecular weight of the resin. In addition, MAA-GMA in Table 8 indicates a constitutional unit in which glycidyl methacrylate is added to a constitutional unit derived from methacrylic acid.

TABLE 8

| | P-6 |
|---|---|
| St | 47.7 |
| MAA-GMA | 32 |
| MAA | 19 |
| MMA | 1.3 |
| Weight-average molecular weight (Mw) | 17,000 |

It is noted that all of the resins P-5 and P-6 correspond to the alkali-soluble resin. Each of the resins P-5 and P-6 was added to the photosensitive resin composition in a form of a solution containing each of the resins.

### Synthesis of Blocked Isocyanate Compound Q-1

Butanone oxime (manufactured by Idemitsu Kosan Co., Ltd.) (453 g) was dissolved in methyl ethyl ketone (700 g) under a nitrogen stream. To the obtained solution, 1,3-bis(isocyanatomethyl)cyclohexane (a mixture of cis and trans isomers, manufactured by Mitsui Chemicals, Inc., TAKENATE 600) (500 g) was added dropwise over 1 hour under ice cooling, and after the dropwise addition, the reaction was further carried out for 1 hour. Then, the temperature of the solution was raised to 40° C., and the reaction was carried out for 1 hour. It has been confirmed that the reaction was completed by ¹H-nuclear magnetic resonance (NMR) and high performance liquid chromatography (HPLC), and a methyl ethyl ketone solution (solid content concentration: 57.7% by mass) of a blocked isocyanate compound Q-1 (see the following formula) was obtained.

It is noted that the blocked isocyanate compound Q-1 was added to the photosensitive resin composition in a form of a solution containing the blocked isocyanate compound Q-1.

| Blocked isocyanate compound | Structure | NCO value [mmol/g] |
|---|---|---|
| Q-1 | 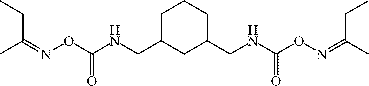 [SMILES: CC/C(C)=N\OC(=O)NCC1CCCC(CNC(=O)O/N=C(/C)CC)C1] | 5.4 |

### Synthesis of Blocked Isocyanate Compound Q-8

A methyl ethyl ketone solution (solid content concentration: 75.0% by mass) of a blocked isocyanate compound Q-8 (see the following formula) was obtained with reference to a synthesis method for the blocked isocyanate compound Q-1.

It is noted that the blocked isocyanate compound Q-8 was added to the photosensitive resin composition in a form of a solution containing the blocked isocyanate compound Q-8.

| | | |
|---|---|---|
| Q-8 | 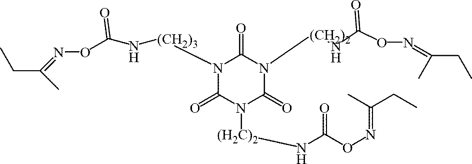 | 3.9 |

### Preparation of Photosensitive Resin Compositions 5 and 6

According to the prescriptions described in Table 9 below, components were mixed with stirring to prepare photosensitive resin compositions 5 and 6. It is noted that the unit of the amount of each component is part by mass.

TABLE 9

| | | Photosensitive resin composition r5 | Photosensitive resin composition r6 |
|---|---|---|---|
| Polymerizable compound | Tricyclodecanedimethanol diacrylate (A-DCP, manufactured by SHIN-NAKAMURA CHEMICAL Co, Ltd.) | 5.60 | 18.26 |
| | 1,9-nonanediol diacrylate (A-NOD-N (manufactured by SHIN-NAKAMURA CHEMICAL Co., Ltd.)) | | 2.79 |
| | Dipentaerythritol hexaacrylate (A-DPH (manufactured by SHIN-NAKAMURA CHEMICAL Co., Ltd.)) | | 8.15 |
| | Monomer having carboxy group, ARONIX TO-2349 (manufactured by Toagosei Co., Ltd.) | 0.93 | 3.04 |
| | Urethane acrylate 8UX-015 A (manufactured by Taisei Fine Chemical Co., Ltd.) | 2.80 | |
| Alkali-soluble resin | P-5 (solid content:36.3% binder solution) | 42.85 | |
| | P-6 (solid content:36.3% binder solution) | | 49.03 |
| Photopolymer | 1-[9-ethyl-6-(2-methylbenzoyl)-9H-carbazole-3-yl]ethanone-l-(0-acetyloxime) (IRGACURE OXE-02, manufactured by BASF SE) | 0.11 | 0.37 |
| ization initiator | 2-methyl-(4-methylthiophenyl)-2-morpholinopropane-l-one (Omnirad 907, manufactured by IGM Resins B.Y.) | 0.21 | 0.74 |
| | DURANATE TPA-B80E (manufactured by Asahi Kasei Chemicals Co., Ltd.) | 4.53 | |
| | Q-1 (solid content:57.7% binder solution) | | 2.97 |
| | Q-8 (solid content:75.0% binder solution) | | 12.50 |
| | N-phenylglycine (manufactured by Tokyo Chemical Industry Co., Ltd.) | 0.03 | 0.10 |
| Additive | Benzimidazole (manufactured by Tokyo Chemical Industry Co., Ltd.) | 0.09 | 0.13 |
| | Isonicotinamide (manufactured by Tokyo Chemical Industry Co., Ltd.) | | 0.52 |
| | SMA EF-40 (copolymer of styrene/maleic acid anhydride = 4:1 (molar ratio), acid anhydride value: 1.94 mmol/g, Mw:10,500, manufactured by Cray Valley) | | 1.20 |
| | MEGAFACE F551A (manufactured by DIC Corporation) | 0.16 | 0.16 |
| Solvent | Methyl ethyl ketone | 42.69 | 42.69 |
| | Average film thickness of photosensitive resin layer (µm) | 5.0 | 5.0 |

### Preparation of Water-Soluble Resin Composition]

### Synthesis of Polymer P-7

Propylene glycol monomethyl ether (270.0 g) was introduced into a three-neck flask, and the temperature was raised to 70° C. under a nitrogen stream while stirring.

On the other hand, allyl methacrylate (45.6 g, Fujifilm Wako Pure Chemical Corporation) and methacrylic acid (14.4 g) were dissolved in propylene glycol monomethyl ether (270.0 g), and further, V-65 (3.94 g, FUJIFILM Wako Pure Chemical Corporation) was dissolved therein to prepare a dropping liquid, which was added dropwise into the flask over 2.5 hours. The stirred state was maintained as it was, and the reaction was carried out for 2.0 hours. Then, the temperature of the contents in the flask was returned to room temperature, the contents in the flask were added dropwise into 2.7 L of ion exchange water in a stirred state, and reprecipitation was carried out to obtain a suspension. The suspension was filtered through Nutche (a Buchner funnel) in which a filter paper was placed, and the filtrate was further washed with ion exchange water to obtain a powder in a state of being wet. Blast drying was carried out at 45° C., and it was confirmed that a constant weight was reached, whereby a resin P-7 was obtained as a powder at a yield of 70%. The amount of the residual monomer measured by using gas chromatography was less than 0.1% by mass with respect to the polymer solid content.

### Preparation of Water-Soluble Resin Compositions 8 to 14

According to the prescriptions shown in Table 10 below, components were mixed with stirring to prepare water-soluble resin compositions 8 to 14. It is noted that the unit of the amount of each component is part by mass.

It is noted that the water-soluble resin compositions 8 to 14 can be used for forming a refractive index adjusting layer.

In addition, the resin P-7 and ARUFON UC-3920, which are used in the preparation of the water-soluble resin compositions 8 to 14, are an alkali-soluble resin. In addition, the resin P-7 and ARUFON UC-3920 have a solubility of 0.1 g or more in 100 g of water having a liquid temperature of 22° C. and a pH of 7.0. That is, these resins also correspond to the water-soluble resin.

TABLE 10

| | | | | | | | | |
|---|---|---|---|---|---|---|---|---|
| | | Water-soluble resin composition 8 | Water-soluble resin composition 9 | Water-soluble resin composition 10 | Water-soluble resin composition 11 | Water-soluble resin composition 12 | Water-soluble resin composition 13 | Water-soluble resin composition 14 |
| Nanouse OZS-30M: ZrO₂ particle (containing tin oxide) Methanol dispersion liquid (nonvolatile fraction: 30.5%) manufactured by Nissan Chemical Industries, Ltd. | | 4.34 | 4.34 | 4.34 | 4.34 | 4.34 | 4.34 | 4.34 |
| Ammonia water (25%) | | 7.84 | 7.84 | 7.84 | 7.84 | 7.84 | 7.84 | 7.84 |
| Copolymer | P-7 | 0.21 | 0.20 | 0.20 | 0.20 | 0.20 | 0.21 | 0.21 |
| | ARUFON UC-3920 (manufactured by Toagosei Co., Ltd.) | 0.08 | 0.02 | 0.02 | 0.02 | 0.02 | 0.08 | 0.08 |
| Monomer having carboxy group, ARONIX TO-2349 (manufactured by Toagosei Co., Ltd.) | | 0.03 | 0.03 | 0.03 | 0.03 | 0.03 | 0.03 | 0.03 |
| Benzotriazole BT-LX (manufactured by JOHOKU CHEMICAL Co., Ltd.) | | 0.03 | | | | | 0.03 | 0.03 |
| Adenine (manufactured by Tokyo Chemical Industry Co., Ltd.) | | | 0.03 | 0.03 | 0.03 | 0.03 | | |
| N-methyldiethanolamine (manufactured by Tokyo Chemical Industry Co., Ltd.) | | | 0.03 | 0.03 | 0.03 | 0.03 | | |
| Monoisopropanolamine | | 0.02 | | | | | 0.02 | 0.02 |
| Compound A and comparative compound | A-1 | 0.01 | | | | | | |
| | A-5 | | 0.01 | | | | | |
| | A-6 | | | 0.01 | | | | |
| | A-9 | | | | 0.01 | | | |
| | B-1 | | | | | 0.01 | 0.01 | |
| | MEGAFACE F444 (manufactured by DIC Corporation) | | | | | | | 0.01 |
| Ion exchange water | | 21.7 | 21.3 | 21.3 | 21.3 | 21.3 | 21.7 | 21.7 |
| Methanol | | 65.8 | 66.2 | 66.2 | 66.2 | 66.2 | 65.8 | 65.8 |
| Average film thickness of water-soluble | | 80 | 80 | 80 | 80 | 80 | 80 | 80 |
| | resin layer(nm) | | | | | | | |

### Preparation of Transfer Film

### Example 9

Using a slit-shaped nozzle, the coating amount of the photosensitive resin composition was adjusted so that the width was 1.0 m and the thickness of the photosensitive composition layer after drying was the specific film thickness (the film thickness described in Table 9: 8.0 µm), and the photosensitive resin composition 5 was applied onto a temporary support of a polyethylene terephthalate film (Lumirror 16KS40 (manufactured by Toray Industries, Inc.)) having a thickness of 16 µm. Next, the obtained laminate was allowed to pass through, over 60 seconds, a drying zone of 3 m in which the temperature was set to 80° C. and the film surface wind speed was set to be 0.2 m/sec by adjusting the intake amount and the exhaust amount, thereby obtaining a laminate C of the temporary support and the photosensitive resin layer.

Subsequently, the coating amount was adjusted so that the width was 1.0 m and the average film thickness of the composition layer after drying was the specific film thickness (the film thickness described in Table 10: 80 nm), and using a slit-shaped nozzle, a water-soluble resin composition 8 was applied onto the photosensitive resin layer of the produced laminate C. Then, the laminate C was allowed to pass through, over 60 seconds, a drying zone of 3 m in which the temperature was set to 80° C. and the film surface wind speed was set to be 3 m/sec by adjusting the intake amount and the exhaust amount, thereby obtaining a transfer film of Example 9 in which a water-soluble resin layer was formed on the photosensitive resin layer.

### Examples 10 to 16 and Comparative Examples 3 and 4

A transfer film was prepared in the same manner as in Example 9, except that the kinds of the photosensitive resin composition and the water-soluble resin composition were changed as shown in Table 11.

However, in Examples 10 to 16 and Comparative Examples 3 and 4, the film thickness of the composition layer formed from each composition is also changed depending on the kinds of the water-soluble resin composition and the photosensitive resin composition. The film thickness of the composition layer to be formed is intended to be an average film thickness that is shown together with the composition of each of the compositions in Table 9 and Table 10.

It is noted that the transfer films of Examples 9 to 16 correspond to the transfer film of the second aspect.

### Evaluation of Plane Shape

A polyethylene terephthalate (PET) film having a thickness of 100 µm was prepared.

The produced transfer film was wound forward, and then the surface of the outermost layer (the water-soluble resin layer) of the composition layers disposed on the temporary support was affixed to the above-described PET substrate under laminating conditions of a roll temperature of 100° C., a linear pressure of 1.0 MPa, and a linear speed of 4.0 m/min, thereby laminating the PET substrate to the transfer film. Next, after exposure with an ultra-high pressure mercury lamp without peeling off the temporary support, the temporary support was peeled off and developed. Development was carried out using a 1.0% sodium carbonate aqueous solution at 25° C. for 30 seconds by shower development. An exposure amount at which the resist line width was 20 µm was defined as the optimum exposure amount, when a line-and-space pattern mask was formed through a line-and-space pattern mask (Duty ratio 1:1, line width: 20 µm) by the above method.

The surface of the cured film formed at the optimum exposure amount was visually observed for a region of a length of 10 m × a total width of 1.0 m from the PET film side, and the plane shape was evaluated according to the following evaluation standards. Among them, ranks A, B, and C are practically acceptable ranges. The results are shown in Table 11.

### Evaluation Standard

A: Surface defects were less than 1 defect/m².

B: Surface defects were 1 defect/m² or more and less than 3 defects/m².

C: Surface defects were 3 defects/m² or more and less than 5 defects/m².

D: Surface defects were 5 defects/m² or more and less than 10 defects/m².

E: Surface defects were 10 defects/m² or more.

TABLE 11

| | Configuration of transfer film | | | Plane shape evaluation |
|---|---|---|---|---|
| | First layer | Second layer | | |
| | | Kind of composition | Kind of compound A or comparative compound | |
| Example 9 | Photosensitive resin composition 5 | Water-soluble resin composition 8 | A-1 | A |
| Example 10 | Photosensitive resin composition 6 | Water-soluble resin composition 9 | A-5 | A |
| Example 11 | Photosensitive resin composition 5 | Water-soluble resin composition 10 | A-6 | B |
| Example 12 | Photosensitive resin composition 5 | Water-soluble resin composition 11 | A-9 | C |
| Example 13 | Photosensitive resin composition 6 | Water-soluble resin composition 10 | A-6 | B |
| Example 14 | Photosensitive resin composition 6 | Water-soluble resin composition 11 | A-9 | C |
| Example 15 | Photosensitive resin composition 6 | Water-soluble resin composition 12 | B-1 | A |
| Example 16 | Photosensitive resin composition 6 | Water-soluble resin composition 13 | B-1 | A |
| Comparative Example 3 | Photosensitive resin composition 5 | Water-soluble resin composition 14 | MEGAFACE F444 | E |
| Comparative Example 4 | Photosensitive resin composition 6 | Water-soluble resin composition 14 | MEGAFACE F444 | D |

From the results in Table 11, it has been confirmed that the transfer films of Examples have few surface defects.

In addition, from the comparison among Examples, it was revealed that the surface defects are further suppressed in a case where the compound A is a low-molecular-weight compound A that has a molecular weight of 2,000 or less and is represented by General Formula (6B) described above (corresponding to Examples 15 and 16), or a case where it is a high-molecular-weight compound A that contains the constitutional unit represented by General Formula (4) described above and the constitutional unit represented by General Formula (5) described above (corresponding to Examples 9 to 11 and 13). Among the above, it was revealed that the surface defects are further suppressed in a case where the compound A is a low-molecular-weight compound A that has a molecular weight of 2,000 or less and is represented by General Formula (6B) described above (corresponding to Examples 15 and 16), or a case where it is a high-molecular-weight compound A that has a weight-average molecular weight of 15,000 or less and contains the constitutional unit represented by General Formula (4) described above and the constitutional unit represented by General Formula (5) described above (corresponding to Examples 9 and 10).

### EXPLANATION OF REFERENCES

1, 11: temporary support
3: thermoplastic resin layer
5, 15: water-soluble resin layer
7, 13: negative tone photosensitive resin layer
9,17: cover film
10, 20: transfer film

What is claimed is:

1. A transfer film comprising:
a temporary support; and
a composition layer disposed on the temporary support,
wherein the composition layer includes a photosensitive resin layer and a water-soluble resin layer,
the transfer film is obtained by laminating the temporary support, the water-soluble resin layer, and the photosensitive resin layer in this order or obtained by laminating the temporary support, the photosensitive resin layer, and the water-soluble resin layer in this order, and
the water-soluble resin layer contains a compound A having a group represented by General Formula (1), 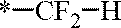
in the formula, * represents a bonding position.

2. The transfer film according to claim 1,
wherein the compound A is a compound having a group represented by General Formula (2), 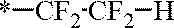
in the formula, * represents a bonding position.

3. The transfer film according to claim 1,
wherein the compound A is a compound having a group represented by General Formula (3), 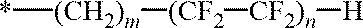
in the formula, m and n each independently represent an integer of 1 to 6, and * represents a bonding position.

4. The transfer film according to claim 1,
wherein the compound A is a high-molecular-weight compound having a weight-average molecular weight of 5,000 or more.

5. The transfer film according to claim 1,
wherein the compound A is a high-molecular-weight compound, and
the high-molecular-weight compound contains a constitutional unit derived from a monomer represented by General Formula (4A), 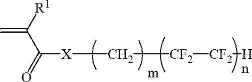
in the formula, R¹ represents a hydrogen atom or a methyl group, X represents an oxygen atom, a sulfur atom, or —N(R²)—, m and n each independently represent an integer of 1 to 6, and R² represents a hydrogen atom or an alkyl group having 1 to 4 carbon atoms.

6. The transfer film according to claim 5,
wherein the high-molecular-weight compound further contains a constitutional unit derived from a monomer represented by General Formula (5), 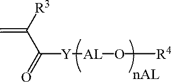
in the formula, R³ represents a hydrogen atom or a methyl group, Y represents an oxygen atom, a sulfur atom, or —N(R⁵)—, AL represents an alkylene group which may have a substituent, nAL represents an integer of 2 or more, R⁴ represents a hydrogen atom or a substituent, and R⁵ represents a hydrogen atom or an alkyl group having 1 to 4 carbon atoms.

7. The transfer film according to claim 1,
wherein a molecular weight of the compound A is 2,000 or less.

8. The transfer film according to claim 1,
wherein the compound A is a compound represented by General Formula (6A), 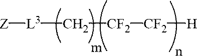
in the formula, Z represents a monovalent organic group, L³ represents an oxygen atom, a sulfur atom, or —N(R⁶)—, m and n each independently represent an integer of 1 to 6, and R⁶ represents a hydrogen atom or an alkyl group having 1 to 4 carbon atoms.

9. The transfer film according to claim 8,
wherein Z represents a monovalent organic group including a poly(oxyalkylene) structural moiety which may have a substituent.

10. The transfer film according to claim 1,
wherein the photosensitive resin layer further contains an alkali-soluble resin and contains a polymerizable compound.

11. The transfer film according to claim 1,
wherein the water-soluble resin layer further contains metal oxide particles.

12. The transfer film according to claim 1,
wherein the water-soluble resin layer contains two or more kinds of water-soluble resins.

13. The transfer film according to claim 1, further comprising a thermoplastic resin layer.

14. The transfer film according to claim 1,
wherein the transfer film is obtained by laminating the temporary support, the water-soluble resin layer, and the photosensitive resin layer in this order.

15. The transfer film according to claim 1,
wherein the transfer film is obtained by laminating the temporary support, the thermoplastic resin layer, the water-soluble resin layer, and the photosensitive resin layer in this order.

16. The transfer film according to claim 1,
wherein the transfer film is obtained by laminating the temporary support, the photosensitive resin layer, and the water-soluble resin layer in this order.

17. A manufacturing method for a laminate using the transfer film according to claim 1, the manufacturing method comprising:
an affixing step of bringing a substrate into contact with a surface of an outermost layer among composition layers disposed on the temporary support in the transfer film and affixing the transfer film to the substrate to obtain a transfer film-attached substrate;
an exposure step of subjecting the composition layer to pattern exposure;
a development step of developing the exposed composition layer to form a resin pattern; and
a peeling step of peeling the temporary support from the transfer film-attached substrate, between the affixing step and the exposure step or between the exposure step and the development step.

18. A manufacturing method for a circuit wire using the transfer film according to claim 1, the manufacturing method comprising:
an affixing step of bringing a surface of an outermost layer among composition layers disposed on the temporary support in the transfer film into contact with a substrate having a conductive layer and bonding the transfer film to the substrate having the conductive layer to obtain a transfer film-attached substrate;
an exposure step of subjecting the composition layer to pattern exposure;
a development step of developing the exposed composition layer to form a resin pattern;
an etching step of subjecting the conductive layer in a region where the resin pattern is not disposed to an etching treatment; and
a peeling step of peeling the temporary support from the transfer film-attached substrate, between the affixing step and the exposure step or between the exposure step and the development step.

19. A manufacturing method for an electronic device, comprising:
the manufacturing method for a laminate according to claim 17,
wherein the electronic device includes the resin pattern as a cured film.

20. The transfer film according to claim 2,
wherein the compound A is a compound having a group represented by General Formula (3), 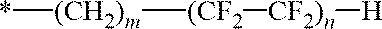
in the formula, m and n each independently represent an integer of 1 to 6, and * represents a bonding position.
